(19) United States
(12) Patent Application Publication
(10) Pub. No.: US 2012/0100481 A1
(43) Pub. Date: Apr. 26, 2012

(54) ACTINIC RAY-SENSITIVE OR RADIATION-SENSITIVE COMPOSITION AND PATTERN FORMING METHOD USING THE SAME

(75) Inventors: Takayuki Ito, Shizuoka (JP); Tomotaka Tsuchimura, Shizuoka (JP); Takeshi Kawabata, Shizuoka (JP)

(73) Assignee: FUJIFILM CORPORATION, Tokyo (JP)

(21) Appl. No.: 13/381,683

(22) PCT Filed: Jul. 28, 2010
(86) PCT No.: PCT/JP2010/063131

§ 371 Date: Dec. 30, 2011

(30) Foreign Application Priority Data
Jul. 31, 2009 (JP) 2009-180207
Sep. 4, 2009 (JP) 2009-204998

(51) Int. Cl. G03F 7/20; G03F 7/027; G03F 7/004

(52) U.S. Cl. 430/283.1; 430/270.1; 430/281.1; 430/285.1; 430/325; 430/296

(57) ABSTRACT

An actinic ray-sensitive or radiation-sensitive composition, including: (1) a low molecular compound having a molecular weight of 500 to 5,000 and containing (G) an acid-decomposable group; and (2) a compound capable of generating an acid of 305 Å³ or more in volume upon irradiation with an actinic ray or radiation, an actinic ray-sensitive or radiation-sensitive composition, including: a solvent; and (1A) a compound which is a low molecular compound having a molecular weight of 500 to 5,000 and containing (Z) one or more groups capable of decomposing upon irradiation with an actinic ray or radiation to produce an acid, (G) one or more acid-decomposable groups and (S) one or more dissolution auxiliary groups, wherein assuming that the number of the functional groups in one molecule of (Z), (G) and (S) is z, q and s, respectively, q/z≧2 and s/z≧2, and a pattern forming method using the composition are provided.

### TECHNICAL FIELD

The present invention relates to an actinic ray-sensitive or radiation-sensitive composition suitable for use in the ultramicrolithography process such as production of VLSI or a high-capacity microchip, in the preparation process of an imprint mold, in the production process of a high-density information recording medium such as hard disc, and in other photofabrication processes, and a pattern forming method using the same. More specifically, the present invention relates to an actinic ray-sensitive or radiation-sensitive composition capable of forming a highly refined pattern with use of electron beam, X-ray, EUV light or the like and suitably usable in the microfabrication of a semiconductor device, and a pattern forming method using the composition. In one embodiment, the present invention relates to a positive resist composition and a pattern forming method using the composition.

In the present invention, the term “actinic ray” or “radiation” indicates, for example, a bright line spectrum of mercury lamp, a far ultraviolet ray typified by excimer laser, an extreme-ultraviolet ray, an X-ray or an electron beam. Also, in the present invention, the “light” means an actinic ray or radiation.

### BACKGROUND ART

In the process of producing a semiconductor device such as IC and LSI, microfabrication by lithography using a photoresist composition has been conventionally performed. Recently, the integration degree of an integrated circuit is becoming higher and formation of an ultrafine pattern in the sub-micron or quarter-micron region is required. To cope with this requirement, the exposure wavelength also tends to become shorter, for example, from g line to i line or further to KrF excimer laser light. At present, other than the excimer laser light, development of lithography using electron beam, X-ray or EUV light is proceeding.

Furthermore, the microfabrication by lithography is expanding its application range not only to the production process of a semiconductor device but also to the preparation of a nanoimprint mold and the production of a high-density information recording medium such as hard disc.

Above all, the electron beam lithography is positioned as a next-generation or next-next-generation pattern formation technique, and a high-sensitivity and high-resolution positive resist is being demanded. In particular, the elevation of sensitivity for shortening the wafer processing time is a very important task but in the positive resist for electron beam, when elevation of sensitivity is sought for, not only reduction of the resolution but also worsening of the line edge roughness are brought about, and development of a resist satisfying these properties at the same time is strongly demanded. The line edge roughness as used herein means that the edge at the interface between the resist pattern and the substrate irregularly fluctuates in the direction perpendicular to the line direction due to the resist property and when the pattern is viewed from right above, the edge gives an uneven appearance. This unevenness is transferred by the etching step using the resist as a mask and causes deterioration of electric property, resulting in decrease in the yield. Particularly, in an ultrafine region of 0.25 μm or less, the improvement of line edge roughness is a very important issue. The high sensitivity is in a trade-off relationship with high resolution, good pattern profile and improved line edge roughness, and it is very important how satisfy all of these properties at the same time.

Also in the lithography using X-ray or EUV light, it is similarly an important task to satisfy all of high sensitivity, high resolution and the like at the same time, and this task needs to be solved.

As for the resist suitable for such a lithography process using electron beam, X-ray or EUV light, a chemical amplification resist utilizing an acid catalytic reaction is mainly used from the standpoint of increasing the sensitivity. In the case of a positive resist, a chemical amplification resist composition mainly composed of an acid generator and a phenolic polymer having a property of being insoluble or sparingly soluble in an aqueous alkali solution but becoming soluble in an aqueous alkali solution by the action of an acid (hereinafter simply referred to as a “phenolic acid-decomposable resin”) is being effectively used.

However, in the formation of a more refined pattern of 100 nm or less, it is difficult with the above-described resin compound to obtain sufficient performance in terms of line edge roughness and resolution, because the unit of dissolution is large and a molecular weight distribution as well as a compositional ratio distribution are present.

As the method for solving these problems, there are known cases of using, as the resist composition, a low molecular acid-decomposable compound [for example, a phenol-based compound derivative having a specific structure (see, for example, JP-A-10-83073 (the term “JP-A” as used herein means an “unexamined published Japanese patent application” and JP-A-2000-305270), a calixarene having a specific structure (see, for example, JP-A-10-120610), a calixresorcinarene (see, for example, JP-A-10-310545), a phenol-based dendrimer with the mother nucleus being a calixresorcinarene (see, for example, JP-A-10-310545), or a truxene derivative (see, for example JP-A-2008-76850)] different from conventional resins. However, even when such a low molecular compound is used, it can be hardly said that sufficient improvement effects as compared with conventional resin-based compound are obtained, and more improvements are demanded.

On the other hand, a specific photo-acid generator is known to be effective as the method for improving the line edge roughness or resolution (see, for example, JP-A-2005-97254), but the source of effect is not clarified and a case of using it in combination with the above-described low molecular compound is also not known.

In addition, with recent pattern refinement, thinning of the resist film is proceeding, and enhancement in the edging resistance of the resist is also an important problem to be solved.

As described above, also in the lithography using X-ray or EUV light, it is similarly an important task to satisfy all of high sensitivity, high resolution, good pattern profile, improved line edge roughness and dry etching resistance at the same time, and resolution of this task is required.

In order to solve these problems, in International Publication No. 08/029,673, pamphlet, a low molecular compound having introduced thereinto a function of a photo-acid generator is studied, and in U.S. Patent Application Publication No. 2007/122734, a molecular resist using a low molecular compound with an attempt to enhance the sensitivity and suppress the line edge roughness is studied. On the other hand, use of a resin having a function of a photo-acid generator in the main or side chain of the polymer is studied (see, for example, JP-A-9-325497, U.S. Patent Application Publication No. 2006/121390, U.S. Patent Application Publication No. 2007/117043, JP-A-2008-133448 and Proc. of SPIE, Vol. 6923, 692312, 2008).

However, under the conventional technology, it is at present impossible to satisfy all of sensitivity, resolution, pattern profile, line edge roughness and dry etching resistance at the same time in the lithography using electron beam, X-ray or EUV light.

### SUMMARY OF INVENTION

In order to enhance the performance in microfabricating a semiconductor device by using high-energy ray, X-ray, electron beam or EUV light, an object of the present invention is to provide an actinic ray-sensitive or radiation-sensitive composition excellent in the resolution, line edge roughness and etching resistance and at the same time, excellent in the sensitivity and pattern profile, and a pattern forming method using the composition.

As a result of intensive studies to solve those problems, it has been found that the above-described object can be attained by using a low molecular compound having a molecular weight of 500 to 5,000 and containing (G) an acid-decomposable group capable of decomposing by the action of an acid to accelerate the dissolution in an alkali developer, as follows: that is, using (1) a low molecular compound having a molecular weight of 500 to 5,000 and containing (G) an acid-decomposable group capable of decomposing by the action of an acid to accelerate the dissolution in an alkali developer together with (2) a compound capable of generating an acid of 305 Å³ or more in volume upon irradiation with an actinic ray or radiation (first embodiment); or using, as the low molecular compound (1), (1A) a low molecular compound having introduced thereinto (Z) a group capable of decomposing upon irradiation with an actinic ray or radiation to produce an acid and (S) a dissolution auxiliary group capable of accelerating the dissolution in an alkali developer (second embodiment).

The present invention is as follows. In the following, <1> to <8> come under a first embodiment, and <9> to <16> come under a second embodiment.

<1> An actinic ray-sensitive or radiation-sensitive composition, comprising:

(1) a low molecular compound having a molecular weight of 500 to 5,000 and containing (G) an acid-decomposable group capable of decomposing by an action of an acid to accelerate a dissolution of the low molecular compound (1) in an alkali developer; and

(2) a compound capable of generating an acid of 305 Å³ or more in volume upon irradiation with an actinic ray or radiation.

<2> The actinic ray-sensitive or radiation-sensitive composition as described in <1> above,

wherein the compound (2) is represented by the following formula (2-1) or (2-2):

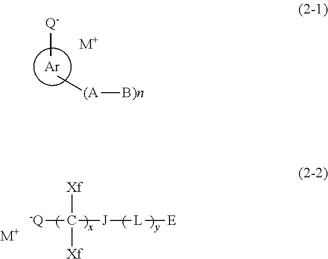

wherein in formula (2-1), Ar represents an aromatic ring and may further have a substituent other than the -(A-B) group;

n represents an integer of 1 or more;

A represents a single bond or a divalent linking group;

B represents a group containing a hydrocarbon group;

when n is 2 or more, a plurality of the -(A-B) groups are the same or different from each other;

Q⁻ represents an anion with pKa of the conjugated acid of the anion represented by Q⁻ being 6 or less; and

M⁺ represents an organic onium ion, and in formula (2-2), each Xf independently represents a fluorine atom or an alkyl group substituted with at least one fluorine atom;

J represents a single bond, a linear, branched or cyclic alkylene group which may contain an ether oxygen, an arylene group, or a group containing a combination of these groups, and the groups combined may be connected through an oxygen atom;

L represents a divalent linking group, and when a plurality of L's are present, the plurality of L's are the same or different from each other;

E represents a group having a ring structure;

x represents an integer of 1 to 20;

y represents an integer of 0 to 10; and

Q⁻ and M⁺ have the same meanings as those in formula (2-1).

<3> The actinic ray-sensitive or radiation-sensitive composition as described in <2> above,

wherein the compound (2) is represented by formula (2-2), and formula (2-2) is represented by the following formula (2-3):

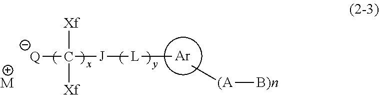

wherein Ar, n, A, B, Q⁻, M⁺, Xf, J, L, x and y have the same meanings as respective symbols in formulae (2-1) and (2-2).

<4> The actinic ray-sensitive or radiation-sensitive composition as described in <2> or <3> above,

wherein in formula (2-1) or (2-3), B is a group containing a hydrocarbon group having a carbon number of 4 or more.

<5> The actinic ray-sensitive or radiation-sensitive composition as described in <2> or <3> above,

wherein in formula (2-1) or (2-3), B is a group containing a tertiary or quaternary carbon atom-containing hydrocarbon group having a carbon number of 4 or more.

<6> The actinic ray-sensitive or radiation-sensitive composition as described in <2> or <3> above,

wherein in formula (2-1) or (2-3), B is a group containing a cyclic hydrocarbon having a carbon number of 4 or more.

<7> The actinic ray-sensitive or radiation-sensitive composition as described in any one of <1> to <6> above,

wherein the low molecular compound (1) further contains (S) a dissolution auxiliary group capable of accelerating a dissolution of the low molecular compound (1) in an alkali developer.

<8> The actinic ray-sensitive or radiation-sensitive composition according to any one of <1> to <7> above,

wherein the low molecular compound (1) is a compound represented by the following formula (1-1):

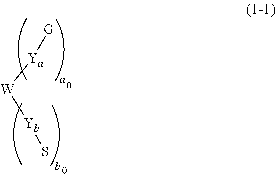

wherein W represents an (a₀+b₀)-valent organic group;

each of Yₐ and Y_{b} independently represents a single bond or a divalent linking group;

G represents an acid-decomposable group capable of decomposing by an action of an acid to accelerate a dissolution of the low molecular compound (1) in an alkali developer;

S is a dissolution auxiliary group capable of accelerating a dissolution of the low molecular compound (1) in an alkali developer;

each of a₀ and b₀ independently represents an integer of 1 to 30, and when a plurality of —(Yₐ-G) groups and a plurality of —(Y_{b}—S) groups are present respectively, the plurality of —(Yₐ-G) groups and the plurality of —(Y_{b}—S) groups are the same or different from each other respectively.

<9> An actinic ray-sensitive or radiation-sensitive composition, comprising:

a solvent; and

(1A) a compound which is a low molecular compound having a molecular weight of 500 to 5,000 and containing, in one molecule, (Z) one or more groups capable of decomposing upon irradiation with an actinic ray or radiation to produce an acid, (G) one or more acid-decomposable groups capable of decomposing by an action of an acid to accelerate a dissolution of the compound (1A) in an alkali developer and (S) one or more dissolution auxiliary groups capable of accelerating a dissolution of the compound (1A) in an alkali developer, wherein assuming that the number of the functional groups in one molecule of (Z), (G) and (S) is z, q and s, respectively, q/z≧2 and s/z≧2.

<10> The actinic ray-sensitive or radiation-sensitive composition as described in <9> above,

wherein the compound (1A) is a compound represented by the following formula (1A-1) or (1A-2):

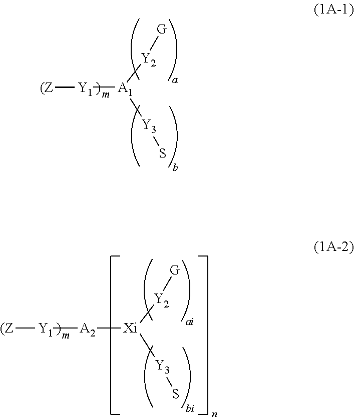

wherein in formula (1A-1), A₁ represents an (a+b+m)-valent organic group;

each of Y₁, Y₂ and Y₃ independently represents a single bond or a divalent linking group;

Z represents a group capable of decomposing upon irradiation with an actinic ray or radiation to produce an acid;

G represents an acid-decomposable group capable of decomposing by an action of an acid to accelerate a dissolution of the compound (1A) in an alkali developer;

S represents a dissolution auxiliary group capable of accelerating a dissolution of the compound (1A) in an alkali developer;

m represents an integer of 1 to 3; and

each of a and b independently represents an integer of 2 to 10,

in formula (1A-2), A₂ represents an (m+n)-valent organic group;

Y₁, Y₂, Y₃, Z, G, S and m have the same meanings as those in formula (1A-1);

Xi represents an (ai+bi+1)-valent organic group;

n represents an integer of 1 to 10;

each of ai and bi independently represents an integer of 0 to 5; and

ai and bi are not 0 at the same time, and

in formulae (1A-1) and (1A-2), when a plurality of —(Y₁—Z) groups, a plurality of —(Y₂-G) groups, a plurality of —(Y₃—S) groups and a plurality of Xi's are present respectively, the plurality of —(Y₁—Z) groups, the plurality of —(Y₂-G) groups, the plurality of —(Y₃—S) groups and the plurality of Xi's are the same or different from each other respectively.

<11> The actinic ray-sensitive or radiation-sensitive composition as described in <9> or <10> above,

wherein the compound (1A) contains at least one aromatic ring.

<12> The actinic ray-sensitive or radiation-sensitive composition as described in <11> above, comprising:

as the compound (1A), a compound in which at least one of A₁, Y₁, Y₂ and Y₃ in formula (1A-1) or at least one of A₂, Xi, Y₁, Y₂ and Y₃ in formula (1A-2) is a group containing an aromatic group.

<13> The actinic ray-sensitive or radiation-sensitive composition as described in <11> or <12> above,

wherein the aromatic ring is a benzene ring.

<14> The actinic ray-sensitive or radiation-sensitive composition as described in <11> or <12> above,

wherein the aromatic group is a condensed ring composed of two or more rings.

<15> The actinic ray-sensitive or radiation-sensitive composition as described in <14> above,

wherein the aromatic ring is a naphthalene ring.

<16> The actinic ray-sensitive or radiation-sensitive composition as described in any one of <9> to <15> above, further comprising:

a basic compound.

<17> A pattern forming method, comprising:

forming a film by using the actinic ray-sensitive or radiation-sensitive composition according to any one of <1> to <16> above; and

exposing and developing the film.

<18> The pattern forming method as described in <17> above,

wherein the exposure is performed using X-ray, electron beam or EUV.

### DESCRIPTION OF EMBODIMENTS

The present invention is described in detail below.

Incidentally, in the present invention, when a group (atomic group) is denoted without specifying whether substituted or unsubstituted, the group includes both a group having no substituent and a group having a substituent. For example, “an alkyl group” includes not only an alkyl group having no substituent (unsubstituted alkyl group) but also an alkyl group having a substituent (substituted alkyl group).

Furthermore, in the present invention, unless otherwise indicated, the “exposure” includes not only exposure to a mercury lamp, a far ultraviolet ray typified by excimer laser, an X-ray, EUV light or the like but also lithography with a particle beam such as electron beam and ion beam.

Preferred embodiments of the present invention are described below, but the present invention is not limited to the following embodiments, and it should be understood that embodiments after appropriately adding changes, modifications and the like to the following embodiments based on the normal knowledge of one skilled in the art without departing from the purport of the invention are included in the scope of the present invention.

A first embodiment of the present invention relates to an actinic ray-sensitive or radiation-sensitive composition comprising (1) a low molecular compound having a molecular weight of 500 to 5,000 and containing (G) an acid-decomposable group capable of decomposing by the action of an acid to change the solubility in an alkali developer and (2) a compound capable of generating an acid of 305 Å³ or more in volume upon irradiation with an actinic ray or radiation.

The (1) low molecular compound having a molecular weight of 500 to 5,000 and containing (G) an acid-decomposable group capable of decomposing by the action of an acid to change the solubility in an alkali developer is described below.

### [Low Molecular Compound (1)]

The low molecular compound (1) for use in the present invention is a low molecular compound having a molecular weight of 500 to 5,000 and containing (G) an acid-decomposable group capable of decomposing by the action of an acid to accelerate the dissolution in an alkali developer and in addition to the acid-decomposable group (G), preferably contains (S) a dissolution auxiliary group capable of accelerating the dissolution in developer.

The molecular weight is preferably from 700 to 4,000, more preferably from 1,000 to 3,000. If the molecular weight is less than 500, the temperature of baking such as PB and PEB is limited, and the resolution may deteriorate, whereas if the molecular weight exceeds 5,000, the line edge roughness may deteriorate.

The low molecular compound (1) for use in the present invention may be a so-called dendrimer or star polymer but is not a so-called chain polymer obtained by cleaving the unsaturated bond of an unsaturated bond-containing compound (so-called polymerizable monomer) with use of an initiator and growing the bond through a chain reaction.

The low molecular compound (1) for use in the present invention is not particularly limited in its structure as long as the above-described conditions are satisfied, but the preferred embodiment thereof includes a compound represented by the following formula (I-1):

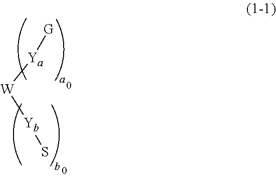

In formula (1-1), W represents an (a₀+b₀)-valent organic group, each of Yₐ and Y_{b} independently represents a single bond or a divalent linking group, G represents an acid-decomposable group capable of decomposing by the action of an acid to accelerate the dissolution in an alkali developer, S is a dissolution auxiliary group capable of accelerating the dissolution in an alkali developer, each of a₀ and b₀ independently represents an integer of 1 to 30, and when the group in the parenthesis is present in a plurality of parentheses, the group in each parenthesis may be the same as or different from the group in every other parentheses.

The carbon number of the organic group represented by W is preferably from 1 to 300, more preferably from 10 to 200.

Each of a₀ and b₀ is preferably from 2 to 20, more preferably from 3 to 10. The ratio (a₀/b₀) between a₀ and b₀ is preferably from 1/10 to 10, more preferably from ⅓ to 3, still more preferably from ½ to 2.

The organic group represented by W preferably contains an aromatic ring. The aromatic ring may be a monocyclic ring such as benzene ring and biphenyl ring, and may be a condensed ring composed of two or more rings, such as naphthalene ring, anthracene ring, phenanthrene ring, fluorene ring, triphenylene ring, naphthacene ring and truxene ring. Such a ring may contain a heteroatom. Examples of the aromatic ring containing a heteroatom include a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthylidine ring, a quinoxaline ring, a quinoxazoline ring, an isoquinoline ring, a carbazole ring, a phenanthridine ring, an acridine ring, a phenanthroline ring, a thianthrene ring, a cumene ring, a xanthene ring, a phenoxathiin ring, a phenothiazine ring and a phenazine ring.

The aromatic ring is preferably a benzene ring or a naphthalene ring.

Preferred examples of the organic group represented by W are illustrated below. In the following specific examples of the organic group represented by W, the organic group has a bond to Yₐ or Y_{b} in formula (1-1) at an arbitrary site denoted by *.

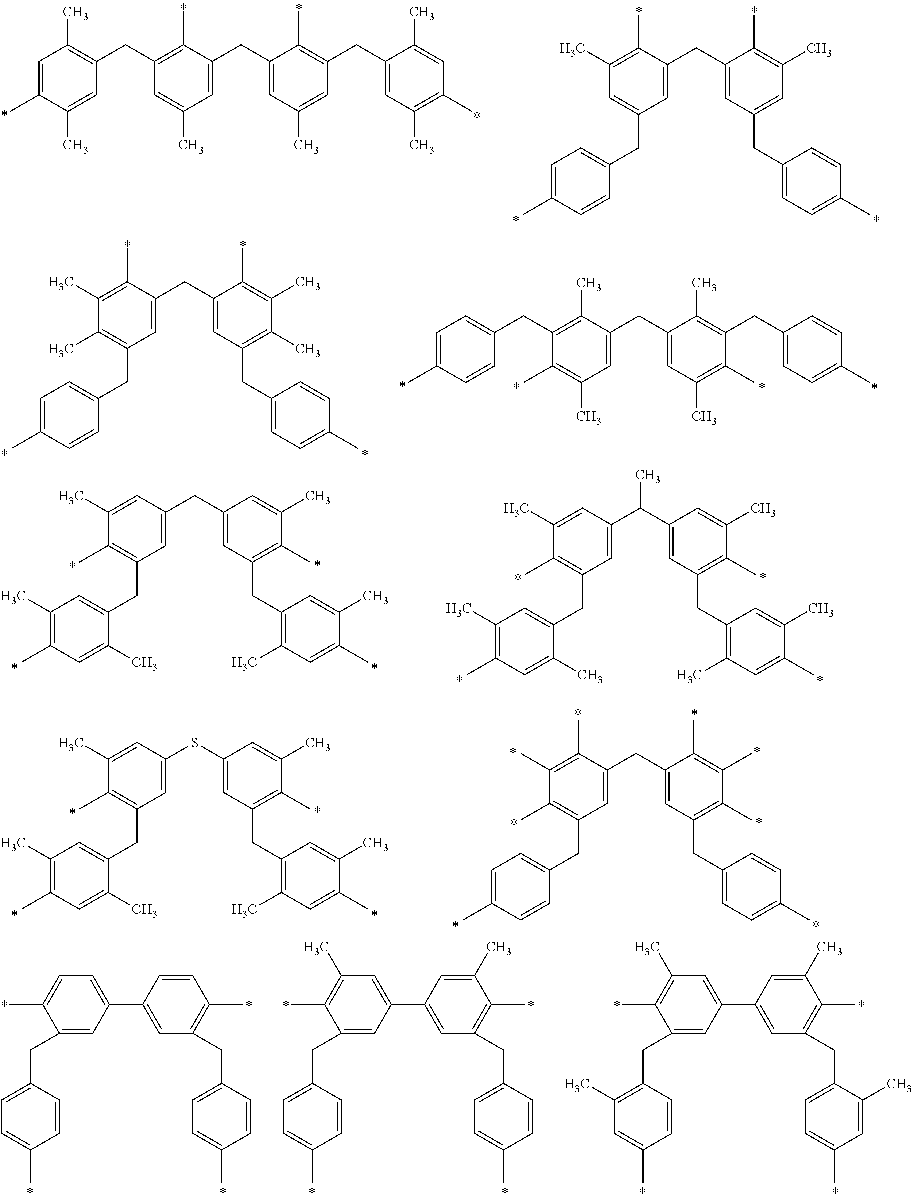

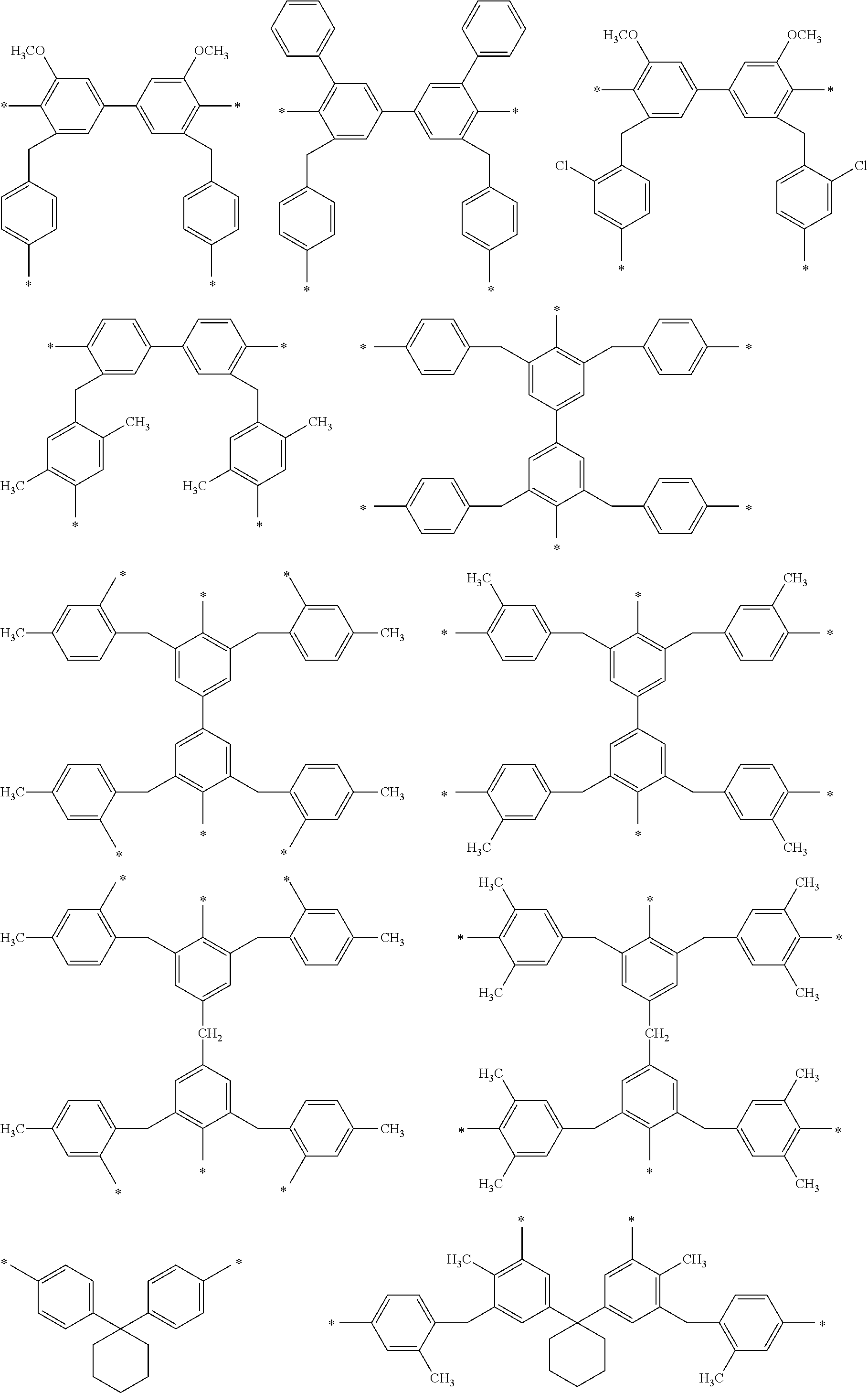

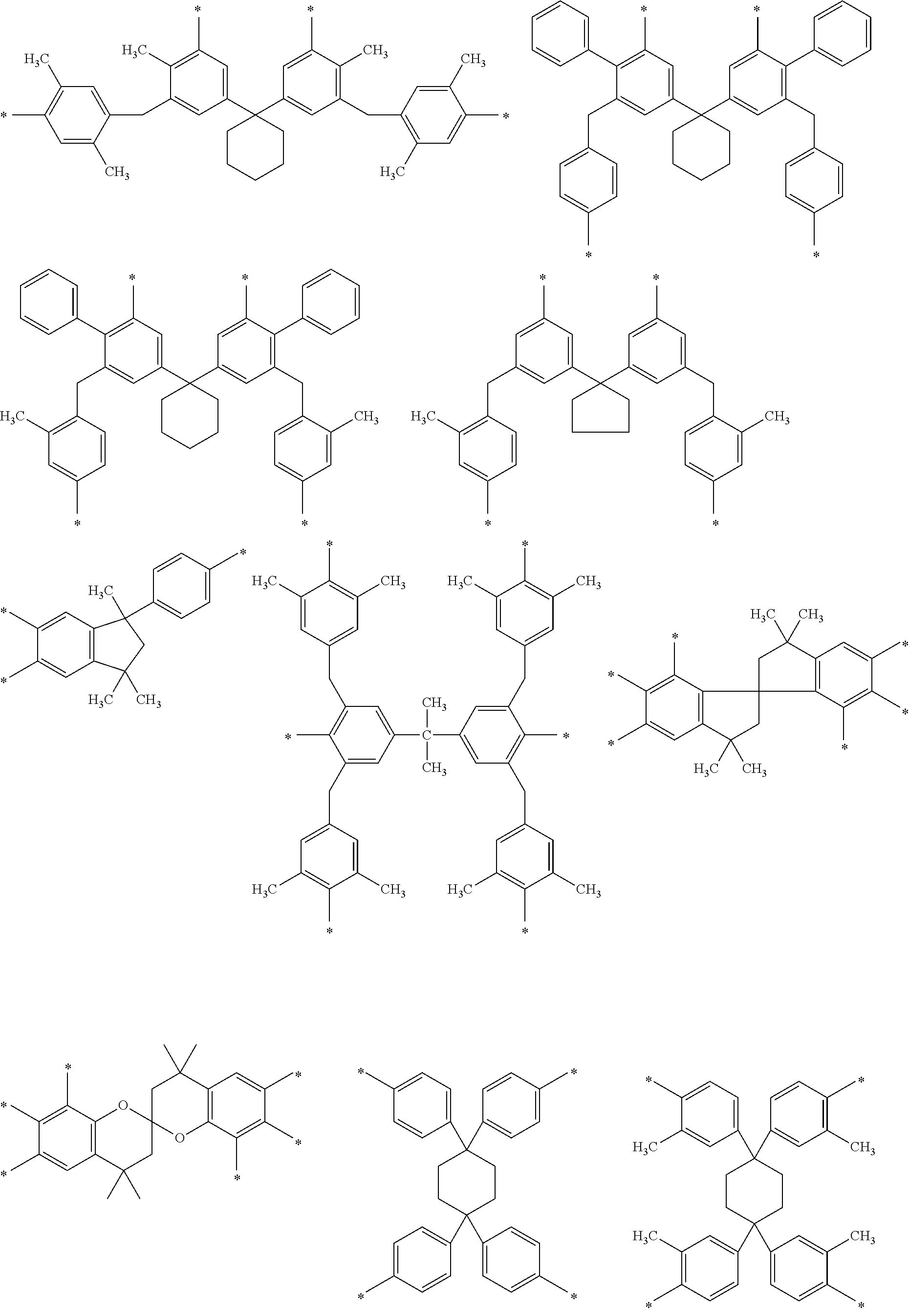

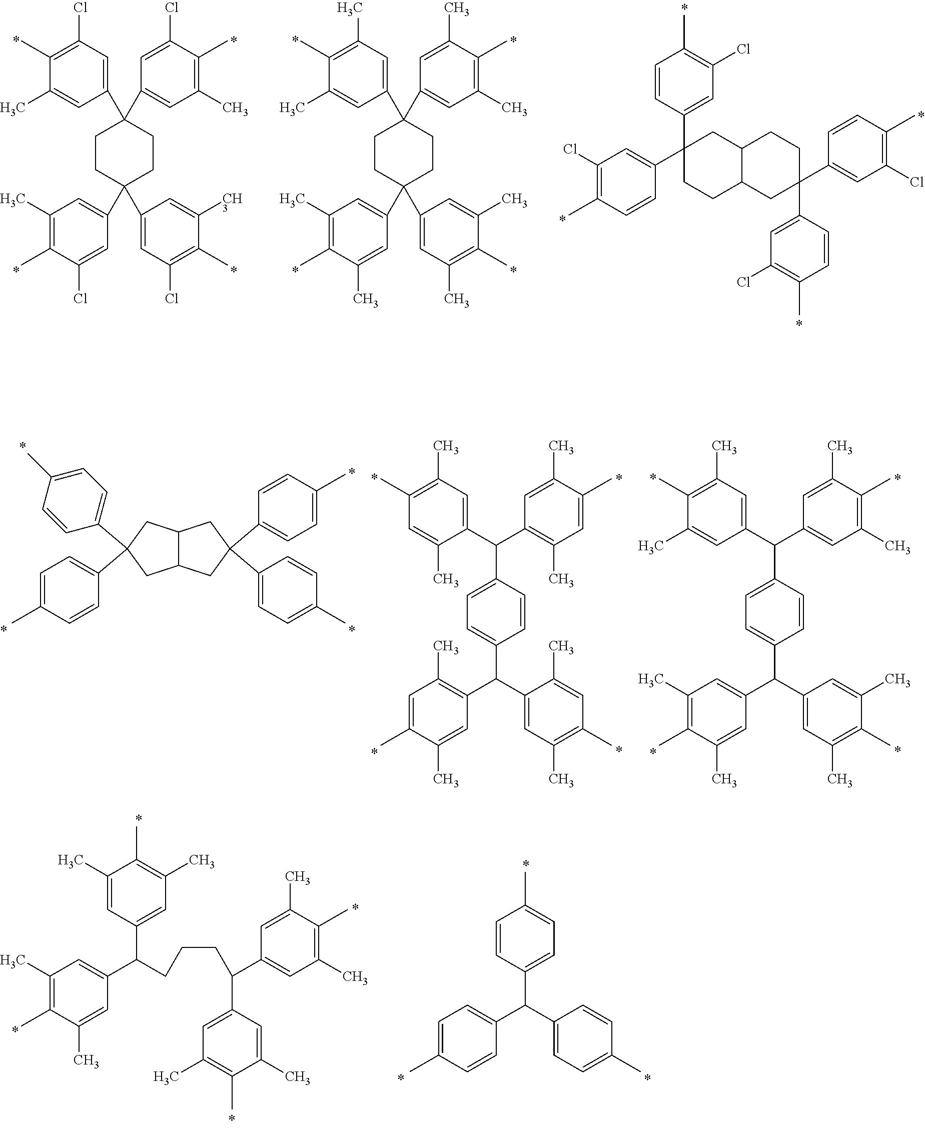

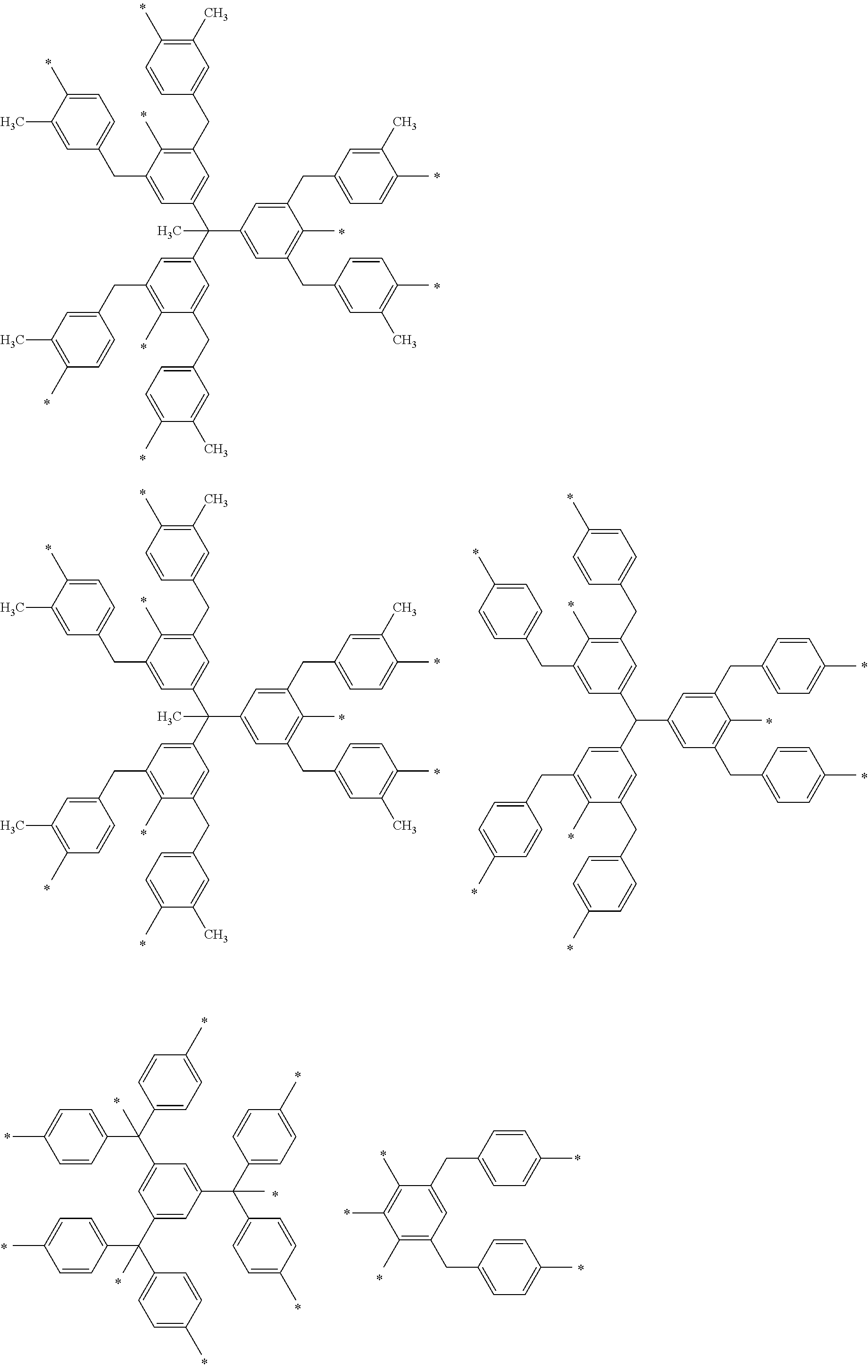

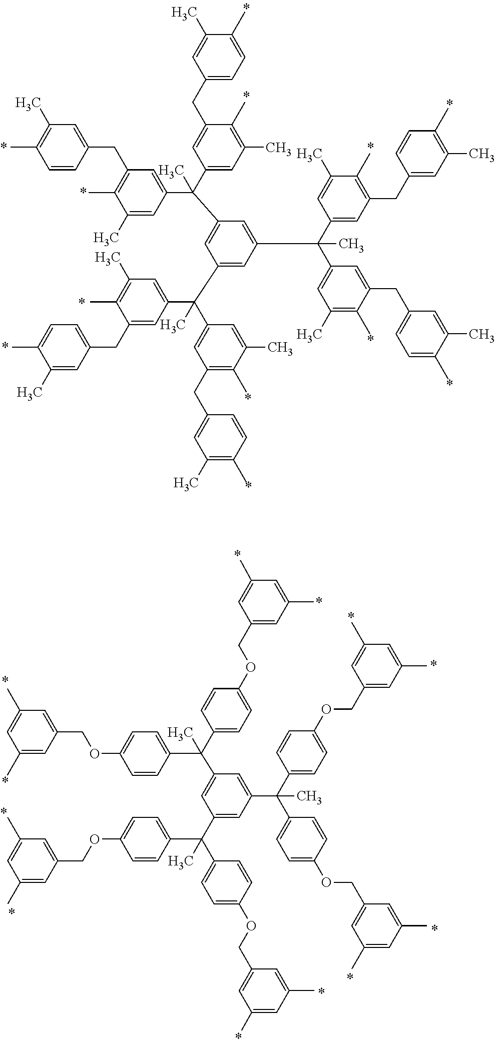

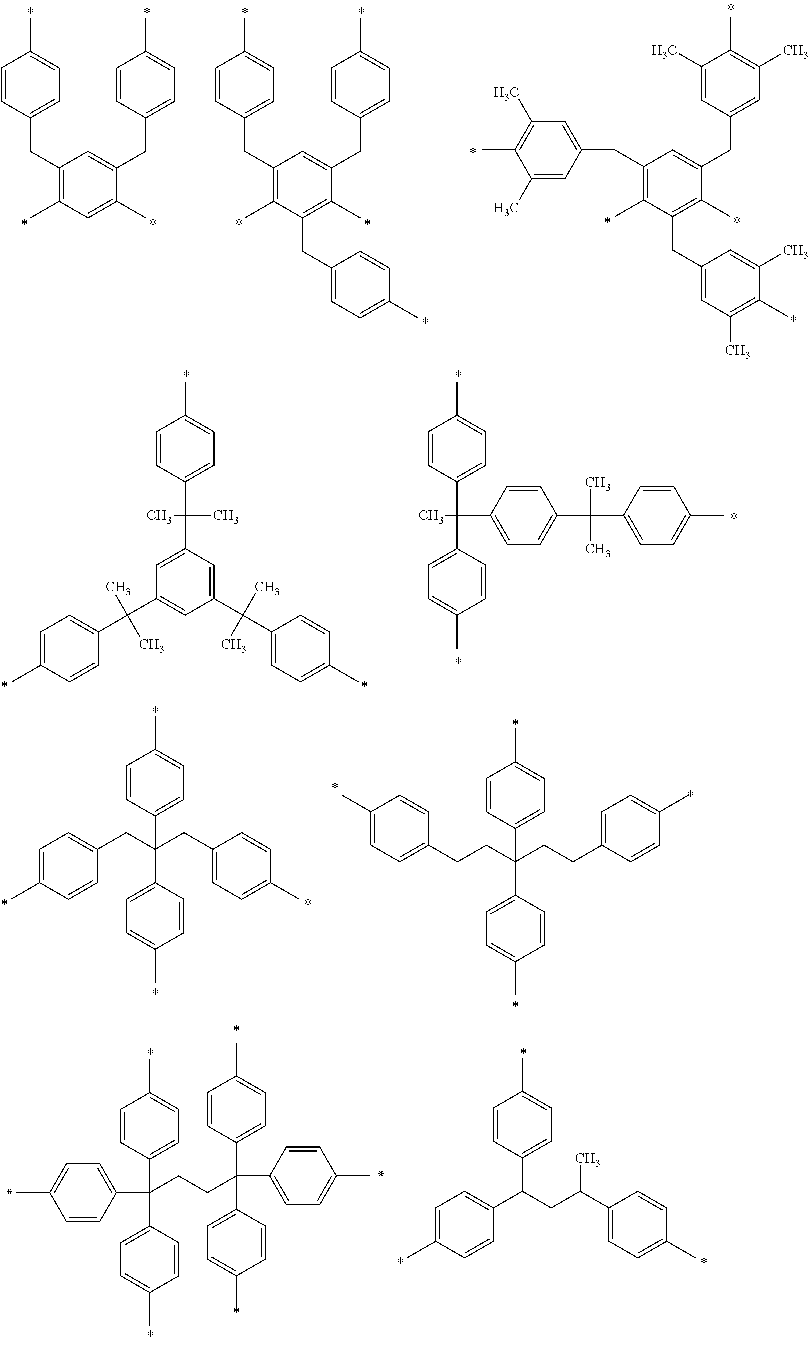

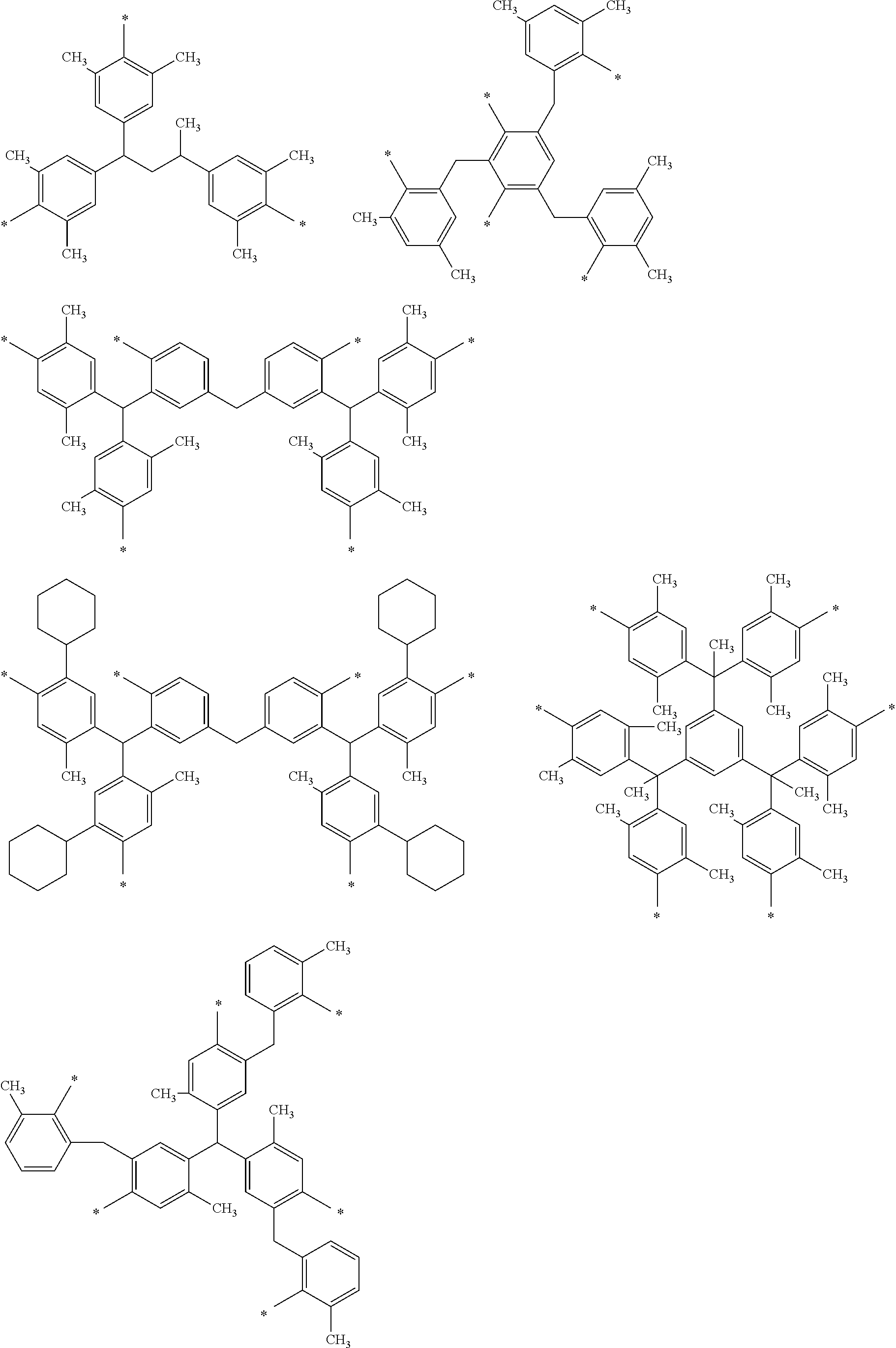

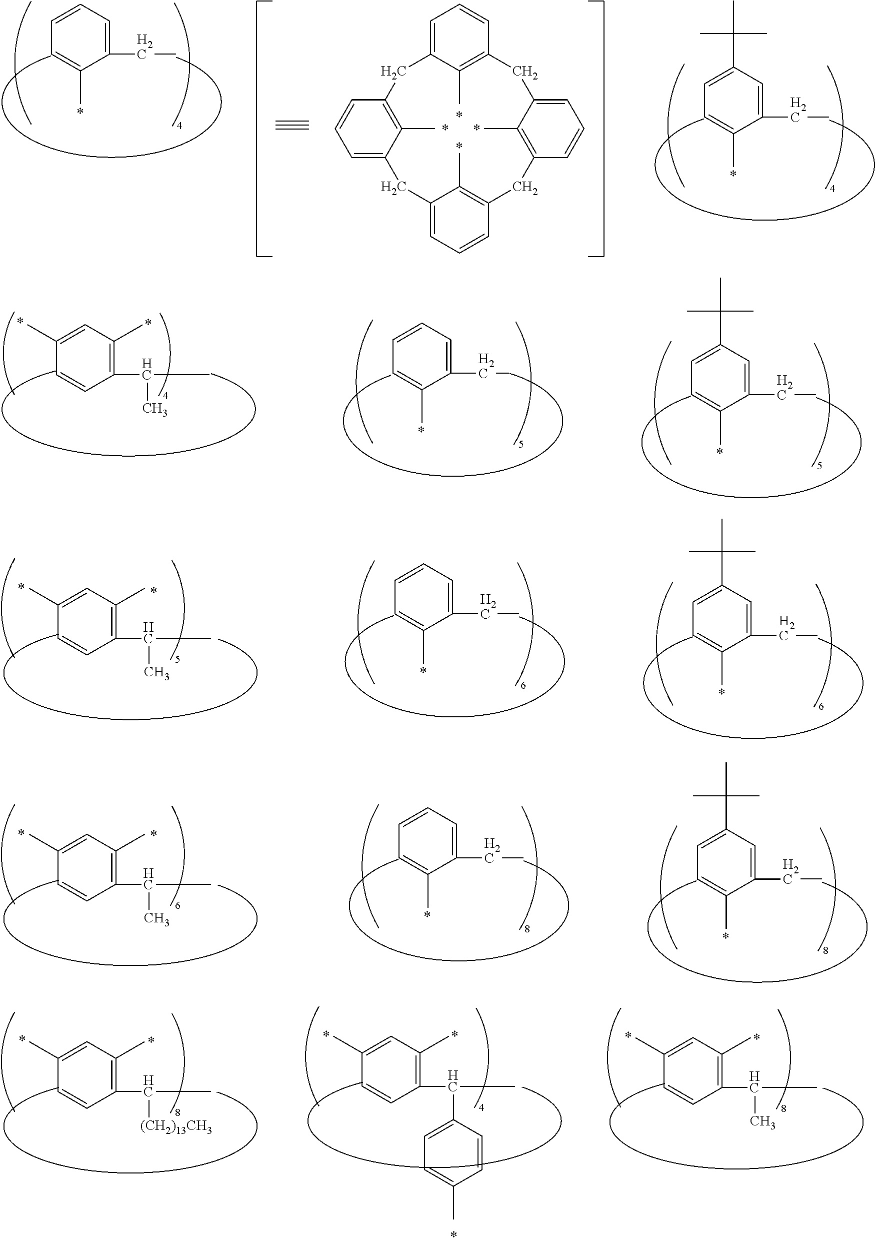

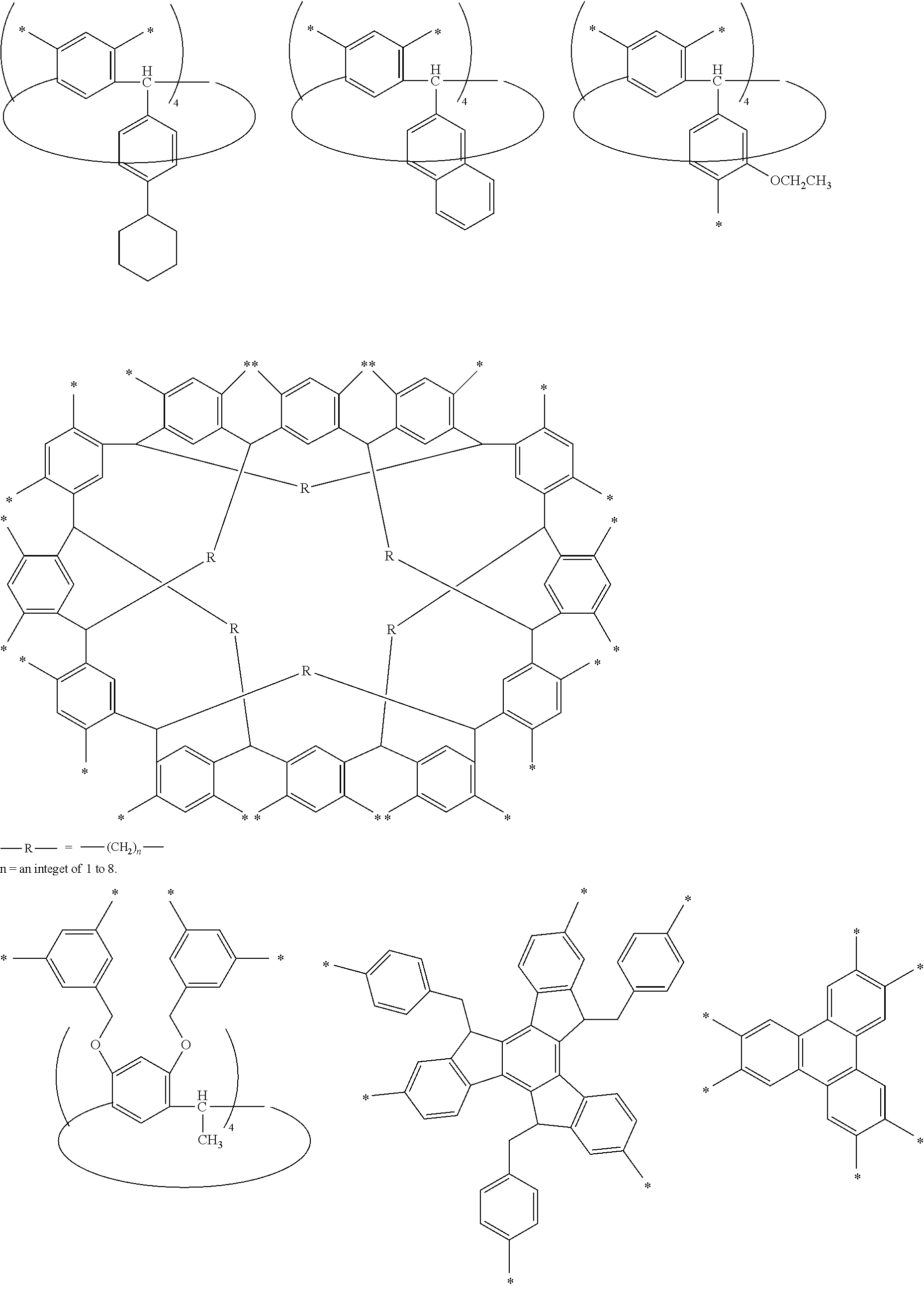

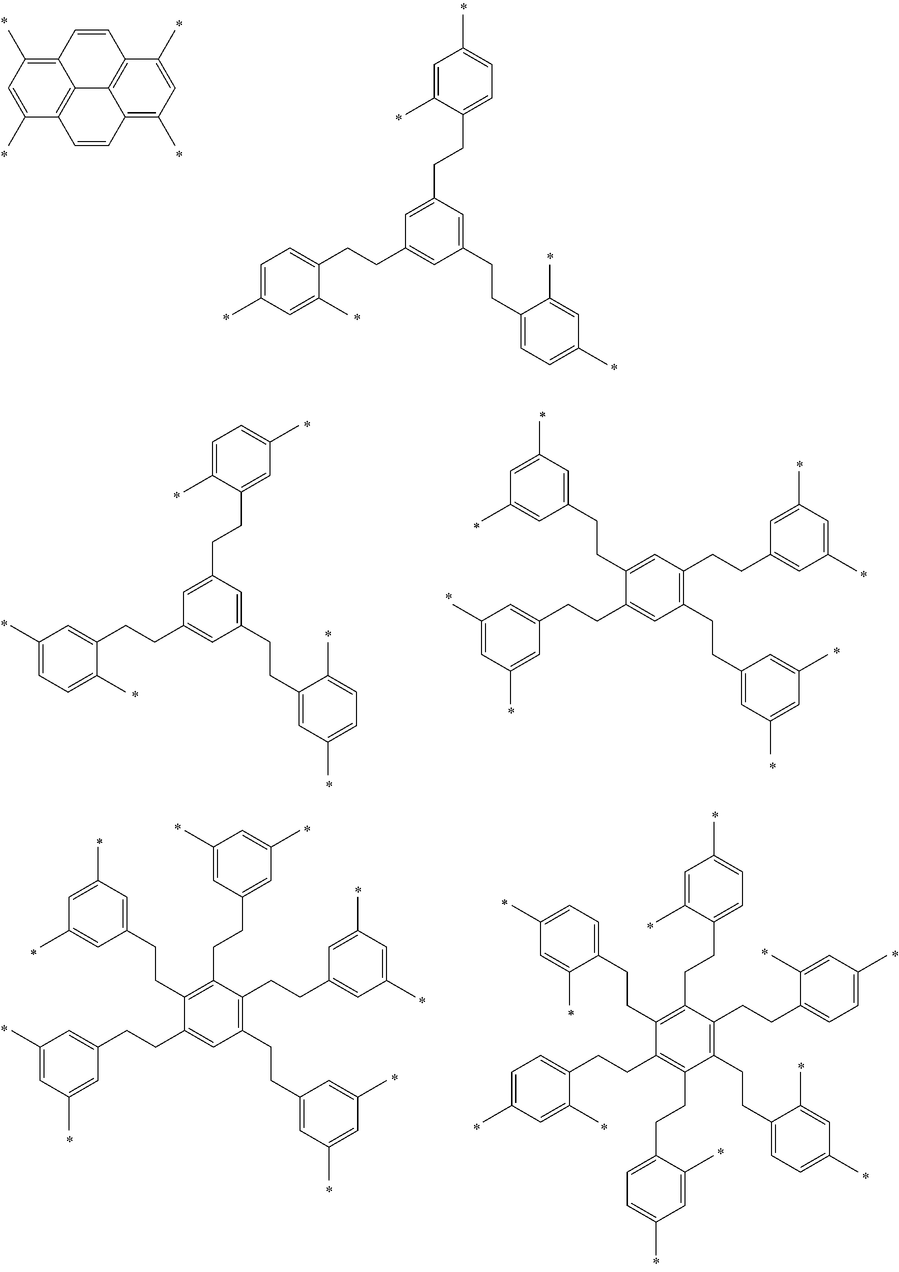

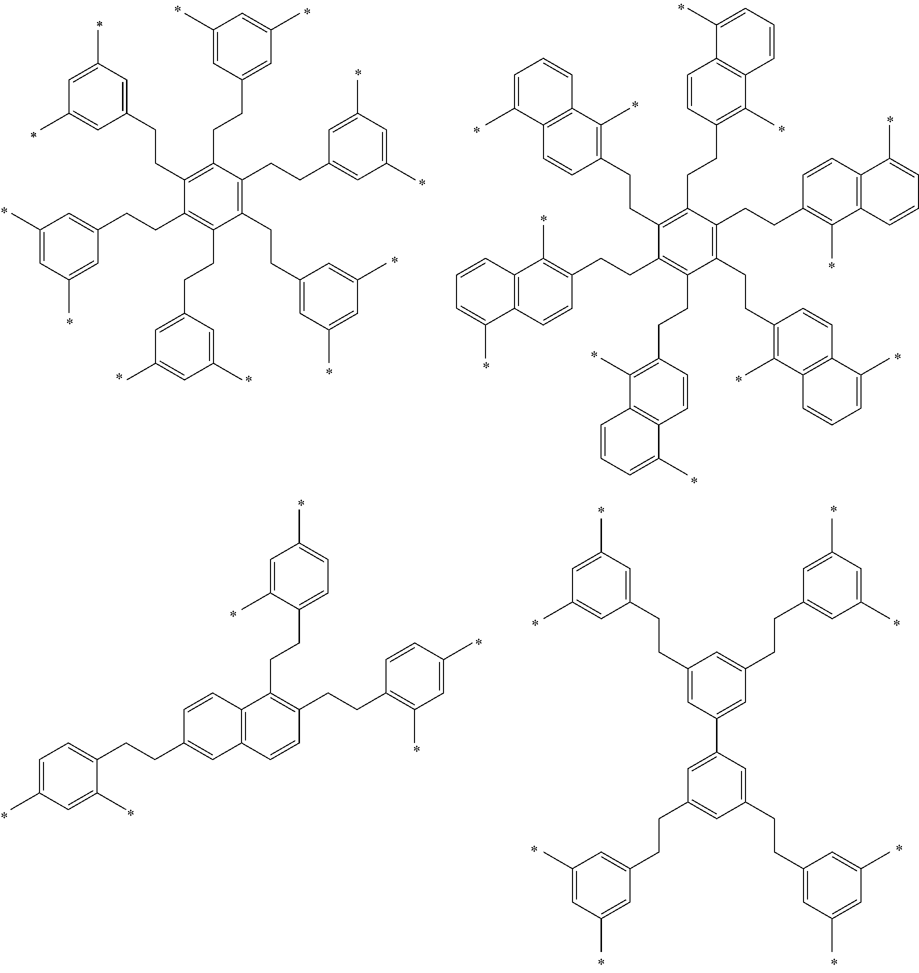

The divalent linking group represented by Yₐ is preferably *—Y₁₁—, *—Y₁₂—, *—Y₁₂—Y₁₁—, *—Y₁₂—C(═O)—Y₁₁—, *—Y₁₂—C(═O)—, *—Y₁₂—SO₂—Y₁₁—, *—C(═O)—Y₁₂—Y₁₁—, *—SO₂—Y₁₂—Y₁₁—, *—Y₁₂—C(═O)—Y₁₂′-Y₁₁— or an arbitrary combination thereof. Here, * represents a site bonded to W, Y₁₁ represents a substituted or unsubstituted alkylene group having a carbon number of 1 to 20, a substituted or unsubstituted cycloalkylene group having a carbon number of 3 to 20, a substituted or unsubstituted arylene group having a carbon number of 6 to 20, or a substituted or unsubstituted aralkylene group having a carbon number of 7 to 20, each of Y₁₂ and Y₁₂′ independently represents an oxygen atom, a sulfur atom or N(Ry), and Ry represents a substituted or unsubstituted alkyl group having a carbon number of 1 to 20, a substituted or unsubstituted cycloalkyl group having a carbon number of 3 to 20, a substituted or unsubstituted aryl group having a carbon number of 6 to 20, or a substituted or unsubstituted aralkyl group having a carbon number of 7 to 20.

The divalent linking group represented by Y_{b} is preferably *—Y₂₁—, *—Y₂₂—Y₂₁—, *—Y₂₂—C(═O)—Y₂₁—, *—Y₂₂—SO₂—Y₂₁—, *—C(═O)—Y₂₂—Y₂₁—, *—SO₂—Y₂₂—Y₂₁—, *—Y₂₂—C(═O)—Y₂₂′-Y₂₁— or an arbitrary combination thereof. Here, * represents a site bonded to W, Y₂₁ represents a substituted or unsubstituted alkylene group having a carbon number of 1 to 20, a substituted or unsubstituted cycloalkylene group having a carbon number of 3 to 20, a substituted or unsubstituted arylene group having a carbon number of 6 to 20, or a substituted or unsubstituted aralkylene group having a carbon number of 7 to 20, each of Y₂₂ and Y₂₂′ independently represents an oxygen atom, a sulfur atom or N(Ry), and Ry represents a substituted or unsubstituted alkyl group having a carbon number of 1 to 20, a substituted or unsubstituted cycloalkyl group having a carbon number of 3 to 20, a substituted or unsubstituted aryl group having a carbon number of 6 to 20, or a substituted or unsubstituted aralkyl group having a carbon number of 7 to 20.

Examples of the substituent which each of the groups above may have include a nitro group, a halogen atom (fluorine atom, chlorine atom, bromine atom, iodine atom), an amino group, a cyano group, a hydroxyl group, an alkoxy group (preferably having a carbon number of 1 to 15), a cycloalkyl group (preferably having a carbon number of 3 to 15), an aryl group (preferably having a carbon number of 6 to 15), an alkoxycarbonyl group (preferably having a carbon number of 2 to 15), an acyl group (preferably having a carbon number of 2 to 15), an acylamino group (preferably having a carbon number of 2 to 15), a carbamoyl group (preferably having a carbon number of 1 to 15), a sulfonylamino group (preferably having a carbon number of 2 to 15), and a sulfamoyl group (preferably having a carbon number of 1 to 15). As for the aryl group and the ring structure in each group, examples of the substituent further include an alkyl group (preferably having a carbon number of 1 to 15).

### [(G) Acid-Decomposable Group Capable of Decomposing by the Action of an Acid to Accelerate the Dissolution in an Alkali Developer]

G represents an acid-decomposable group capable of decomposing by the action of an acid to accelerate the dissolution in an alkali developer and is, for example, a group obtained by protecting an alkali-soluble group such as carboxyl group and hydroxyl group with a group capable of leaving by the action of an acid, and acid-decomposable groups represented by the following formulae (G11) and (G12) are preferred.

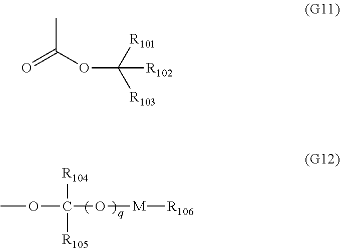

In formula (G11), R₁₀₁ represents an alkyl group, each of R₁₀₂ and R₁₀₃ independently represents a hydrogen atom, an alkyl group, a cycloalkyl group or an aryl group, and R₁₀₂ and R₁₀₃ may combine with each other to form a ring, provided that R₁₀₂ and R₁₀₃ are not a hydrogen atom at the same time. In the case where either one of R₁₀₂ and R₁₀₃ is a hydrogen atom, the other is an aryl group.

The alkyl group of R₁₀₁ to R₁₀₃ is preferably an alkyl group having a carbon number of 1 to 20, more preferably an alkyl group having a carbon number of 1 to 10, still more preferably an alkyl group having a carbon number of 1 to 4, such as methyl group, ethyl group, n-propyl group, isopropyl group, n-butyl group, isobutyl group and tert-butyl group.

The cycloalkyl group represented by R₁₀₂ and R₁₀₃ is preferably a cycloalkyl group having a carbon number of 3 to 20 and may be a monocyclic cycloalkyl group such as cyclopentyl group and cyclohexyl group or a polycyclic cycloalkyl group such as norbornyl group, tetracyclodecanyl group, tetracyclododecanyl group and adamantyl group. The ring formed by combining R₁₀₂ and R₁₀₃ with each other is preferably a ring having a carbon number of 3 to 20 and may be a monocyclic ring such as cyclopentyl group and cyclohexyl group or a polycyclic ring such as norbornyl group, tetracyclodecanyl group and tetracyclododecanyl group. In the case where R₁₀₂ and R₁₀₃ combine with each other to form a ring, R₁₀₃ is preferably an alkyl group having a carbon number of 1 to 3, more preferably a methyl group or an ethyl group.

The aryl group represented by R₁₀₂ and R₁₀₃ is preferably an aryl group having a carbon number of 6 to 20, and examples thereof include a phenyl group and a naphthyl group.

In formula (G12), each of R₁₀₄ and R₁₀₅ independently represents a hydrogen atom, an alkyl group, a cycloalkyl group, an aryl group or an aralkyl group, M represents a single bond or a divalent linking group, and R₁₀₆ represents an alkyl group, a cycloalkyl group, an alicyclic group which may contain a heteroatom, an aromatic ring group which may contain a heteroatom, an amino group, an ammonium group, a mercapto group, a cyano group or an aldehyde group.

q represents 0 or 1.

At least two members of R₁₀₄, M and R₁₀₆ may combine to form a ring.

Incidentally, when both R₁₀₄ and R₁₀₅ are a hydrogen atom, q is 1.

The alkyl group represented by R₁₀₄ and R₁₀₅ is preferably an alkyl group having a carbon number of 1 to 10, and specific examples thereof include a methyl group, an ethyl group, a propyl group, an n-butyl group, a sec-butyl group, a hexyl group and an octyl group.

The cycloalkyl group represented by R₁₀₄ and R₁₀₅ is preferably a cycloalkyl group having a carbon number of 3 to 15, and specific examples thereof include a cyclopentyl group, a cyclohexyl group, a norbornyl group and an adamantyl group.

The aryl group represented by R₁₀₄ and R₁₀₅ is preferably an aryl group having a carbon number of 6 to 15, and specific examples thereof include a phenyl group, a tolyl group, a naphthyl group and an anthryl group.

The aralkyl group represented by R₁₀₄ and R₁₀₅ is preferably an aralkyl group having a carbon number of 6 to 20, and specific examples thereof include a benzyl group and a phenethyl group.

The divalent linking group represented by M is, for example, an alkylene group (e.g., methylene, ethylene, propylene, butylene, hexylene, octylene), a cycloalkylene group (e.g., cyclopentylene, cyclohexylene), an alkenylene group (e.g., ethylene, propenylene, butenylene), an arylene group (e.g., phenylene, tolylene, naphthylene), —S—, —O—, —CO—, —SO₂—, —N(R₀)—, or a divalent linking group formed by combining a plurality of these members. R₀ is a hydrogen atom or an alkyl group (for example, an alkyl group having a carbon number of 1 to 8, and specific examples thereof include a methyl group, an ethyl group, a propyl group, an n-butyl group, a sec-butyl group, a hexyl group and an octyl group).

The alkyl group and cycloalkyl group represented by R₁₀₆ have the same meanings as those described above for R₁₀₄ and R₁₀₅.

Examples of the alicyclic group and aromatic ring group in the alicyclic group which may contain a heteroatom and the aromatic ring group which may contain a heteroatom, represented by R₁₀₆, include the cycloalkyl group and aryl group as R₁₀₄ and R₁₀₅, and the alicyclic or aromatic ring preferably has a carbon number of 3 to 15.

Examples of the alicyclic group containing a heteroatom and the aromatic ring group containing a heteroatom include a group having a heterocyclic structure, such as thiirane, cyclothiolane, thiophene, furan, pyrrole, benzothiophene, benzofuran, benzopyrrole, triazine, imidazole, benzimidazole, triazole, thiadiazole, thiazole and pyrrolidone, but as long as it has a structure generally called a heterocyclic ring (a ring formed from carbon and a heteroatom or a ring formed from a heteroatom), the alicyclic or aromatic ring group is not limited thereto.

As for the ring which may be formed by combining at least two members of R₁₀₄, M and R₁₀₆, there is included a case where at least two members of R₁₀₄, M and R₁₀₆ combine to form, for example, a propylene group or a butylene group, thereby forming a ring containing an oxygen atom. The ring is preferably a 5- or 6-membered ring.

The group represented by -M-R₁₀₆ is preferably a group composed of 1 to 30 carbon atoms, more preferably a group composed of 5 to 20 carbon atoms.

Incidentally, when G is an acid-decomposable group represented by formula (G12), W or Yₐ bonded directly to G is preferably an aromatic group.

Each of the groups above may have a substituent, and examples of the substituent include a nitro group, a halogen atom (fluorine atom, chlorine atom, bromine atom, iodine atom), an amino group, a cyano group, a hydroxyl group, an alkoxy group (preferably having a carbon number of 1 to 15), a cycloalkyl group (preferably having a carbon number of 3 to 15), an aryl group (preferably having a carbon number of 6 to 15), an alkoxycarbonyl group (preferably having a carbon number of 2 to 15), an acyl group (preferably having a carbon number of 2 to 15), an acylamino group (preferably having a carbon number of 2 to 15), a carbamoyl group (preferably having a carbon number of 1 to 15), a sulfonylamino group (preferably having a carbon number of 2 to 15), and a sulfamoyl group (preferably having a carbon number of 1 to 15). As for the aryl group and the ring structure in each group, examples of the substituent further include an alkyl group (preferably having a carbon number of 1 to 15).

Specific examples of the groups represented by formulae (G11) and (G12) are illustrated below, but the present invention is not limited thereto. * means a bond.

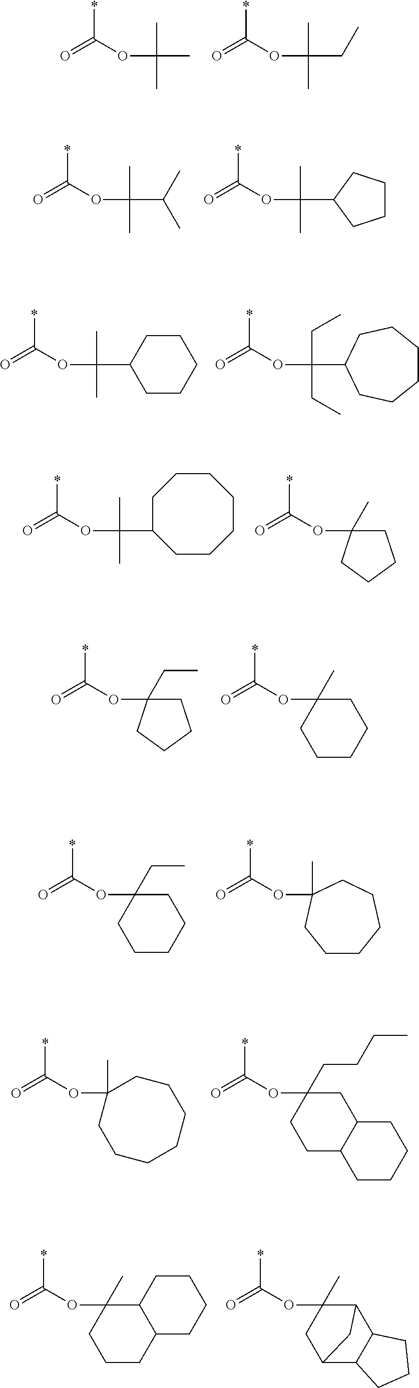

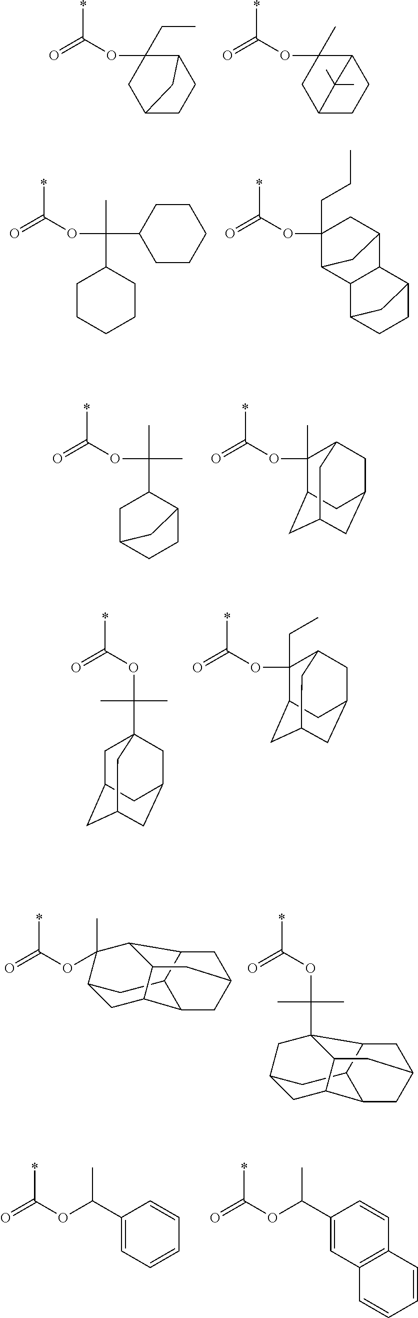

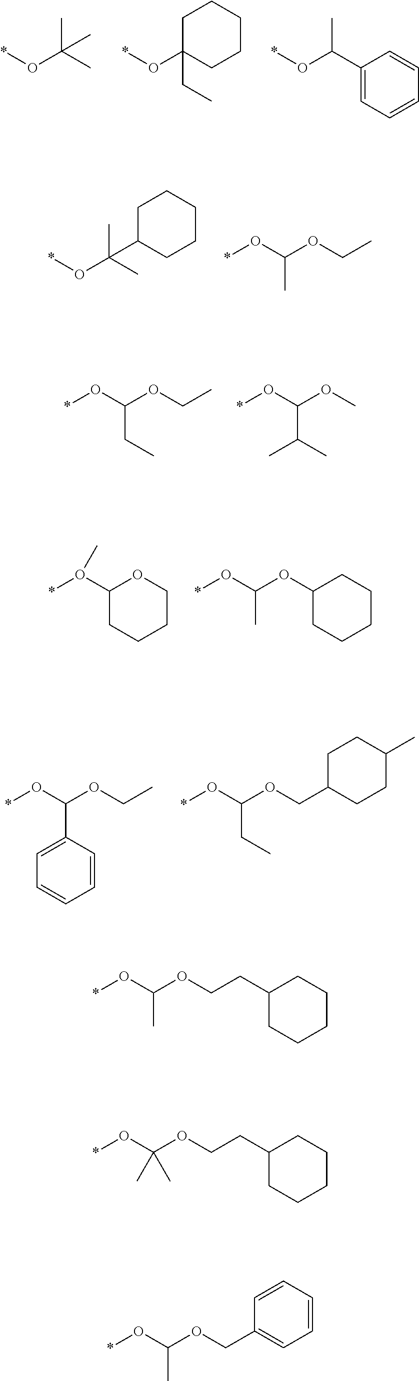

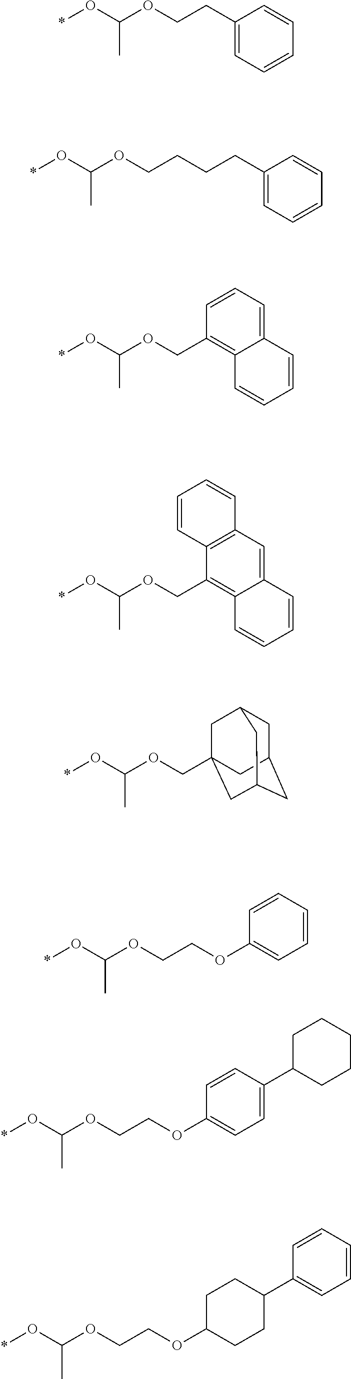

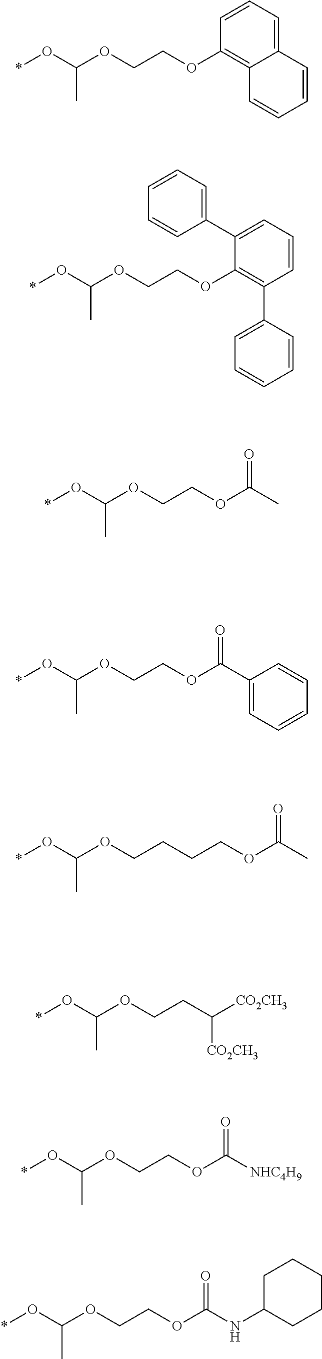

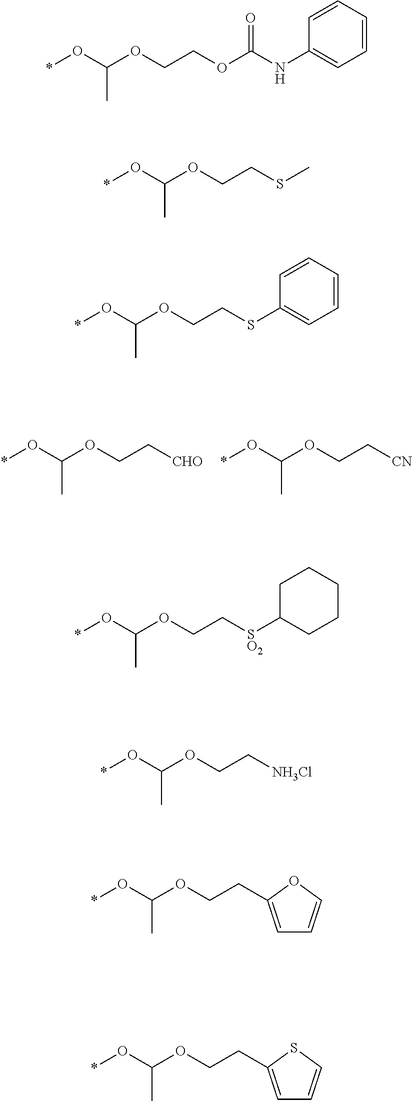

### [(S) Dissolution Auxiliary Group Capable of Accelerating the Dissolution in an Alkali Developer]

The S dissolution auxiliary group capable of accelerating the dissolution in an alkali developer includes a group having solubility in an alkali developer and a group which reacts with an alkali developer to produce a group having solubility in an alkali developer.

Examples of the group having solubility in an alkali developer include a hydroxyl group, a carboxyl group, a sulfonamide group, a disulfonimide group, an acylsulfonylimide group, a diacylimide group and —C(OH)(Rf₁)(Rf₂) [wherein each of Rf₁ and Rf₂ independently represents a perfluoroalkyl group (preferably having a carbon number of 1 to 8)]. As for the configuration of how the hydroxyl group as the group having solubility in an alkali developer is present, a hydroxyl group substituted directly on the aromatic ring is preferred, and a hydroxyl group substituted directly on the benzene or naphthalene ring is more preferred.

The group which reacts with an alkali developer to produce a group having solubility in an alkali developer is preferably a group having a lactone structure.

As for the group having a lactone structure, any group may be used as long as it has a lactone structure, but the lactone structure is preferably a 5- to 7-membered ring lactone structure, and a 5- to 7-membered ring lactone structure forming a condensed ring with another ring structure in the form of forming a bicyclo or Spiro structure is preferred. A group having a lactone structure represented by any one of the following formulae (LC1-1) to (LC1-17) is more preferred. Among these lactone structures, (LC1-1), (LC1-4), (LC1-5), (LC1-6), (LC1-13) and (LC1-14) are preferred.

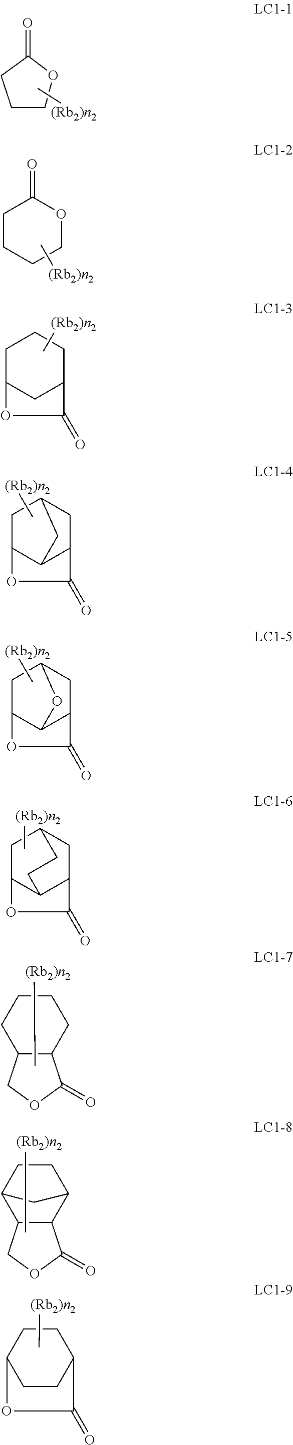

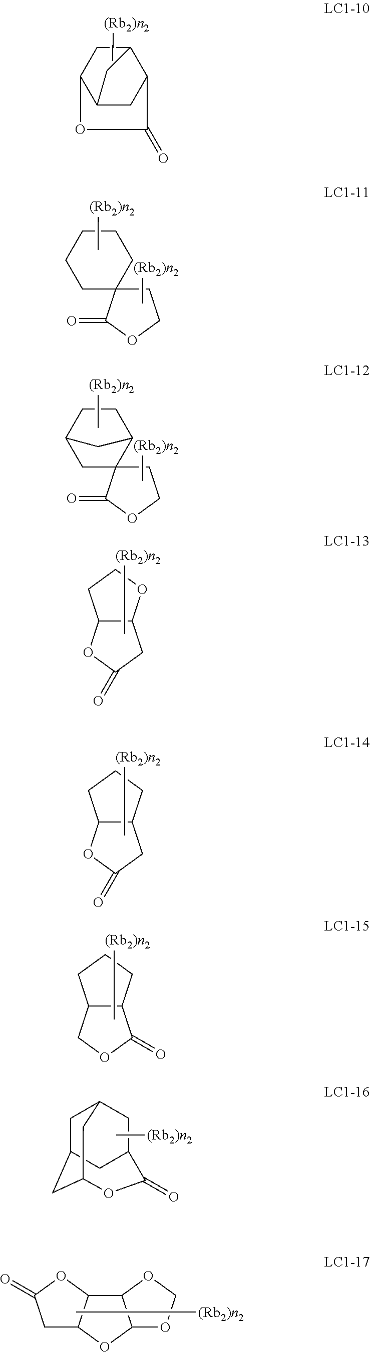

The lactone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 1 to 8, a carboxyl group, a halogen atom, a hydroxyl group, a cyano group and an acid-decomposable group. Among these, an alkyl group having a carbon number of 1 to 4, a cyano group and an acid-decomposable group are more preferred. n₂ represents an integer of 0 to 4. When n₂ is an integer of 2 or more, each substituent (Rb₂) may be the same as or different from every other substituents (Rb₂) and also, the plurality of substituents (Rb₂) may combine with each other to form a ring.

The group having a lactone group usually has an optical isomer, but any optical isomer may be used. One optical isomer may be used alone or a mixture of a plurality of optical isomers may be used. In the case of mainly using one optical isomer, the optical purity (ee) thereof is preferably 90% or more, more preferably 95% or more.

Specific examples of the lactone group are illustrated below, but the present invention is not limited thereto.

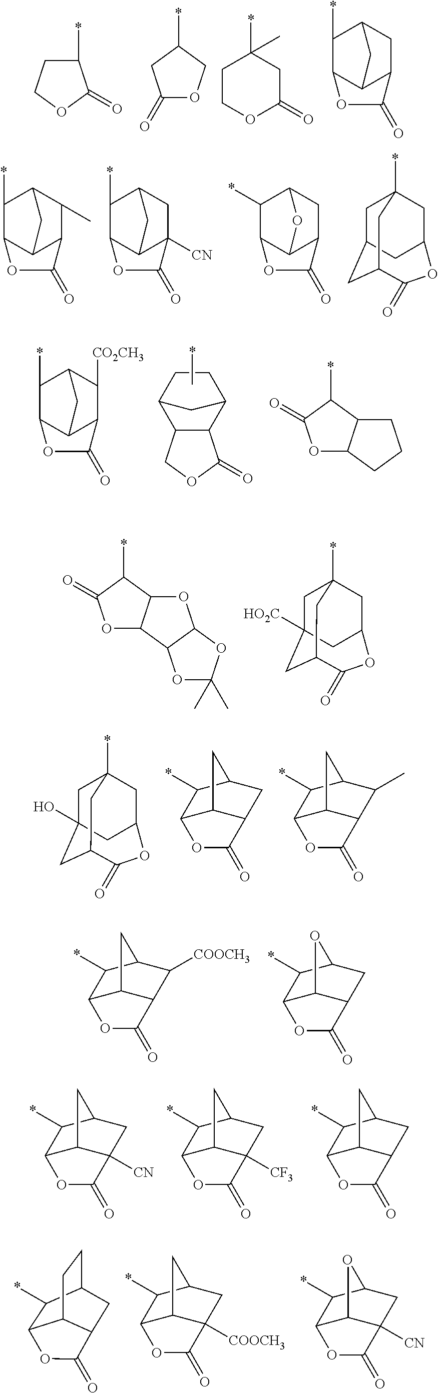

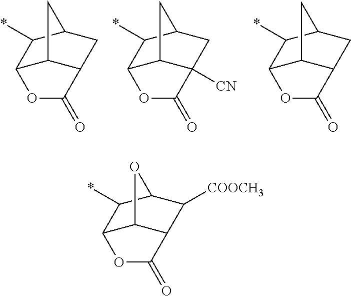

Specific preferred examples of the compound represented by formula (I-1) are illustrated below, but the present invention is not limited thereto.

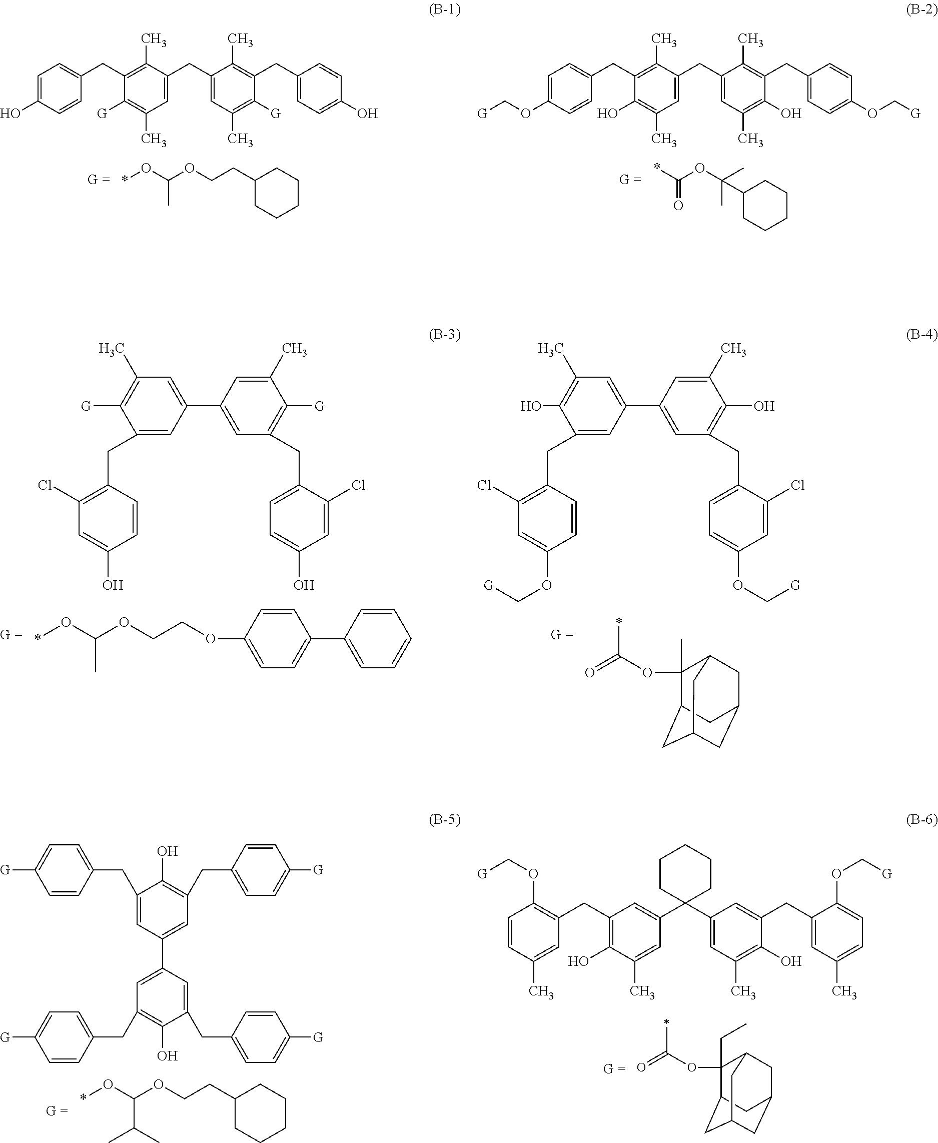

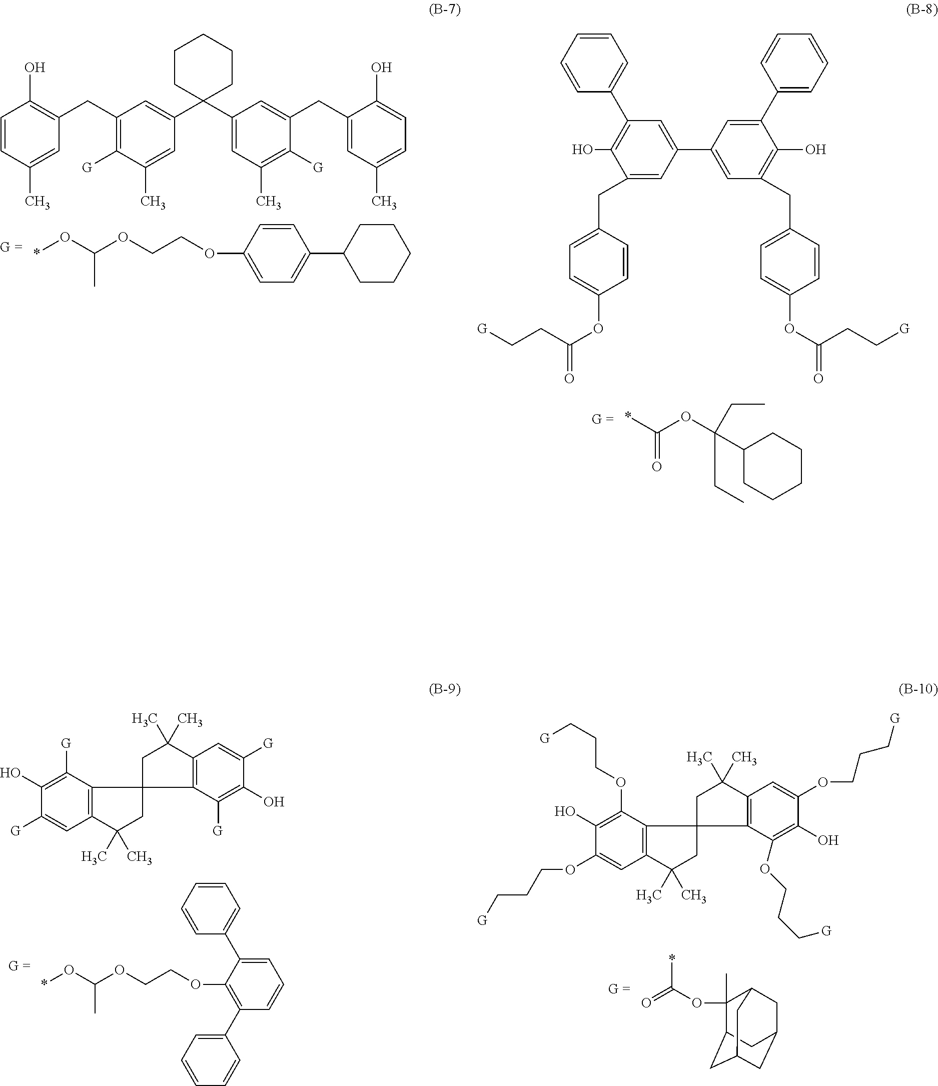

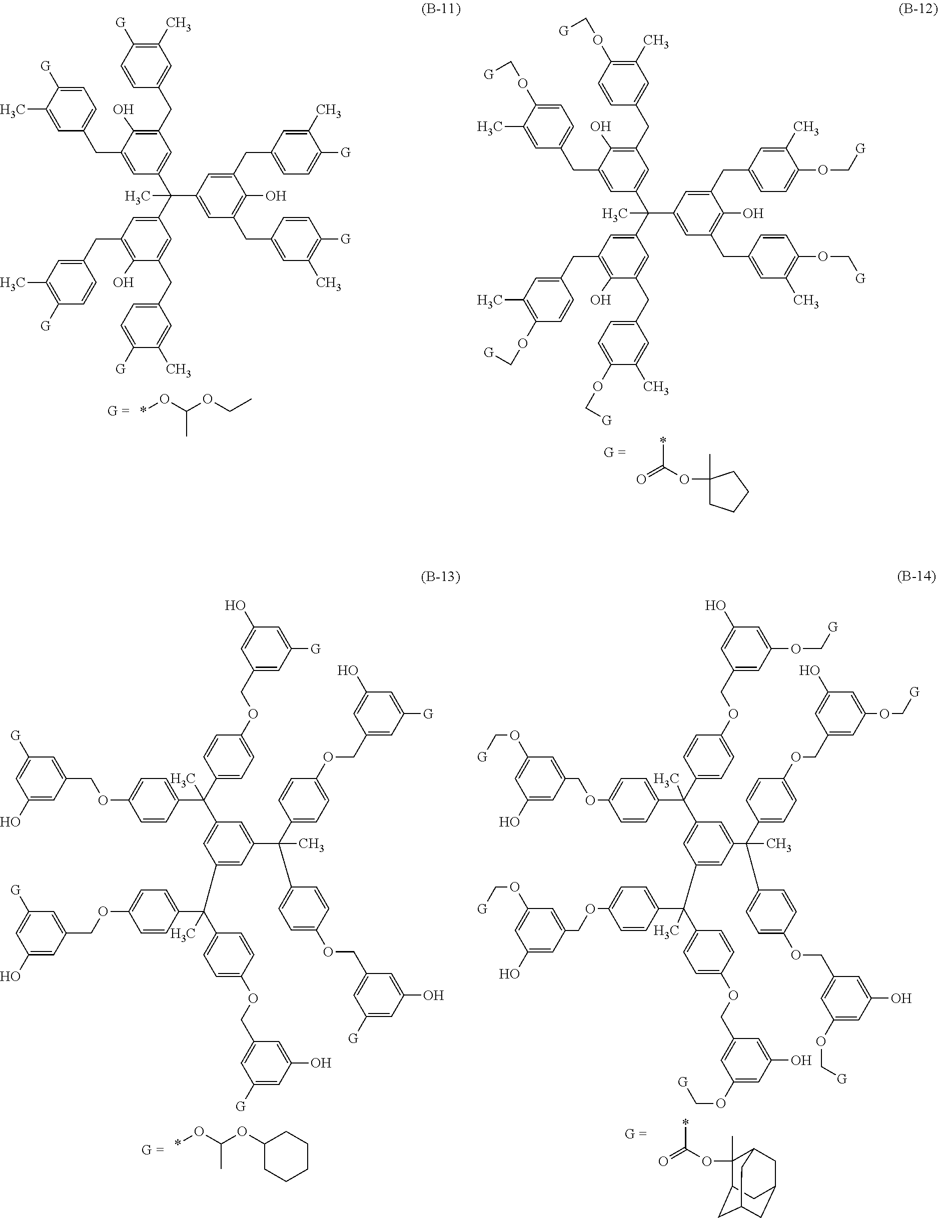

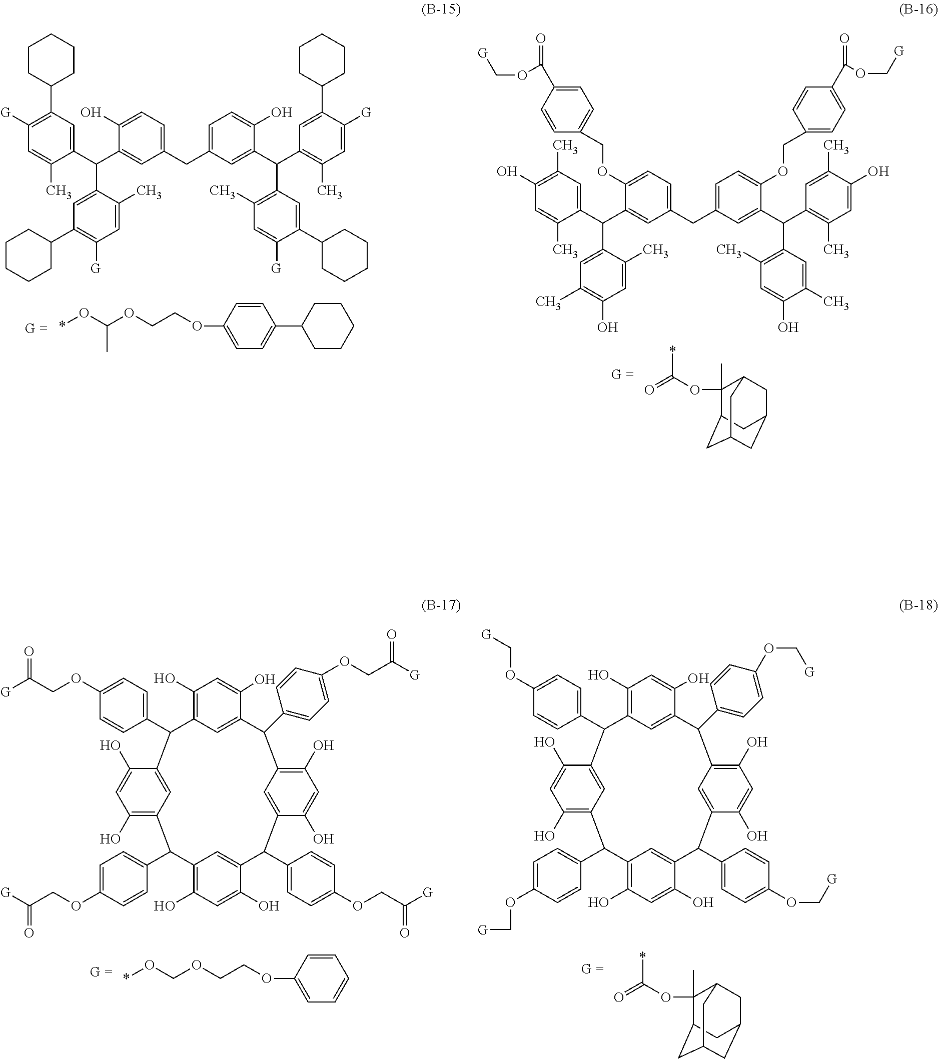

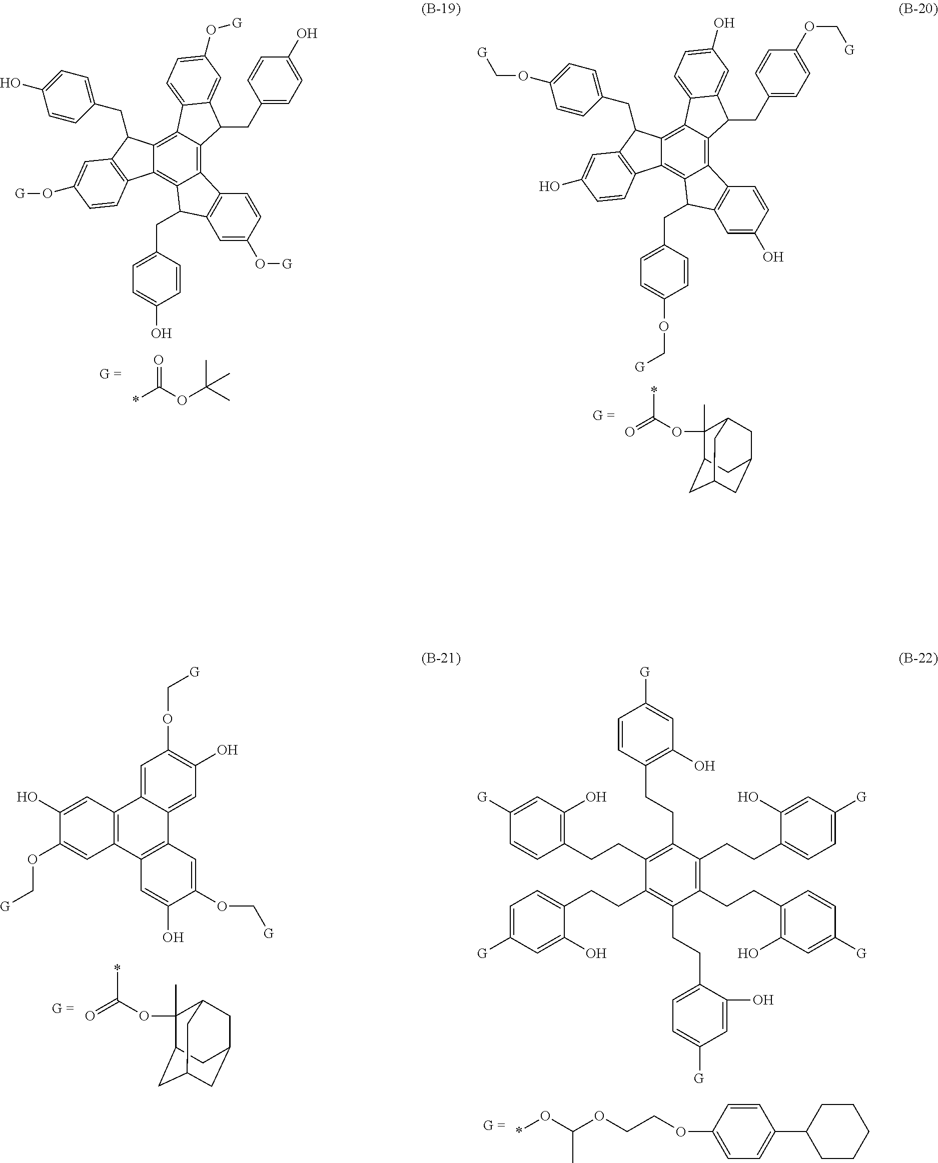

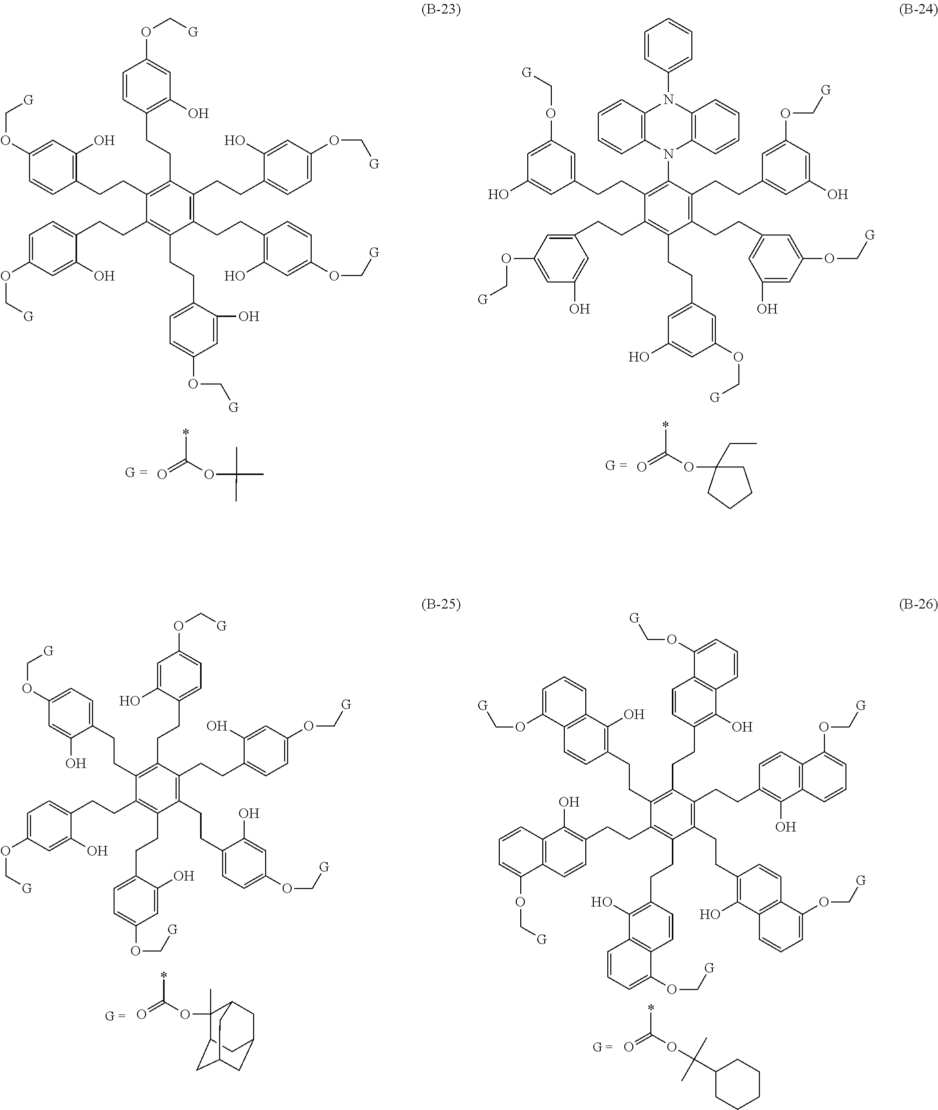

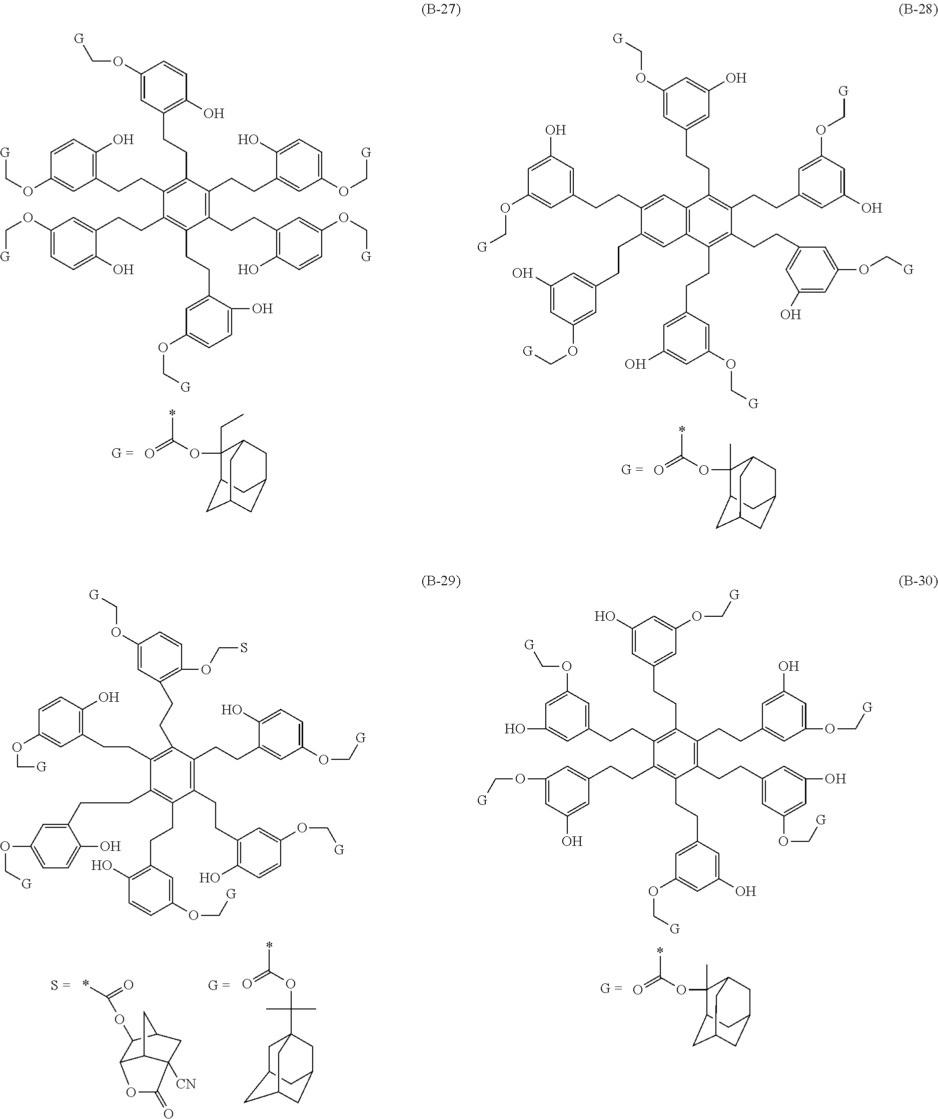

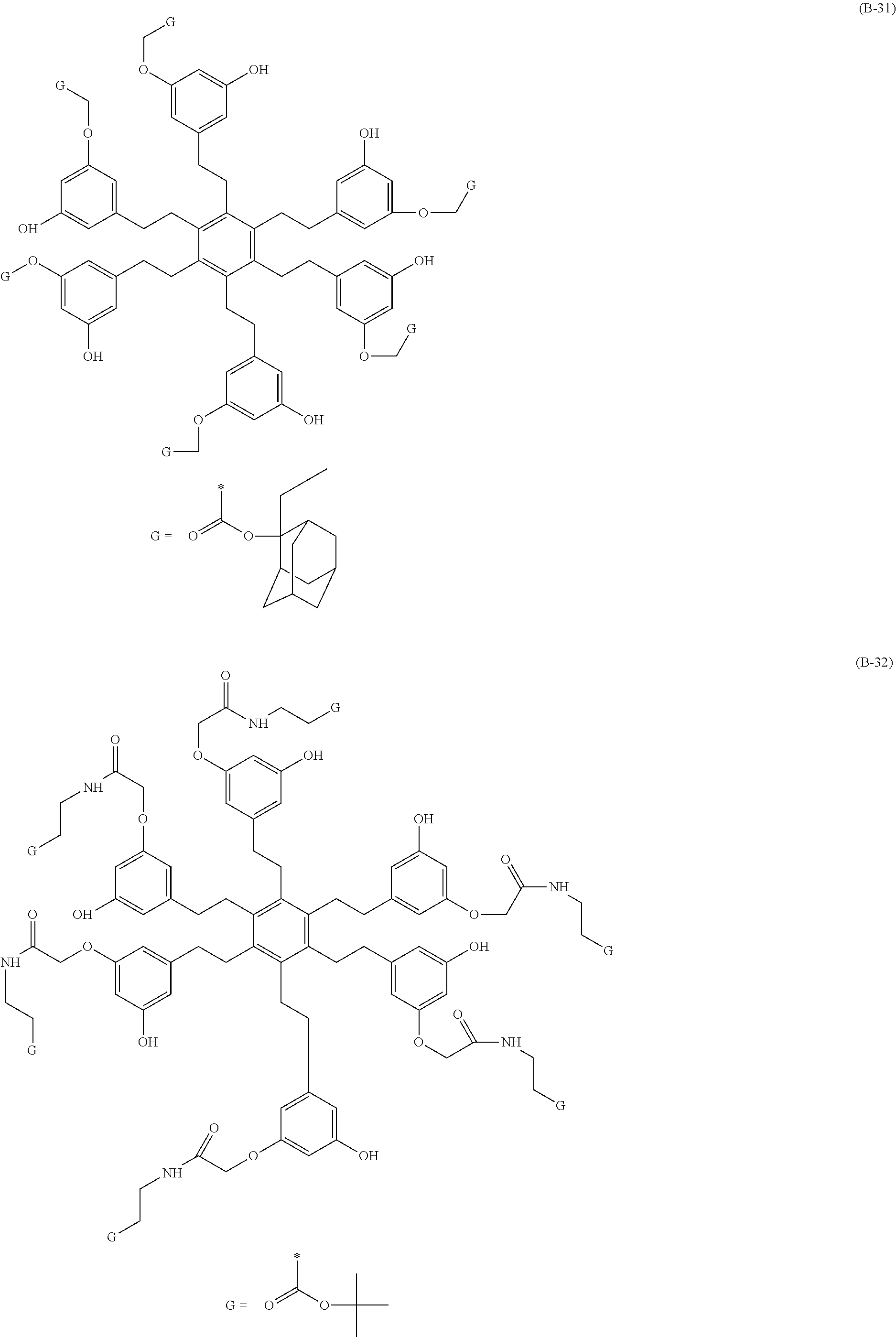

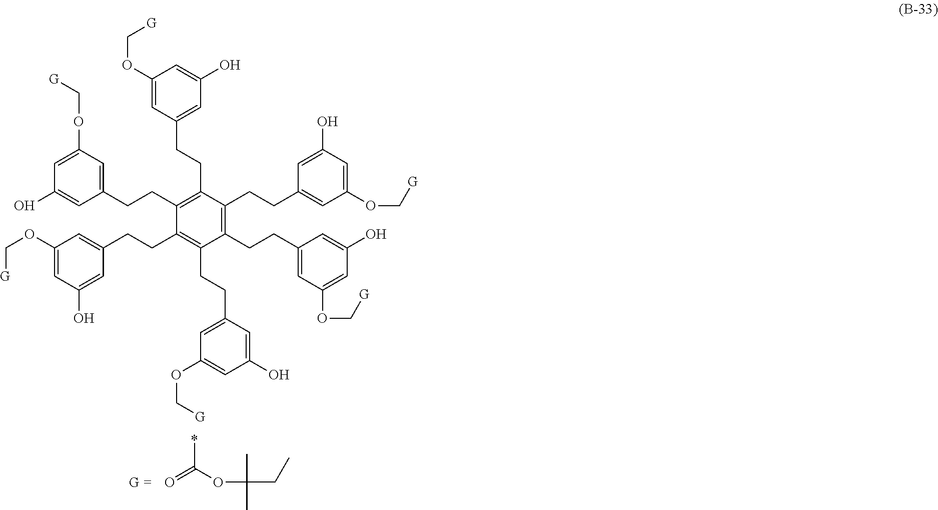

[(2) Compound Capable of Generating an Acid of 305 Å³ or More in Volume Upon Irradiation with an Actinic Ray or Radiation]

The compound capable of generating an acid upon irradiation with an actinic ray or radiation, which is used in the first embodiment of the present invention, is a compound capable of generating an acid of 305 Å³ or more in volume upon irradiation with an actinic ray or radiation (hereinafter sometimes referred to as an “acid generator (2)”). The “volume of an acid” as used herein means the volume of a region occupied by van der Waals spheres based on the van der Waals radius of an atom constituting the acid. More specifically, the “volume of an acid” is a volume computed as follows. That is, the most stable conformation is determined by molecular force field calculation using the MM3 method, and the most stable conformation is then subjected to molecular orbital calculation using the PM3 method to compute a van der Waals volume. This van der Waals volume is defined as the “volume of an acid”.

The acid generator for use in the present invention may be any acid generator as long as the volume of an acid generated upon irradiation with an actinic ray or radiation is 305 Å³ or more as determined by the method above, but the preferred embodiment thereof includes those represented by the following formulae (2-1) and (2-2).

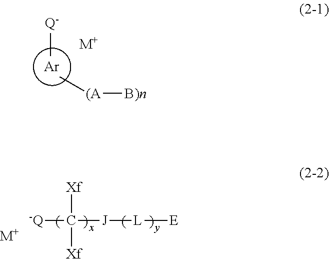

In formula (2-1), Ar represents an aromatic ring and may further have a substituent other than the -(A-B) group, and n represents an integer of 1 or more.

A represents a single bond or a divalent linking group, and preferred examples of the divalent linking group represented by A include a linking group selected from an alkylene group, —O—, —S—, —C(═O)—, —S(═O)₂— and —OS(═O)₂—, and a combination of two or more thereof.

B represents a group containing a hydrocarbon group and preferably has a carbon number of 1 to 30, more preferably from 4 to 30. B preferably represents a group containing a tertiary or quaternary carbon atom-containing hydrocarbon group having a carbon number of 4 to 30. When n is 2 or more, each -(A-B) group may be the same as or different from every other -(A-B) group.

Q⁻ and M⁺ have the same meanings as those in formula (2-2), and these are described in detail later.

The aromatic ring represented by Ar is preferably an aromatic ring having a carbon number of 6 to 30 and may further have a substituent other than the -(A-B) group.

Specific examples of the aromatic ring include a benzene ring, a naphthalene ring, a pentalene ring, an indene ring, an azulene ring, a heptalene ring, an indecene ring, a perylene ring, a pentacene ring, an acenaphthalene ring, a phenanthrene ring, an anthracene ring, a naphthacene ring, a pentacene ring, a chrysene ring, a triphenylene ring, an indene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolidine ring, a quinoline ring, a phthalazine ring, a naphthylidine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring and a phenazine ring. Among these, from the standpoint of both improving the roughness and increasing the sensitivity, a benzene ring, a naphthalene ring and an anthracene ring are preferred, and a benzene ring is more preferred.

In the case where the aromatic ring further has a substituent other than the -(A-B) group, examples of the substituent include a halogen atom such as fluorine atom, chlorine atom, bromine atom iodine atom, an alkoxy group such as methoxy group, ethoxy group and tert-butoxy group, an aryloxy group such as phenoxy group and p-tolyloxy group, an alkylthioxy group such as methylthioxy group, ethylthioxy group and tert-butylthioxy group, an arylthioxy group such as phenylthioxy group and p-tolylthioxy group, an alkoxycarbonyl group such as methoxycarbonyl group, butoxycarbonyl group and phenoxycarbonyl group, an acetoxy group, a linear or branched alkyl group such as methyl group, ethyl group, propyl group, butyl group, heptyl group, hexyl group, dodecyl group and 2-ethylhexyl group, an alkenyl group such as vinyl group, propenyl group and hexenyl group, an alkynyl group such as acetylene group, propynyl group and hexynyl group, an aryl group such as phenyl group and tolyl group, an acyl group such as benzoyl group, acetyl group and tolyl group, a hydroxy group, a carboxy group and a sulfonic acid group. Among these, from the standpoint of improving the roughness, a linear alkyl group and a branched alkyl group are preferred.

In view of resolution and roughness, the atomic number of A is preferably small. A is preferably a single bond, —O— or —S—, more preferably a single bond.

The hydrocarbon group in the group represented by B containing a tertiary or quaternary carbon atom-containing hydrocarbon group having a carbon number of 4 to 30 includes an acyclic hydrocarbon group and a cyclic aliphatic group.

Examples of the tertiary or quaternary carbon atom-containing acyclic hydrocarbon group having a carbon number of 4 to 30 include a tert-butyl group, a tert-pentyl group, a neopentyl group, an s-butyl group, an isobutyl group, an isohexyl group, a 3,3-dimethylpentyl group and a 2-ethylhexyl group. The acyclic hydrocarbon group is preferably an acyclic hydrocarbon group having a carbon number of 5 to 20 and may have a substituent.

Examples of the cyclic aliphatic group having a carbon number of 4 to 30 include a cycloalkyl group such as cyclobutyl group, cyclopentyl group, cyclohexyl group, cycloheptyl group and cyclooctyl group, an adamantyl group, a norbornyl group, a bornyl group, a camphanyl group, a decahydronaphthyl group, a tricyclodecanyl group, a tetracyclodecanyl group, a camphoroyl group, a dicyclohexyl group, and a pinenyl group. The cyclic aliphatic group is preferably a cyclic aliphatic group having a carbon number of 5 to 20 and may have a substituent.

In the case where the acyclic hydrocarbon group or cyclic aliphatic group has a substituent, examples of the substituent include a halogen atom such as fluorine atom, chlorine atom, bromine atom iodine atom; an alkoxy group such as methoxy group, ethoxy group and tert-butoxy group; an aryloxy group such as phenoxy group and p-tolyloxy group; an alkylthioxy group such as methylthioxy group, ethylthioxy group and tert-butylthioxy group; an arylthioxy group such as phenylthioxy group and p-tolylthioxy group; an alkoxycarbonyl group such as methoxycarbonyl group and butoxycarbonyl group; an aryloxycarbonyl group such as phenoxycarbonyl group; an acetoxy group; a linear or branched alkyl group such as methyl group, ethyl group, propyl group, butyl group, heptyl group, hexyl group, dodecyl group and 2-ethylhexyl group; a cyclic alkyl group such as cyclohexyl group; an alkenyl group such as vinyl group, propenyl group and hexenyl group; an alkynyl group such as acetylene group, propynyl group and hexynyl group; an aryl group such as phenyl group and tolyl group; a hydroxy group, a carboxy group, a sulfonic acid group and a carbonyl group. Among these, from the standpoint of both improving the roughness and increasing the sensitivity, a linear or branched alkyl group is preferred.

Specific examples of the group having a cyclic aliphatic group or an acyclic hydrocarbon group are illustrated below. In the formulae, * indicates the bonding site to A (when A is a single bond, to Ar).

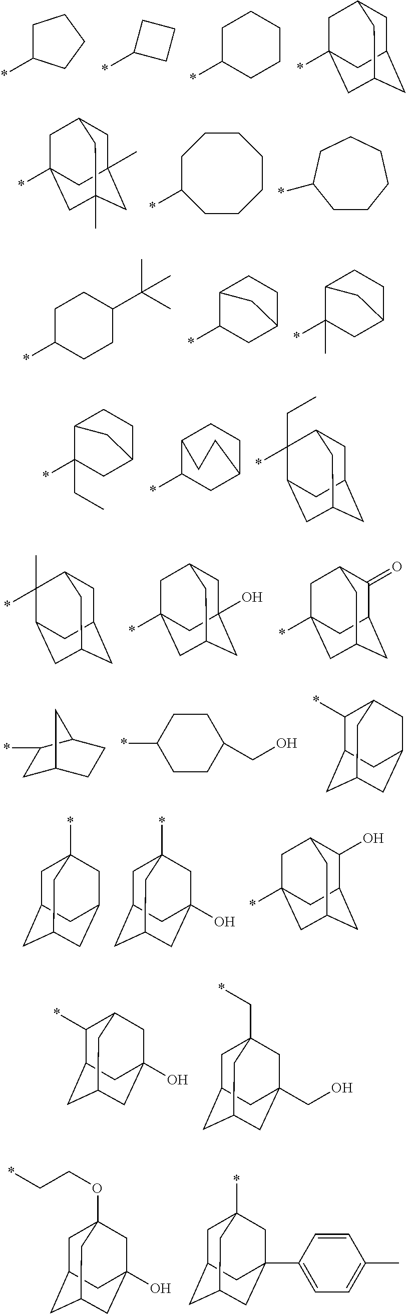

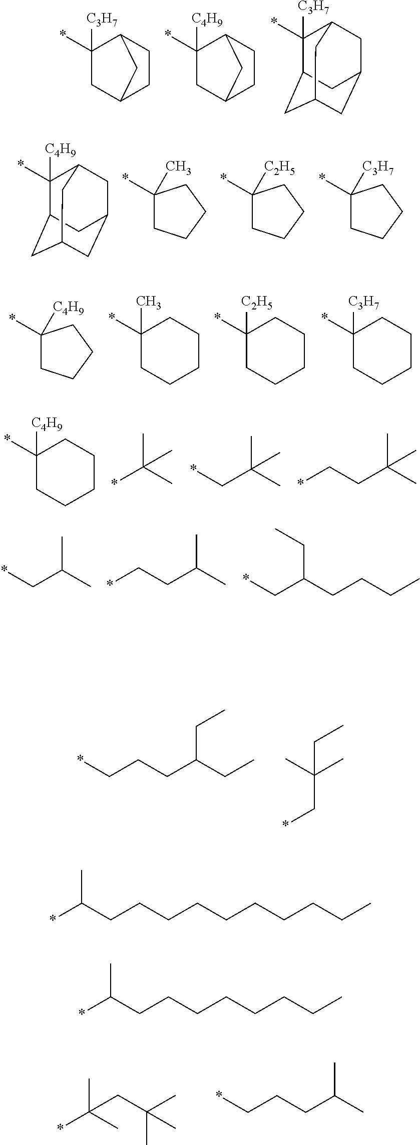

Among these, the structures shown below are preferred.

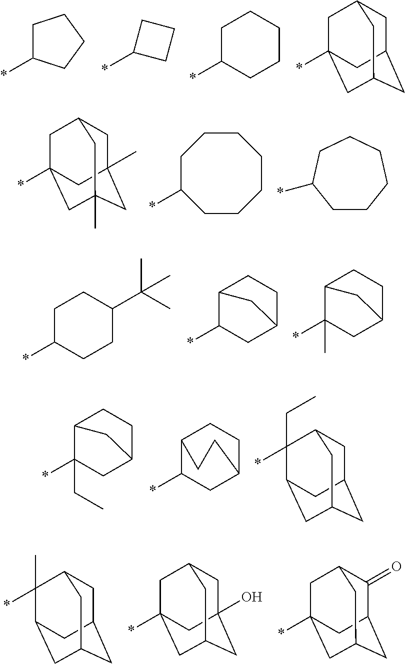

In view of resolution and roughness, the group represented by B containing a tertiary or quaternary carbon atom-containing hydrocarbon group having a carbon number of 4 or more is preferably a cyclic aliphatic group. Among the cyclic aliphatic groups described above, from the standpoint of improving the roughness, a cycloalkyl group, an adamantyl group and a norbornyl group are preferred, a cycloalkyl group is more preferred, and out of the cycloalkyl group, a cyclohexyl group is most preferred.

n represents an integer of 1 or more and from the standpoint of improving the roughness, is preferably an integer of 2 to 5, more preferably from 2 to 4, and most preferably n=3.

The -(A-B) group is preferably substituted on at least one o-position, more preferably substituted on two o-positions, with respect to the substitution position of Q⁻.

Formula (2-2) is described below.

In formula (2-2), each Xf independently represents a fluorine atom or an alkyl group substituted with at least one fluorine atom.

J represents a single bond, a linear, branched or cyclic alkylene group which may contain an ether oxygen, an arylene group, or a group comprising a combination of these groups, and the groups combined may be connected through an oxygen atom.

The alkylene group represented by J is preferably a linear, branched or cyclic alkylene group having a carbon number of 1 to 20, more preferably from 1 to 10 (e.g., methylene, ethylene, propylene, 1,4-cyclohexylene), and a part or all of hydrogen atoms bonded to carbon may be replaced by a fluorine atom. The arylene group represented by J is preferably an arylene group having a carbon number of 6 to 20, more preferably from 6 to 10 (e.g., phenylene, naphthylene), and a part or all of hydrogen atoms bonded to carbon may be replaced by a fluorine atom. Such an alkylene group and/or arylene group may be used alone, or a plurality thereof may be used in combination. In this case, the alkylene groups and/or arylene groups may be combined through an oxygen atom.

L represents a divalent linking group, and when a plurality of L's are present, each L may be the same as or different from every other L.

E represents a group having a ring structure.

x represents an integer of 1 to 20 and is preferably an integer of 1 to 4. y represents an integer of 0 to 10 and is preferably an integer of 0 to 3.

Xf is a fluorine atom or an alkyl group substituted with at least one fluorine atom. The alkyl group is preferably an alkyl group having a carbon number of 1 to 10, more preferably from 1 to 4. Also, the alkyl group substituted with a fluorine atom is preferably a perfluoroalkyl group.

Xf is preferably a fluorine atom or a perfluoroalkyl group having a carbon number of 1 to 4. Specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, more preferably a fluorine atom or CF₃, and most preferably a fluorine atom.

In formula (2-2), each of R₁ and R₂ is a group selected from a hydrogen atom, a fluorine atom, an alkyl group and an alkyl group substituted with at least one fluorine atom. The alkyl group which may be substituted with a fluorine atom is preferably an alkyl group having a carbon number of 1 to 4. The alkyl group substituted with a fluorine atom is preferably a perfluoroalkyl group having a carbon number of 1 to 4, and specific examples thereof include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉. Among these, CF₃ is preferred.

Examples of the divalent linking group represented by L include —COO—, —OCO—, —CO—, —O—, —S—, —SO—, —SO₂—, —N(R)— (wherein R represents a hydrogen atom, a substituted or unsubstituted alkyl group having a carbon number of 1 to 20, a substituted or unsubstituted cycloalkyl group having a carbon number of 3 to 20, a substituted or unsubstituted aryl group having a carbon number of 6 to 20, or a substituted or unsubstituted aralkyl group having a carbon number of 7 to 20), an alkylene group, a cycloalkylene group, an alkenylene group, and a combination thereof. Among these, —COO—, —OCO—, —CO—, —O—, —S—, —SO— and —SO₂— are preferred, and —COO—, —OCO— and —SO₂— are more preferred.

In formula (2-2), E represents a group having a ring structure. Examples of E include an alicyclic group, an aryl group and a heterocyclic structure-containing group.

The alicyclic group as E may have a monocyclic structure or a polycyclic structure. The alicyclic group having a monocyclic structure is preferably a monocyclic cycloalkyl group such as cyclopentyl group, cyclohexyl group and cyclooctyl group. The alicyclic group having a polycyclic structure is preferably a polycyclic cycloalkyl group such as norbornyl group, tricyclodecanyl group, tetracyclodecanyl group, tetracyclododecanyl group and adamantyl group. In particular, when an alicyclic group having a bulky structure of 6-membered or higher membered ring is employed as E, diffusion into the film can be suppressed in the PEB (post-exposure baking) step, and resolution and EL (exposure latitude) can be further enhanced.

Examples of the aryl group as E include a benzene ring, a naphthalene ring, a phenanthrene ring and an anthracene ring.

The heterocyclic structure-containing group as E may or may not have aromaticity. The heteroatom contained in this group is preferably a nitrogen atom or an oxygen atom. Specific examples of the heterocyclic structure include a furan ring, a thiophene ring, a benzofuran ring, a benzothiophene ring, a dibenzofuran ring, a dibenzothiophene ring, a pyridine ring, a piperidine ring and a morpholine ring. Among these, a furan ring, a thiophene ring, a pyridine ring, a piperidine ring and a morpholine ring are preferred.

E may have a substituent. Examples of the substituent include an alkyl group (may be linear, branched or cyclic, preferably having a carbon number of 1 to 12), an aryl group (preferably having a carbon number of 6 to 14), a hydroxy group, an alkoxy group, an ester group, an amido group, a urethane group, a ureido group, a thioether group, a sulfonamido group and a sulfonic acid ester group.

The preferred embodiment of E includes a group represented by the following formula:

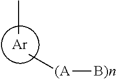

wherein Ar, A, B and n have the same meanings as those in formula (2-1).

In formulae (2-1) and (2-2), Q⁻ represents an anion with pKa of the conjugated acid (QH) being 6 or less. Here, pKa means an acid dissociation constant in water (25° C.).

The preferred embodiment of the anion represented by Q⁻ includes the following anions.

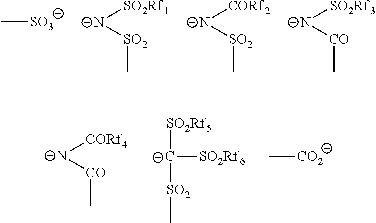

In the formulae, each of Rf₁ to Rf₆ independently represents a linear, branched or cyclic alkyl group having a carbon number of 1 to 20, which may have an ether bond. The carbon number is preferably from 1 to 10, and the alkyl group is preferably an alkyl fluoride group substituted with one or more fluorine atoms, more preferably a perfluoroalkyl group with all hydrogen atoms being replaced by a fluorine atom.

Q⁻ is more preferably a sulfonate anion.

Examples of the acid of 305 Å³ or more in volume, which is generated resulting from decomposition of the acid generator for use in the present invention upon irradiation with an actinic ray or radiation, are illustrated below, but the present invention is not limited thereto.

Incidentally, the computed volume is affixed to each of these examples. This value is determined as follows by using “WinMOPAC” produced by Fujitsu Limited. That is, first, the chemical structure of the acid in each example was input. Then, using this structure as an initial structure, the most stable conformation of each acid was determined by molecular force field calculation using the MM3 method. Thereafter, with respect to the most stable conformation, molecular orbital calculation using the PM3 method was performed to compute the “accessible volume” of each acid.

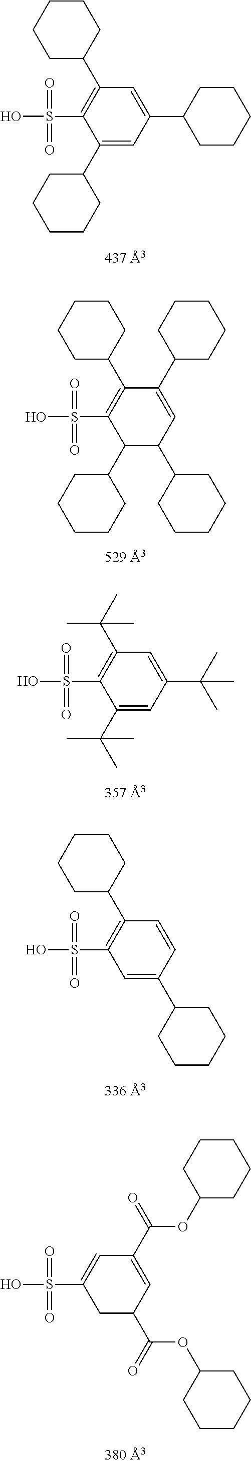

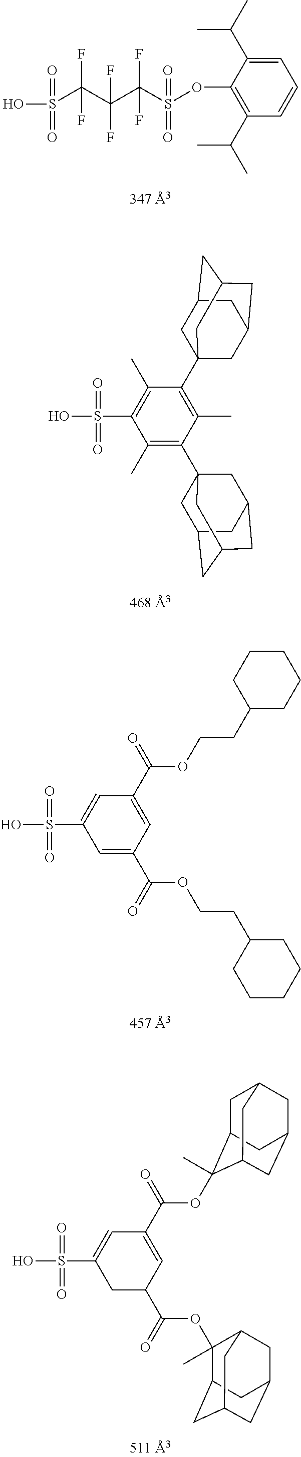

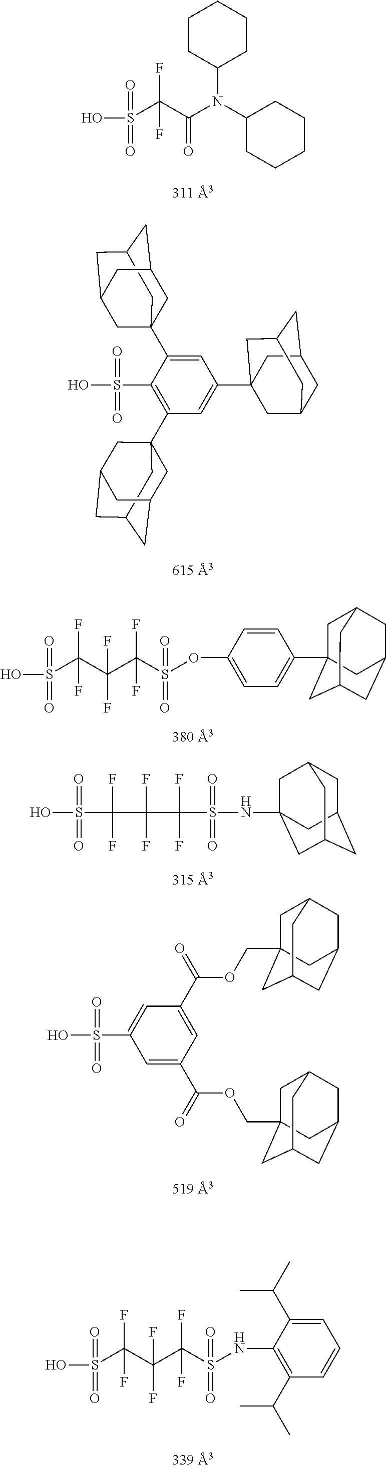

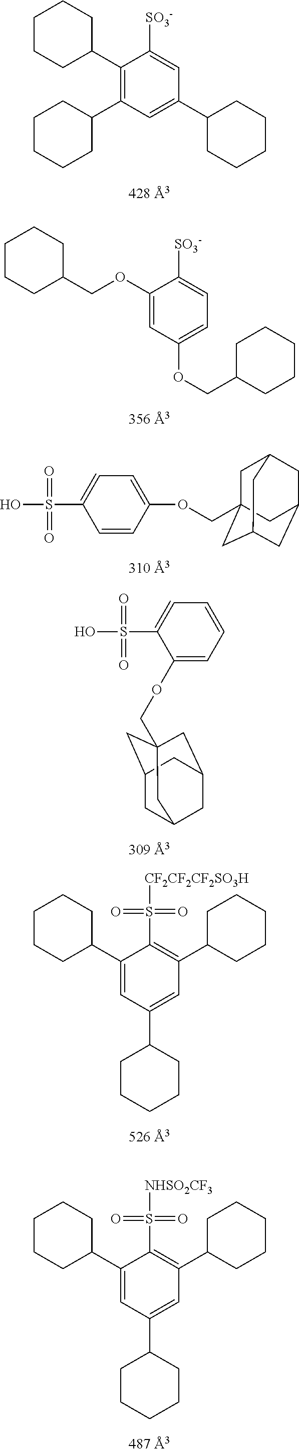

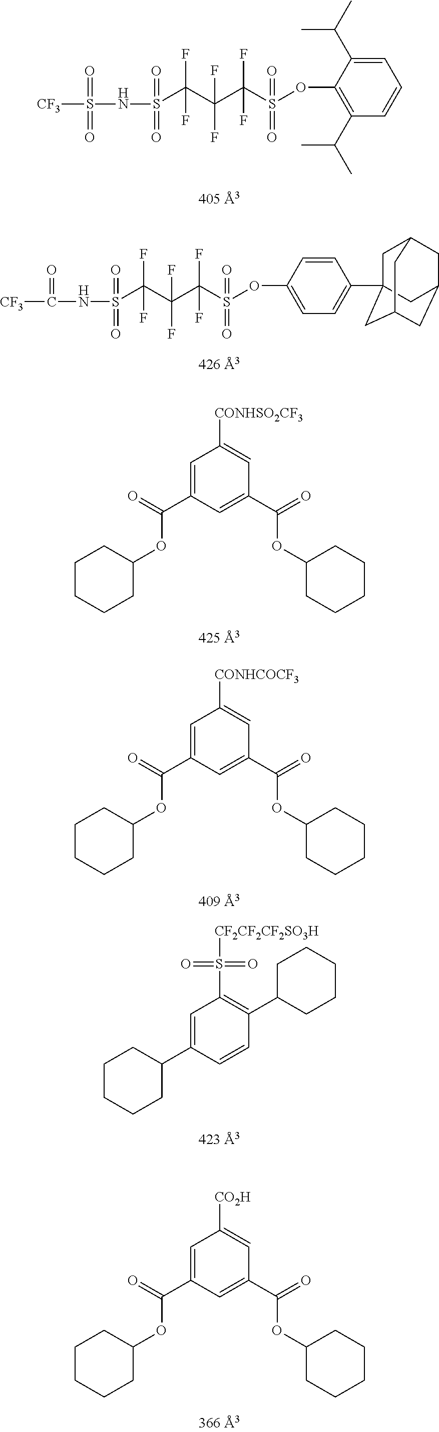

The volume of the acid is preferably 350 Å³ or more, more preferably 400 Å³ or more. Also, the volume is preferably 2,000 Å³ or less, more preferably 1,500 Å³ or less. If this volume is excessively large, the sensitivity or solubility in the coating solvent may decrease.

In formulae (2-1) and (2-2), M⁺ represents an organic onium ion.

Examples of the organic onium ion (counter cation) represented by M⁺ include onium ions such as iodonium, sulfonium, phosphonium, diazonium, ammonium, pyridinium, quinolinium, acridinium, oxonium, selenonium and arsonium, and among these, onium ions such as iodonium, sulfonium, phosphonium, diazonium, quinolinium and acridinium are preferred.

Other examples include, but are not limited to, cations such as onium ions of onium salts of Group 15 to 17 elements described in JP-A-6-184170, diazonium ions of diazonium salts described in S. I. Schlesinger, Photogr. Sci. Eng., 18, 387 (1974) and T. S. Bal et al., Polymer, 21, 423 (1980), ammonium ions of ammonium salts described in U.S. Pat. Nos. 4,069,055, 4,069,056 and Re 27,992 and JP-A-3-140140, phosphonium ions of phosphonium salts described in D. C. Necker et al., Macromolecules, 17, 2468 (1984), C. S. Wen et al., Teh Proc. Conf. Rad. Curing ASIA, p. 478, Tokyo, October (1988), U.S. Pat. Nos. 4,069,055 and 4,069,056 and JP-A-9-202873, iodonium ions of iodonium salts described in J. V. Crivello et al., Macromolecules, 10 (6), 1307 (1977), Chem. & Eng. News, November 28, p. 31 (1988), European Patents 104,143, 339,049 and 410,201, JP-A-2-150848 and JP-A-2-296514, sulfonium ions of sulfonium salts described in J. V. Crivello et al., Polymer J., 17, 73 (1985), J. V. Crivello et al., J. Org. Chem., 43, 3055 (1978), W. R. Watt et al., J. Polymer Sci., Polymer Chem. Ed., 22, 1789 (1984), J. V. Crivello et al., Polymer Bull., 14, 279 (1985), J. V. Crivello et al., Macromolecules, 14(5), 1141 (1981), J. V. Crivello et al., J. Polymer Sci., Polymer Chem. Ed., 17, 2877 (1979), European Patents 370,693, 161, 811, 410, 201, 339, 049, 233, 567, 297,443 and 297,442, U.S. Pat. Nos. 3,902,114, 4,933,377, 4,760,013, 4,734,444 and 2,833,827, German Patents 2,904,626, 3,604,580 and 3,604,581, JP-A-7-28237 and JP-A-8-27102, quinolinium ions of quinolinium salts described in JP-A-9-221652, selenonium ions of selenonium salts described in J. V. Crivello et al., Macromolecules, 10 (6), 1307 (1977) and J. V. Crivello et al., J. Polymer Sci., Polymer Chem. Ed., 17, 1047 (1979), and arsonium ions of arsonium salts described in C. S. Wen et al., Teh Proc. Conf. Rad. Curing ASIA, p. 478, Tokyo, October (1988).

Also, preferred examples of the counter cation above include cations having a structure represented by the following formulae (II) to (VII).

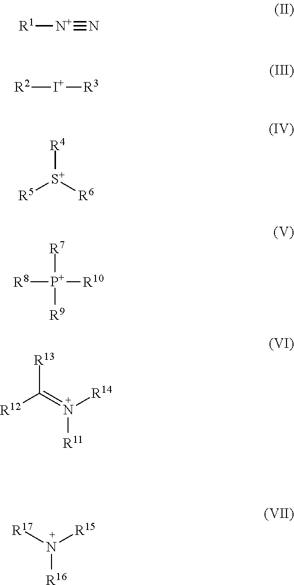

In formulae (II) to (VII), each of R¹ to R³ independently represents an aryl group, each of R⁴ to R⁶ independently represents an alkyl group, an alkenyl group, an alkynyl group, an aryl group, a hydrocarbon ring group or a heterocyclic group, each of R⁷ to R¹¹ independently represents an alkyl group, an alkenyl group, an alkynyl group, an aryl group, a hydrocarbon ring group, a heterocyclic group, an alkoxy group or an aryloxy group, and each of R¹² to R¹⁷ independently represents a hydrogen atom, a halogen atom or a monovalent organic group.

The alkyl group of R⁴ to R¹¹ preferably has a carbon number of 1 to 30, more preferably from 1 to 20, still more preferably from 1 to 8, and may be linear or may have a substituent.

The alkenyl group of R⁴ to R¹¹ preferably has a carbon number of 2 to 30, more preferably from 2 to 20, still more preferably from 2 to 8, and may further have a substituent.

The alkynyl group of R⁴ to R¹¹ preferably has a carbon number of 2 to 30, more preferably from 2 to 20, still more preferably from 2 to 8, and may further have a substituent.

The aryl group of R¹ to R¹¹ preferably has a carbon number of 6 to 30, more preferably from 6 to 20, still more preferably from 6 to 10, and may further have a substituent.

The hydrocarbon ring group of R⁴ to R¹¹ preferably has a carbon number of 3 to 30, more preferably from 3 to 20, still more preferably from 3 to 10, and may further have a substituent.

The heterocyclic group of R⁴ to R¹¹ preferably has a carbon number of 4 to 30, more preferably from 4 to 20, still more preferably from 4 to 10, and may further have a substituent. Also, the heteroatom contained in the heterocyclic group is preferably a nitrogen atom, an oxygen atom or a sulfur atom.

The alkoxy group of R⁷ to R¹¹ is preferably an alkoxy group having a carbon number of 1 to 30, more preferably from 1 to 20, still more preferably from 1 to 8. Also, the alkoxy group may have a substituent described later, and the alkyl moiety of the alkoxy group may be an alkenyl group, an alkynyl group, a hydrocarbon ring group or a non-aromatic heterocyclic group.

The aryloxy group of R⁷ to R¹¹ is preferably an aryloxy group having a carbon number of 6 to 30, more preferably from 6 to 20, still more preferably from 6 to 10. Also, the aryloxy group may have a substituent described later, and the aryl moiety of the aryloxy group may be an aromatic heterocyclic group.

In formula (III), R² and R³ may combine to form a ring, if possible.

In formula (IV), two or more of R⁴ to R⁶ may combine to form a ring, if possible. Also, the compound may be a compound having a structure where at least one of R⁴ to R⁶ is combined to at least one of R⁴ to R⁶ in another compound represented by formula (IV) through a single bond or a linking group.

In formula (V), two or more of R⁷ to R¹⁰ may combine to form a ring, if possible.

In formula (VI), two or more of R¹¹ to R¹⁴ may combine to form a ring, if possible.

In formula (VII), two or more of R¹⁵ to R¹⁷ may combine to form a ring, if possible.

As for the substituent which the above-described alkyl group, alkenyl group, alkynyl group, aryl group, hydrocarbon group, heterocyclic group, alkoxy group or aryloxy group may have, a monovalent non-metallic atom group excluding hydrogen is used, and preferred examples thereof include a halogen atom (e.g., —F, —Br, —Cl, —I), a hydroxyl group, an alkyl group, an aryl group, an alkenyl group, an alkynyl group, an alkoxy group, an aryloxy group, a mercapto group, an alkylthio group, an arylthio group, an alkyldithio group, an aryldithio group, an amino group, an N-alkylamino group, an N,N-dialkylamino group, an N-arylamino group, an N,N-diarylamino group, an N-alkyl-N-arylamino group, an acyloxy group, a carbamoyloxy group, an N-alkylcarbamoyloxy group, an N-arylcarbamoyloxy group, an N,N-dialkylcarbamoyloxy group, an N,N-diarylcarbamoyloxy group, an N-alkyl-N-arylcarbamoyloxy group, an alkylsulfoxy group, an arylsulfoxy group, an acylthio group, an acylamino group, an N-alkylacylamino group, an N-arylacylamino group, a ureido group, an N′-alkylureido group, an N′,N′-dialkylureido group, an N′-arylureido group, an N′,N′-diarylureido group, an N′-alkyl-N′-arylureido group, an N-alkylureido group, an N-arylureido group, an N′-alkyl-N-alkylureido group, an N′-alkyl-N-arylureido group, an N′,N′-dialkyl-N-alkylureido group, an N′,N′-dialkyl-N-arylureido group, an N′-aryl-N-alkylureido group, an N′-aryl-N-arylureido group, an N′,N′-diaryl-N-alkylureido group, an N′,N′-diaryl-N-arylureido group, an N′-alkyl-N′-aryl-N-alkylureido group, an N′-alkyl-N′-aryl-N-arylureido group, an alkoxycarbonylamino group, an aryloxycarbonylamino group, an N-alkyl-N-alkoxycarbonylamino group, an N-alkyl-N-aryloxycarbonylamino group, an N-aryl-N-alkoxycarbonylamino group, an N-aryl-N-aryloxycarbonylamino group, a formyl group, an acyl group, a carboxyl group and a conjugate base group (hereinafter, referred to as a carboxylato), an alkoxycarbonyl group, an aryloxycarbonyl group, a carbamoyl group, an N-alkylcarbamoyl group, an N,N-dialkylcarbamoyl group, an N-arylcarbamoyl group, an N,N-diarylcarbamoyl group, an N-alkyl-N-arylcarbamoyl group, an alkylsulfinyl group, an arylsulfinyl group, an alkylsulfonyl group, an arylsulfonyl group, a sulfo group (—SO₃H) and a conjugate base group thereof (hereinafter, referred to as a sulfonato group), an alkoxysulfonyl group, an aryloxysulfonyl group, a sulfinamoyl group, an N-alkylsulfinamoyl group, an N,N-dialkylsulfinamoyl group, an N-arylsulfinamoyl group, an N,N-diarylsulfinamoyl group, an N-alkyl-N-arylsulfinamoyl group, a sulfamoyl group, an N-alkylsulfamoyl group, an N,N-dialkylsulfamoyl group, an N-arylsulfamoyl group, an N,N-diarylsulfamoyl group, an N-alkyl-N-arylsulfamoyl group, an N-acylsulfamoyl group and a conjugate base group thereof, an N-alkylsulfonylsulfamoyl group (—SO₂NHSO₂(alkyl)) and a conjugate base group thereof, an N-arylsulfonylsulfamoyl group (—SO₂NHSO₂(aryl)) and a conjugate base group thereof, an N-alkylsulfonylcarbamoyl group (—CONHSO₂(alkyl)) and a conjugate base group thereof, an N-arylsulfonylcarbamoyl group (—CONHSO₂(aryl)) and a conjugate base group thereof, a silyl group, an alkoxysilyl group (—Si(O-alkyl)₃), an aryloxysilyl group (—Si(O-aryl)₃), a hydroxysilyl group (—Si(OH)₃) and a conjugate base group thereof, a phosphono group (—PO₃H₂) and a conjugate base group thereof (hereinafter, referred to as a phosphonato group), a dialkylphosphono group (—PO₃(alkyl)₂), a diarylphosphono group (—PO₃(aryl)₂), an alkylarylphosphono group (—PO₃(alkyl)(aryl)), a monoalkylphosphono group (—PO₃H(alkyl)) and a conjugate base group thereof (hereinafter, referred to as an alkylphosphonato group), a monoarylphosphono group (—PO₃H(aryl)) and a conjugate base group thereof (hereinafter, referred to as an arylphosphonato group), a phosphonoxy group (—OPO₃H₂) and a conjugate base group thereof (hereinafter, referred to as a phosphonatoxy group), a dialkylphosphonoxy group (—OPO₃(alkyl)₂), a diarylphosphonoxy group (—OPO₃(aryl)₂), an alkylarylphosphonoxy group (—OPO₃(alkyl)(aryl)), a monoalkylphosphonoxy group (—OPO₃H(alkyl)) and a conjugate base group thereof (hereinafter, referred to as an alkylphosphonatoxy group), a monoarylphosphonoxy group (—OPO₃H(aryl)) and a conjugate base group thereof (hereinafter, referred to as an arylphosphonatoxy group), a cyano group, and a nitro group. These substituents may be further substituted with the above-described substituent and may form a ring, if possible.

Each of R¹² to R¹⁷ independently represents a hydrogen atom, a halogen atom or a monovalent organic group.

Examples of the halogen atom of R¹² to R¹⁷ include a fluorine atom, a chlorine atom, a bromine atom and an iodine atom, and the halogen atom is preferably a fluorine atom, a chlorine atom or a bromine atom.

The monovalent organic group of R¹² to R¹⁷ represents a hydroxyl group, an alkyl group, an alkenyl group, an alkynyl group, an aryl group, a hydrocarbon ring group, a heterocyclic group, an alkoxy group, an aryloxy group, an acyl group, an alkoxycarbonyl group, an acyloxy group, —SO₃—R^{a}, —NR^{b}R^{c}, a cyano group, —SiR^{d}R^{e}R^{f}, —SOR^{g}, —SO₂R^{g} or a nitro group. R^{a} represents a hydrogen atom, an alkyl group, an alkenyl group, an alkynyl group, an aryl group, an arylalkyl group, an alkali metal atom or a quaternary ammonium, each of R^{b}, R^{e} and R^{g} independently represents an alkyl group, an alkenyl group, an alkynyl group, an aryl group, a hydrocarbon ring group or a heterocyclic group, and each of R^{d} to R^{f} independently represents an alkyl group, an alkenyl group, an alkynyl group, an aryl group, a hydrocarbon ring group, a heterocyclic group, an alkoxy group or an aryloxy group.

The alkyl group, alkenyl group, alkynyl group, aryl group, hydrocarbon ring group, heterocyclic group, alkoxy group and aryloxy group in R¹² to R¹⁷ have the same meanings as those of R⁷ to R¹¹, and preferred ranges are also the same. Furthermore, these groups may have the above-described substituent.

Each of the acyl group and alkoxycarbonyl group in R¹² to R¹⁷ preferably has a carbon number of 1 to 30, more preferably from 1 to 12, on the carbon chain side and may be linear or may have the above-described substituent.

The acyloxy group in R¹² to R¹⁷ preferably has a carbon number of 1 to 30, more preferably from 1 to 12, and may be linear or may have the above-described substituent.

R^{a} in —SO₃—R^{a} of R¹² to R¹⁷ is preferably a hydrogen atom, the above-described alkyl group which may have a substituent, the above-described aryl group which may have a substituent, a lithium atom, a sodium atom, or a potassium atom.

The above-described alkyl group, alkenyl group, alkynyl group, aryl group, hydrocarbon ring group and heterocyclic group of R^{b} and R^{c} in —NR^{b}R^{c} have the same meanings as those of R⁷ to R¹¹, and preferred ranges are also the same. Furthermore, these groups may have the above-described substituent.

The alkyl group, alkenyl group, alkynyl group, aryl group, hydrocarbon ring group, heterocyclic group, alkoxy group and aryloxy group of R^{d} to R^{f} in —SiR^{d}R^{e}R^{f} have the same meanings as those of R⁷ to R¹¹, and preferred ranges are also the same. Furthermore, these groups may have the above-described substituent.

The alkyl group, alkenyl group, alkynyl group, aryl group, hydrocarbon ring group and heterocyclic group of R^{g} in —SOR^{g} or —SO₂R^{g} have the same meanings as those of R⁷ to R¹¹, and preferred ranges are also the same. Furthermore, these groups may have the above-described substituent.

Specific examples of the counter cation represented by formulae (II) to (VII) include counter cations having a structure shown in Ca-1 to Ca-41 below.

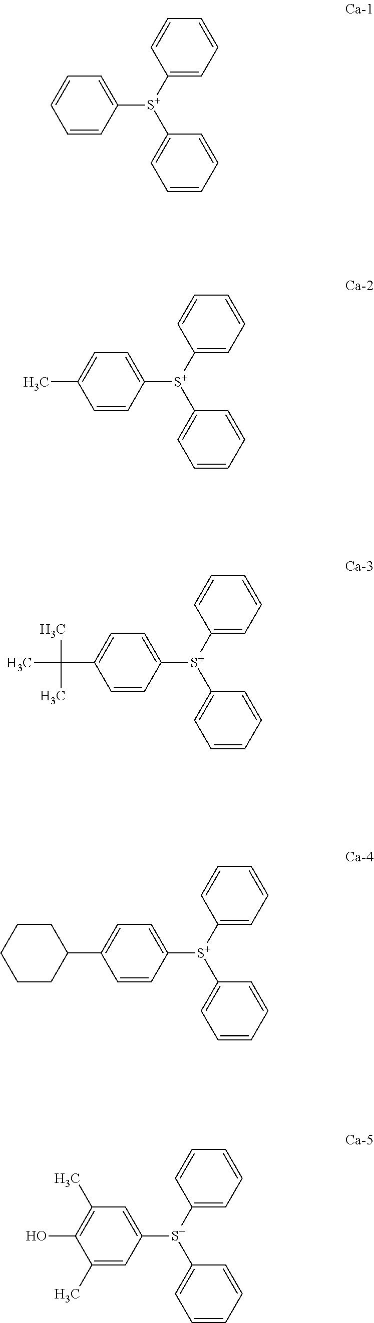

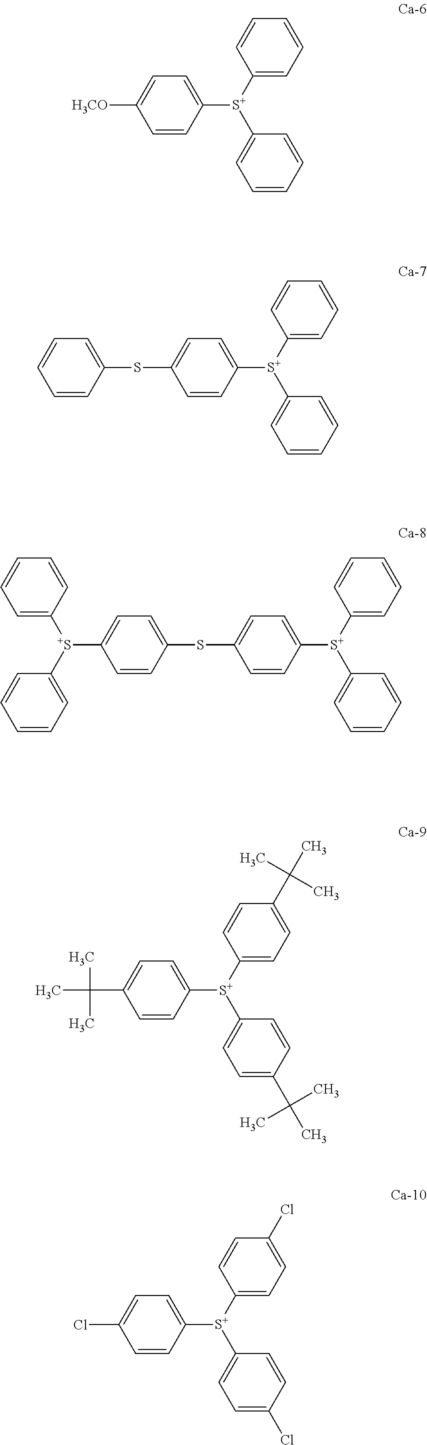

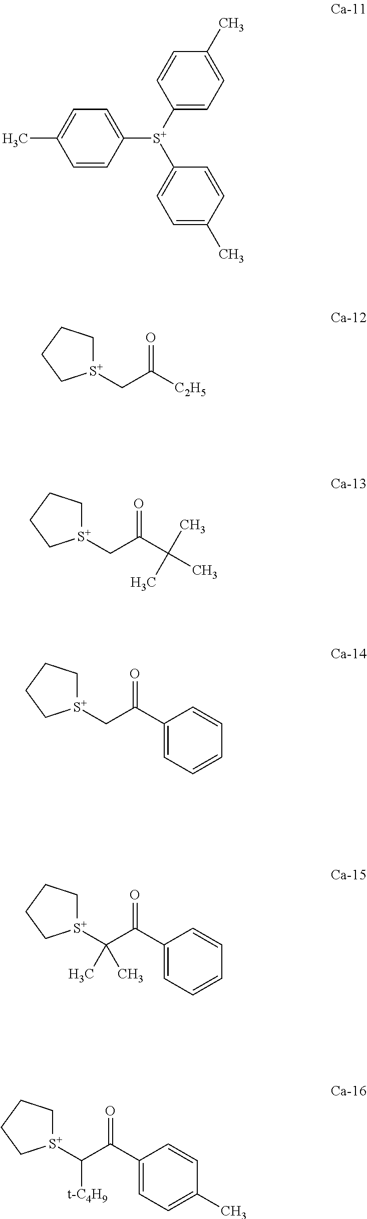

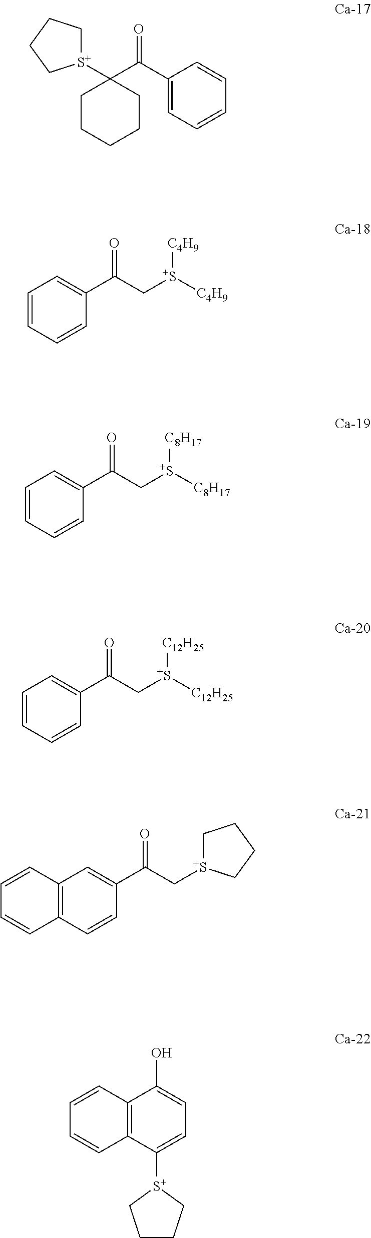

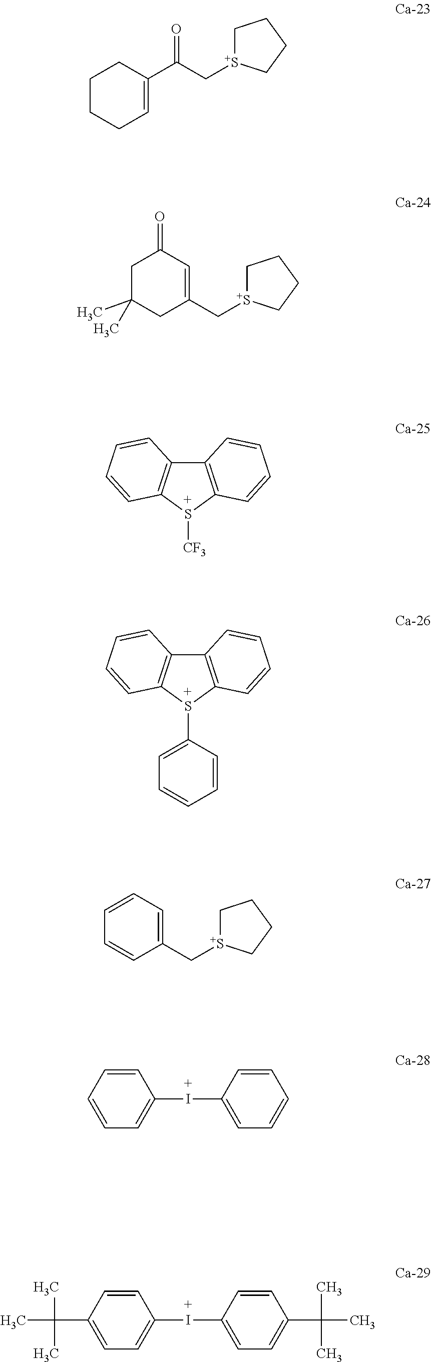

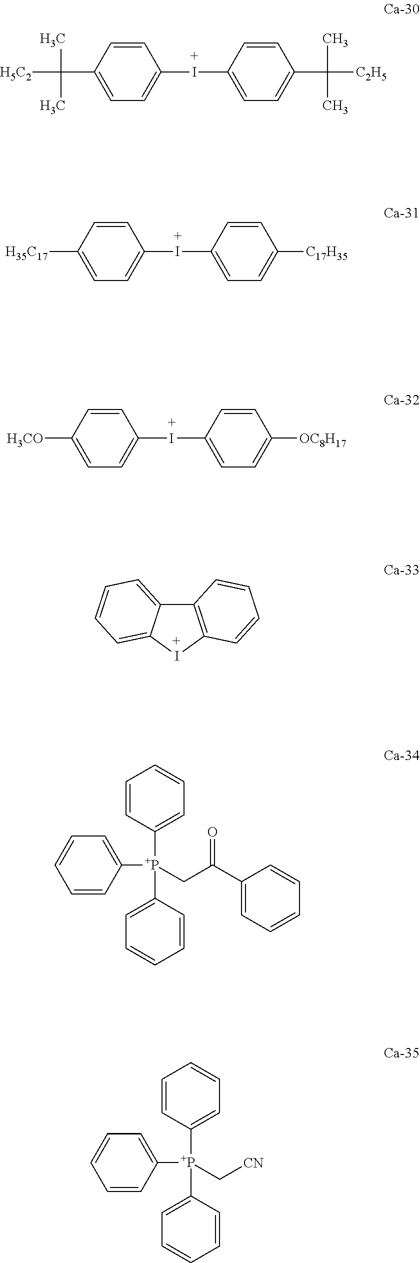

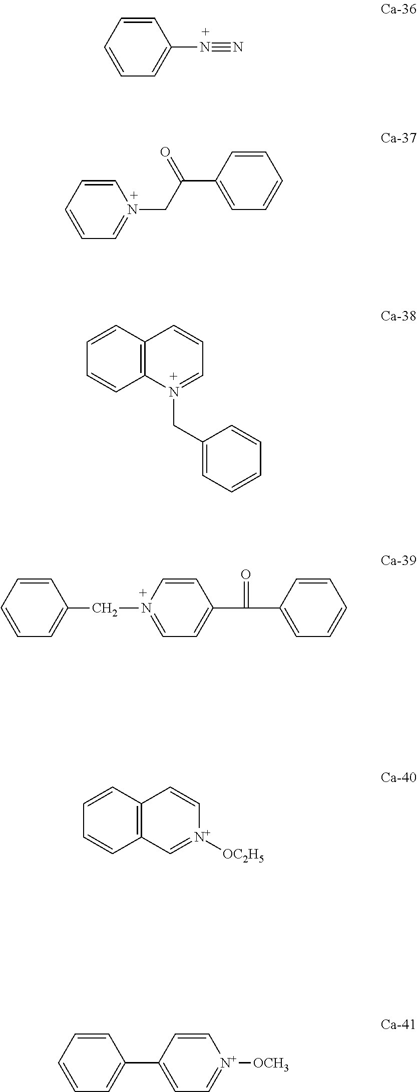

From the standpoint of suppressing the outgas, a cation having a structure of the following formula (VIII) is preferred as the organic onium ion.

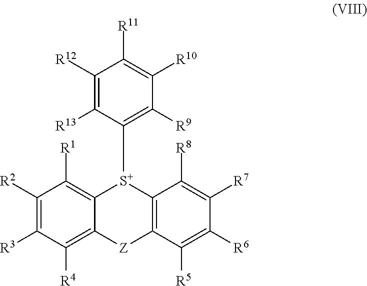

In formula (VIII), each of R¹ to R¹³ independently represents a hydrogen atom or a substituent, and at least one of R¹ to R¹³ is a substituent containing an alcoholic hydroxyl group.

Z represents a single bond or a divalent linking group.

The alcoholic hydroxyl group as used in the present invention indicates a hydroxyl group bonded to a carbon atom of an alkyl group.

In the case where R¹ to R¹³ are a substituent containing an alcoholic hydroxyl group, each of R¹ to R¹³ is represented by —W—Y, wherein Y is an alkyl group substituted with a hydroxyl group and W is a single bond or a divalent linking group.

Examples of the alkyl group of Y include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a boronyl group. Among these, preferred are an ethyl group, a propyl group, an isopropyl group, an n-butyl group, an isobutyl group and a sec-butyl group, and more preferred are an ethyl group, a propyl group and an isopropyl group. In particular, Y preferably contains a —CH₂CH₂OH structure.

The divalent linking group represented by W is not particularly limited but includes, for example, a divalent group formed by substituting a single bond for an arbitrary hydrogen atom of a monovalent group such as alkoxyl group, acyloxy group, carbamoyloxy group, alkoxycarbonyloxy group, aryloxycarbonyloxy group, acylamino group, aminocarbonylamino group, alkoxycarbonylamino group, aryloxycarbonylamino group, sulfamoylamino group, alkyl- or aryl-sulfonylamino group, alkylthio group, arylthio group, sulfamoyl group, alkyl- or aryl-sulfinyl group, alkyl- or arylsulfonyl group, acyl group, aryloxycarbonyl group, alkoxycarbonyl group and carbamoyl group.

W is preferably a single bond or a divalent group formed by substituting a single bond for an arbitrary hydrogen atom of an alkoxyl group, an acyloxy group, an acylamino group, an alkyl- or aryl-sulfonylamino group, an alkylthio group, an alkylsulfonyl group, an acyl group, an alkoxycarbonyl group or a carbamoyl group, more preferably a single bond or a divalent group formed by substituting a single bond for an arbitrary hydrogen atom of an acyloxy group, an alkylsulfonyl group, an acyl group or an alkoxycarbonyl group.

In the case where R¹ to R¹³ are a substituent containing an alcoholic hydroxyl group, the number of carbons contained therein is preferably from 2 to 10, more preferably from 2 to 6, still more preferably from 2 to 4.

The alcoholic hydroxyl group-containing substituent as R¹ to R¹³ may have two or more alcoholic hydroxyl groups. The number of alcoholic hydroxyl groups in the alcoholic hydroxyl group-containing substituent as R¹ to R¹³ is from 1 to 6, preferably from 1 to 3, more preferably 1.

The number of alcoholic hydroxyl groups in the compound represented by formula (VIII) is, in total of all of R¹ to R¹³, from 1 to 10, preferably from 1 to 6, more preferably from 1 to 3.

In the case where R¹ to R¹³ are free of an alcoholic hydroxyl group, each of R¹ to R¹³ is independently a hydrogen atom or a substituent, and the substituent may be any substituent and is not particularly limited, but examples thereof include a halogen atom, an alkyl group (including a cycloalkyl group, a bicycloalkyl group and a tricycloalkyl group), an alkenyl group (including a cycloalkenyl group and a bicycloalkenyl group), an alkynyl group, an aryl group, a heterocyclic group (may be called a heterocycle group), a cyano group, a nitro group, a carboxyl group, an alkoxyl group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkyl- or aryl-sulfonylamino group, a mercapto group, an alkylthio group, an arylthio group, a heterocyclic thio group, a sulfamoyl group, a sulfo group, an alkyl- or aryl-sulfinyl group, an alkyl- or aryl-sulfonyl group, an acyl group, an aryloxycarbonyl group, an alkoxycarbonyl group, a carbamoyl group, an aryl- or heterocyclic-azo group, an imido group, a phosphino group, a phosphinyl group, a phosphinyloxy group, a phosphinylamino group, a phosphono group, a silyl group, a hydrazino group, a ureido group, a boronic acid group (—B(OH)₂), a phosphato group (—OPO(OH)₂), a sulfato group (—OSO₃H), and other known substituents.

Two adjacent members out of R¹ to R¹³ may form in cooperation a ring (an aromatic or non-aromatic hydrocarbon ring or heterocyclic ring, and the rings may further combine to form a polycyclic condensed ring; examples of the ring include a benzene ring, a naphthalene ring, an anthracene ring, a phenanthrene ring, a fluorene ring, a triphenylene ring, a naphthacene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring and phenazine ring).

In the case where R¹ to R¹³ are free of an alcoholic hydroxyl group, each of R¹ to R¹³ is preferably a hydrogen atom, a halogen atom, an alkyl group (including a cycloalkyl group, a bicycloalkyl group and a bicycloalkyl group), an alkenyl group (including a cycloalkenyl group and a bicycloalkenyl group), an alkynyl group, an aryl group, a cyano group, a carboxyl group, an alkoxy group, an aryloxy group, an acyloxy group, a carbamoyloxy group, an acylamino group, an aminocarbonylamino group, an alkoxycarbonylamino group, an aryloxycarbonylamino group, a sulfamoylamino group, an alkyl- or aryl-sulfonylamino group, an alkylthio group, an arylthio group, a sulfamoyl group, an alkyl- or aryl-sulfonyl group, an aryloxycarbonyl group, an alkoxycarbonyl group, a carbamoyl group, an imido group, a silyl group, or a ureido group.

In the case where R¹ to R¹³ are free of an alcoholic hydroxyl group, each of R¹ to R¹³ is more preferably a hydrogen atom, a halogen atom, an alkyl group (including a cycloalkyl group, a bicycloalkyl group and a tricycloalkyl group), a cyano group, an alkoxy group, an acyloxy group, an acylamino group, an aminocarbonylamino group, an alkoxycarbonylamino group, an alkyl- or aryl-sulfonylamino group, an alkylthio group, a sulfamoyl group, an alkyl- or aryl-sulfonyl group, an alkoxycarbonyl group, or a carbamoyl group.

In the case where R¹ to R¹³ are free of an alcoholic hydroxyl group, each of R¹ to R¹³ is still more preferably a hydrogen atom, an alkyl group (including a cycloalkyl group, a bicycloalkyl group and a tricycloalkyl group), a halogen atom, or an alkoxy group.

In formula (VIII), at least one of R¹ to R¹³ contains an alcoholic hydroxyl group, and preferably, at least one of R⁹ to R¹³ contains an alcoholic hydroxyl group.

Z represents a single bond or a divalent linking group. Examples of the divalent linking group include an alkylene group, an arylene group, a carbonyl group, a sulfonyl group, a carbonyloxy group, a carbonylamino group, a sulfonylamido group, an ether group, a thioether group, an amino group, a disulfide group, an acyl group, an alkylsulfonyl group, —CH═CH—, an aminocarbonylamino group, and an aminosulfonylamino group, and these groups may have a substituent. Examples of the substituent thereof are the same as those of the substituent described for R¹ to R¹³. Z is preferably a single bond or a non-electron-withdrawing substituent such as alkylene group, arylene group, ether group, thioether group, amino group, —CH═CH—, —C≡C—, aminocarbonylamino group and aminosulfonylamino group, more preferably a single bond, an ether group or a thioether group, still more preferably a single bond.

Specific examples of the onium ion represented by formula (VIII) are illustrated below, but the present invention is not limited thereto.

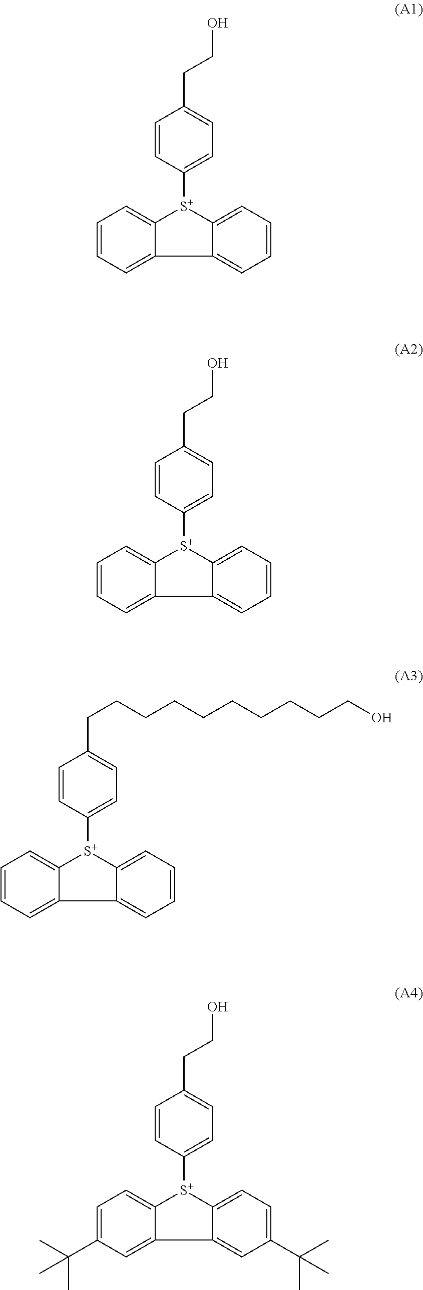

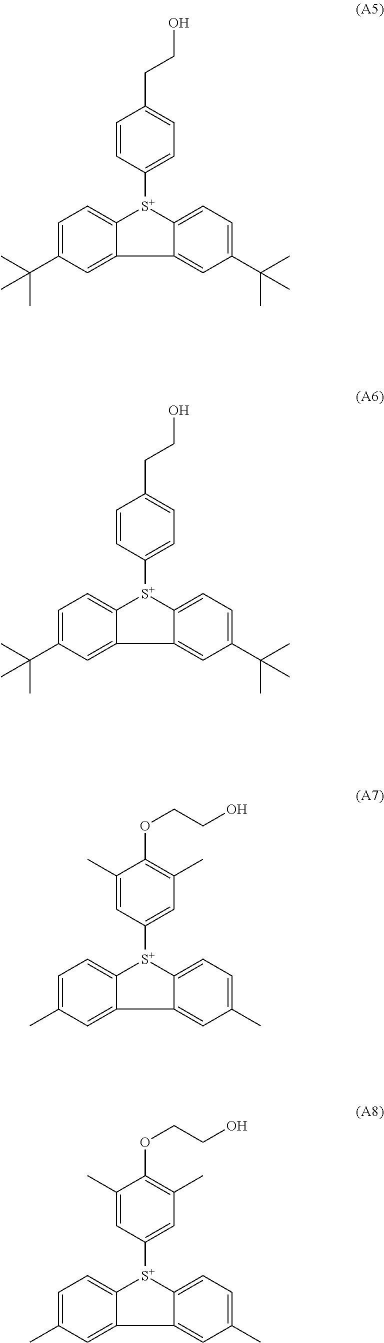

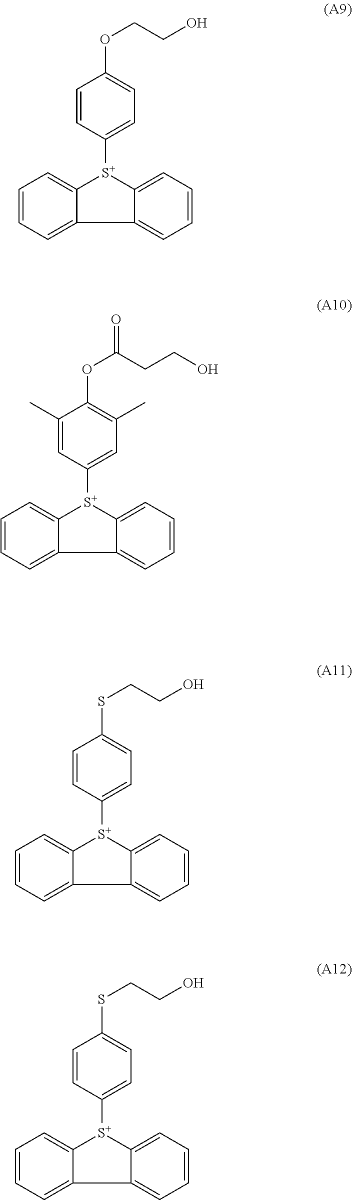

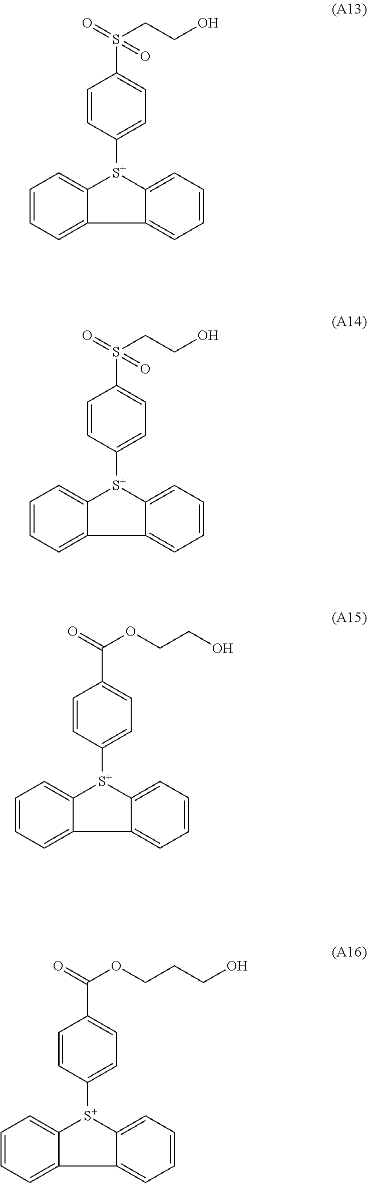

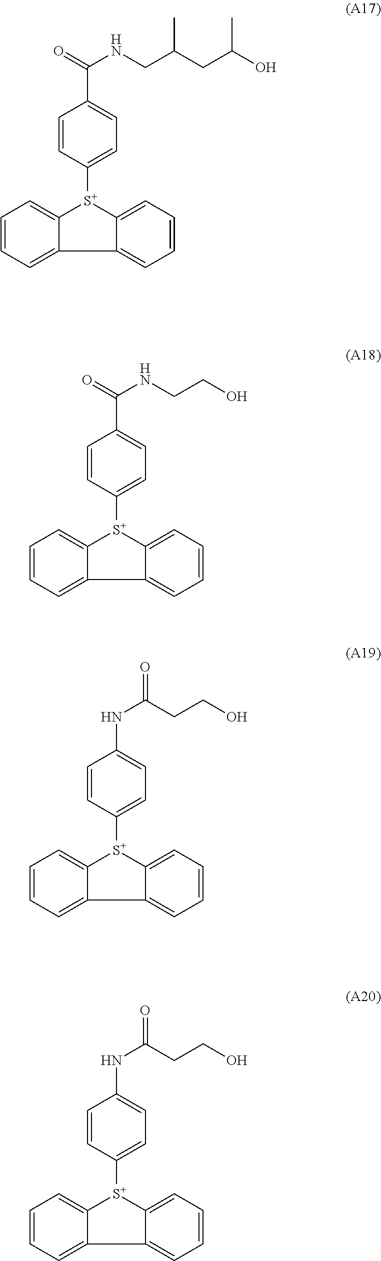

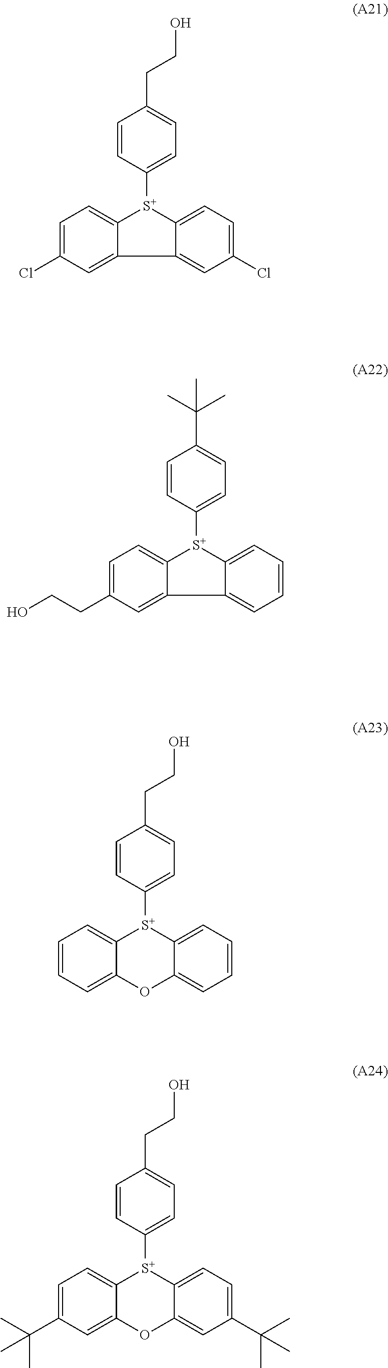

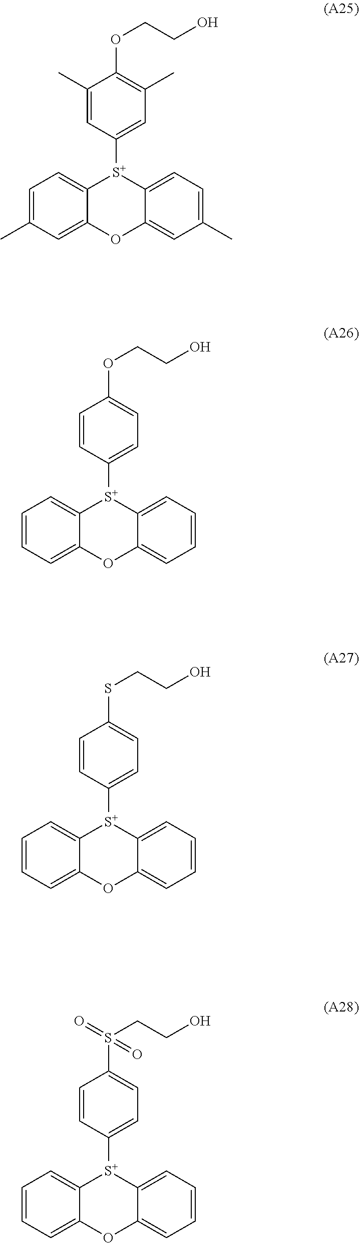

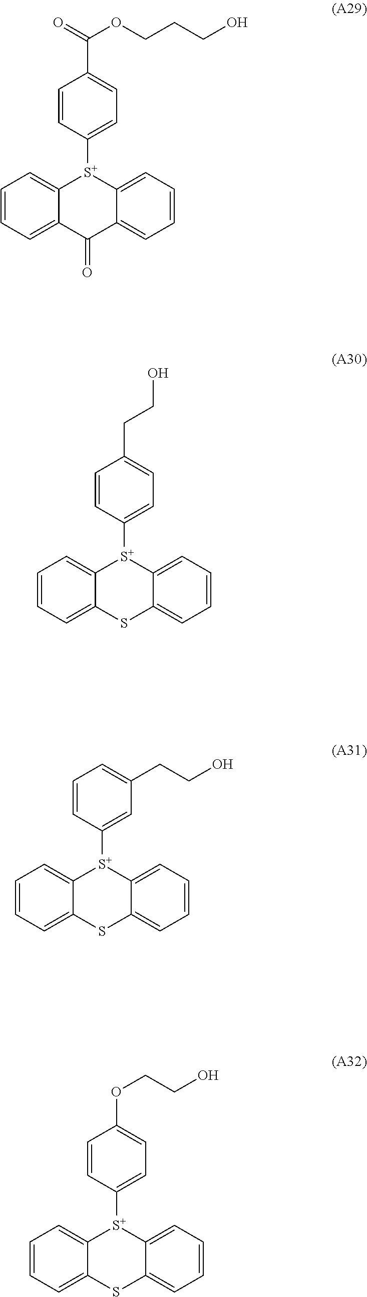

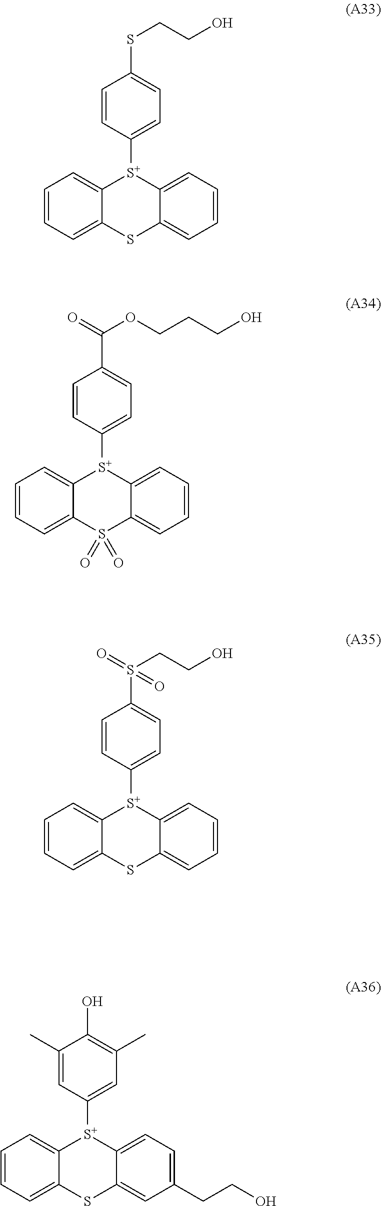

The amount added of the compound represented by formula (2-1) and/or formula (2-2) is, as a total amount, preferably from 0.1 to 40 mass %, more preferably from 0.5 to 35 mass %, still more preferably from 3 to 30 mass %, based on the entire solid content of the actinic ray-sensitive or radiation-sensitive composition. (In this specification, mass ratio is equal to weight ratio.)

Specific preferred examples of the compounds represented by formulae (2-1) and (2-2) are illustrated below, but the present invention is not limited thereto.

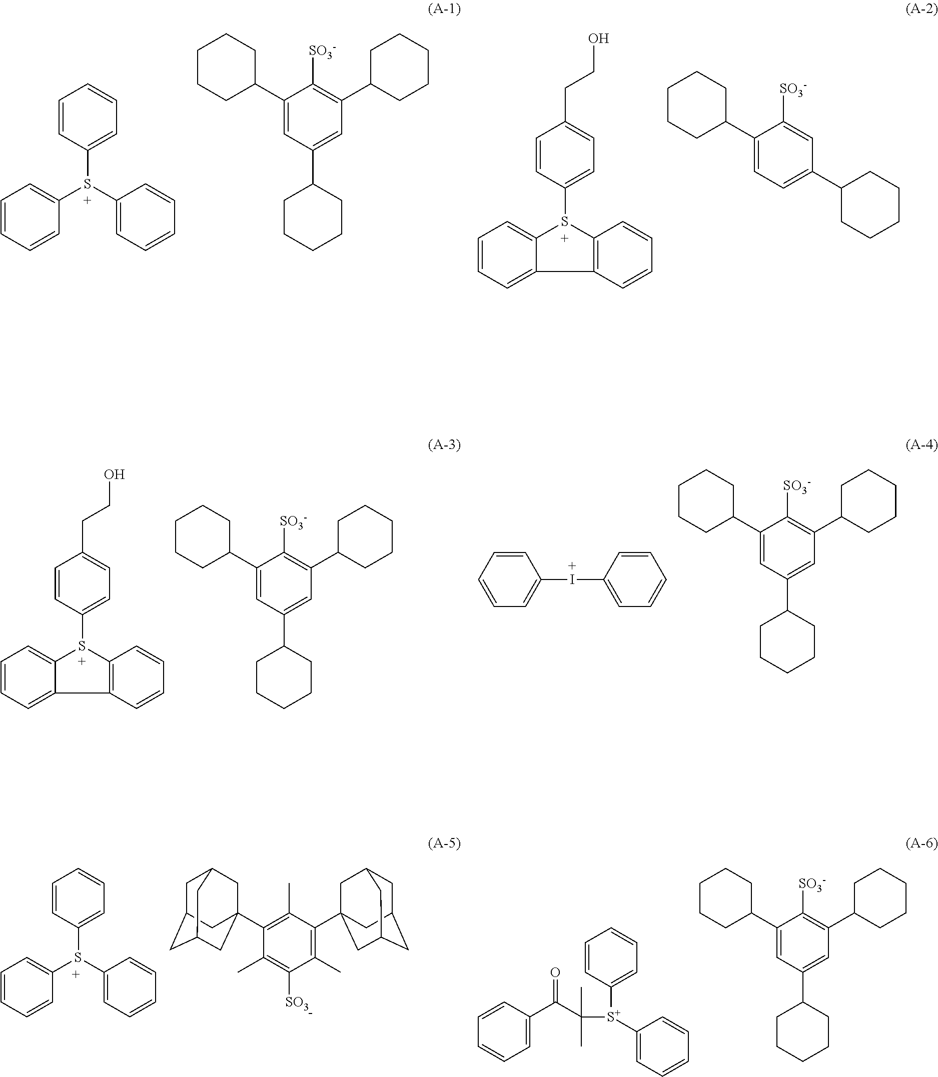

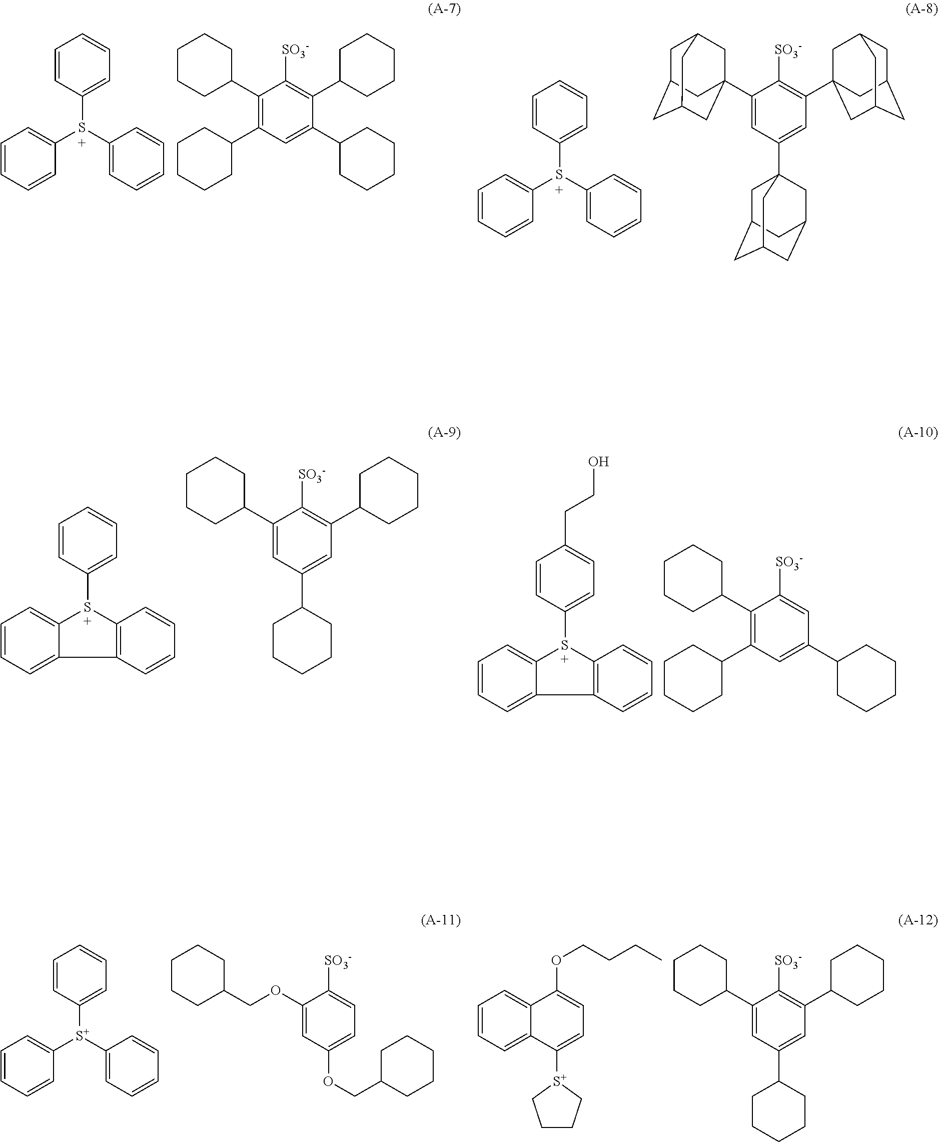

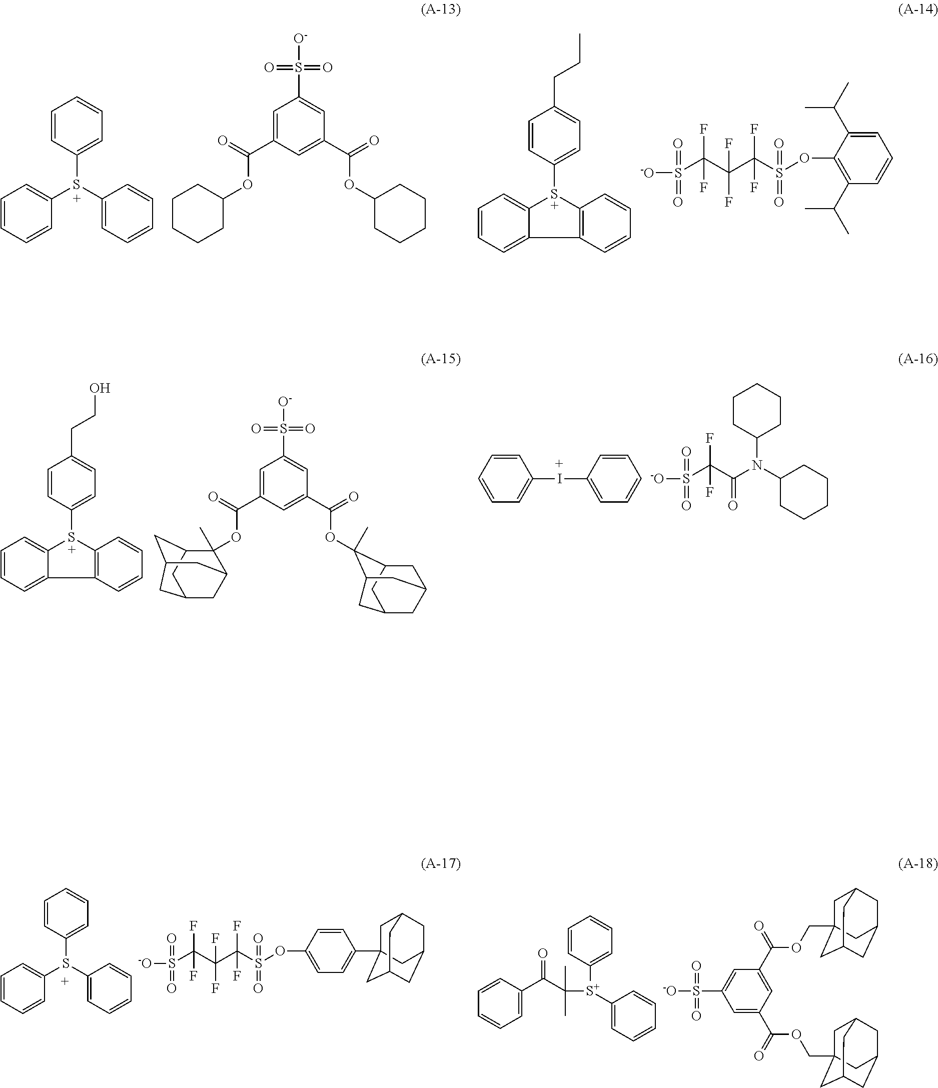

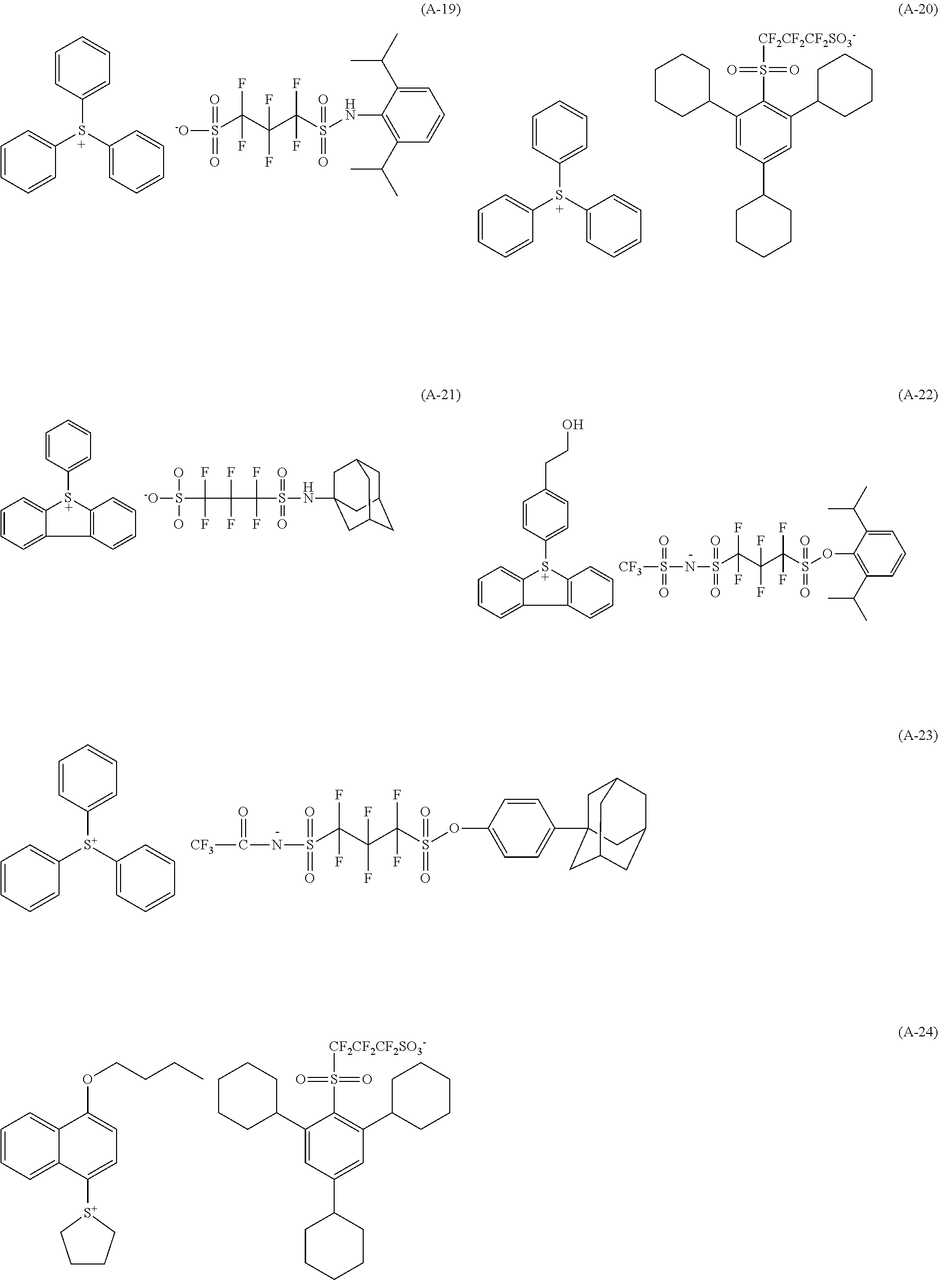

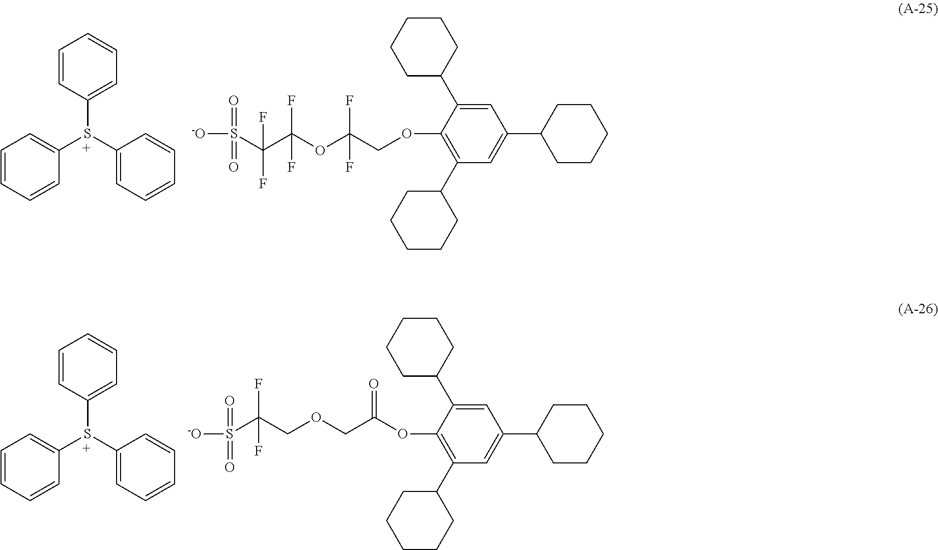

### (Actinic Ray-Sensitive or Radiation-Sensitive Low Molecular Compound-Containing Composition)

The actinic ray-sensitive or radiation-sensitive composition in a second embodiment of the present invention contains, in one aspect, a solvent and (1A) a compound which is a low molecular compound having a molecular weight of 500 to 5,000 and containing, in one molecule, (Z) one or more groups capable of decomposing upon irradiation with an actinic ray or radiation to produce an acid, (G) one or more acid-decomposable groups capable of decomposing by the action of an acid to accelerate the dissolution in an alkali developer and (S) one or more dissolution auxiliary groups capable of accelerating the dissolution in an alkali developer and in which assuming that the number of functional groups in one molecule of (Z), (G) and (S) is z, q and s, respectively, q/z≧2 and s/z≧2.

This is described in detail below.

### [Low Molecular Compound (1A)]

The low molecular compound (1A) contained in the actinic ray-sensitive or radiation-sensitive composition of the present invention is an actinic ray-sensitive or radiation-sensitive low molecular compound having a molecular weight of 500 to 5,000 and containing, in one molecule, (Z) one or more groups capable of decomposing upon irradiation with an actinic ray or radiation to produce an acid, (G) one or more acid-decomposable groups capable of decomposing by the action of an acid to accelerate the dissolution in an alkali developer and (S) one or more dissolution auxiliary groups capable of accelerating the dissolution in an alkali developer, in which assuming that the number of functional groups in one molecule of (Z), (G) and (S) is z, q and s, respectively, q/z≧2 and s/z≧2.

The molecular weight of the low molecular compound (1A) is preferably from 700 to 4,000, more preferably from 1,000 to 3,000. If the molecular eight is less than 500, the temperature of baking such as PB and PEB is limited, and the resolution may deteriorate, whereas if the molecular weight exceeds 5,000, the line edge roughness may deteriorate.

In view of sensitivity, q/z is preferably an integer of 2 to 20, more preferably from 3 to 10, still more preferably from 3 to 6.

In view of resolution, s/z is preferably an integer of 2 to 20, more preferably from 3 to 10, still more preferably from 3 to 6.

It is preferred that q/z is an integer of 2 to 6 and at the same time, s/z is an integer of 2 to 6.

The low molecular compound (1A) preferably contains an aromatic ring. The aromatic ring may be a monocyclic aromatic ring such as benzene ring or a condensed ring composed of two or more ring, such as naphthalene ring and anthracene ring. Also, the ring may contain a heteroatom as in a pyridine ring, a quinoline ring, a phenothiazine ring, a phenoxazine ring, a 5,10-dihydrophenazine ring and the like. The aromatic ring is preferably a benzene ring or a naphthalene ring.

The low molecular compound (1A) for use in the present invention may be, similarly to the low molecular compound (1), a so-called dendrimer or star polymer but is not a so-called chain polymer obtained by cleaving the unsaturated bond of an unsaturated bond-containing compound (so-called polymerizable monomer) with use of an initiator and growing the bond through a chain reaction.

The low molecular compound (1A) for use in the present invention is not particularly limited in its structure as long as the above-described conditions are satisfied, but the preferred embodiment thereof includes compounds represented by the following formulae (1A-1) and (1A-2):

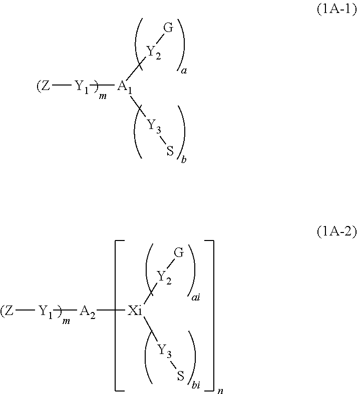

In formula (1A-1), A₁ represents an (a+b+m)-valent organic group, each of Y₁, Y₂ and Y₃ independently represents a single bond or a divalent linking group, Z represents a group capable of decomposing upon irradiation with an actinic ray or radiation to produce an acid, G represents an acid-decomposable group capable of decomposing by the action of an acid to accelerate the dissolution in an alkali developer, S represents a dissolution auxiliary group capable of accelerating the dissolution in an alkali developer, m represents an integer of 1 to 3, and each of a and b independently represents an integer of 2 to 10.

In formula (1A-2), A₂ represents an (m+n)-valent organic group, Y₁, Y₂, Y₃, Z, G, S and m have the same meanings as those in formula (1A-1), Xi represents an (ai+bi+1)-valent organic group, n represents an integer of 1 to 10, each of ai and bi independently represents an integer of 0 to 5, and ai and bi are not 0 at the same time.

In formulae (1A-1) and (1A-2), when the group in the parenthesis is present in a plurality of parentheses, the group in each parenthesis may be the same as or different from the group in every other parentheses.

A₁ is an (a+b+m)-valent organic group, A₂ is an (m+n)-valent organic group, and Xi is an (ai+bi+1)-valent organic group.

The organic group represented by A₁ is an organic group having a carbon number of 1 to 200, preferably a 5- to 30-valent organic group, more preferably a 6- to 20-valent polynuclear benzene derivative or a calixarene derivative. Preferred examples of the organic group represented by A₁ are illustrated below. In the following specific examples of the organic group represented by A₁, the organic group has a bond to Y₁, Y₂ or Y₃ in formula (2-1) at an arbitrary site denoted by *.

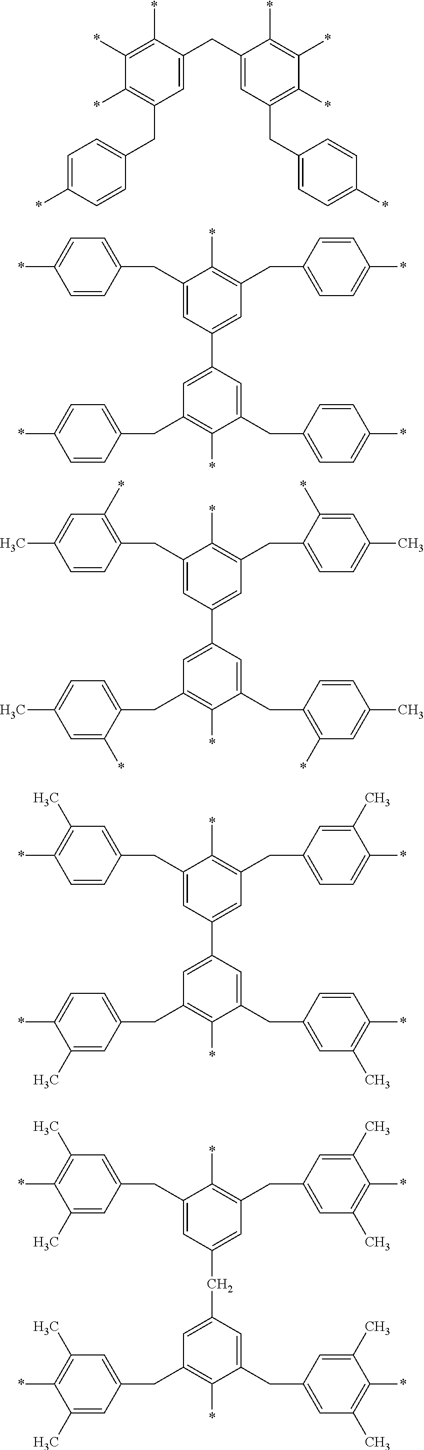

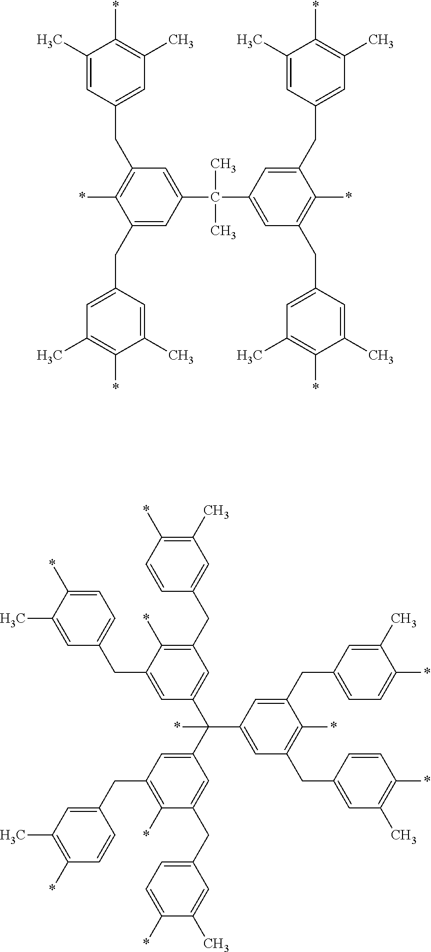

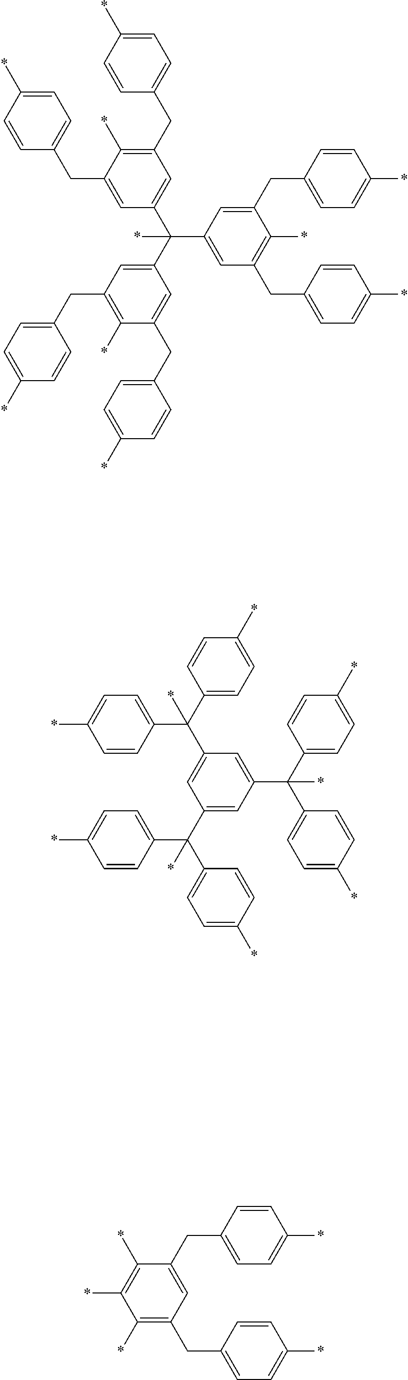

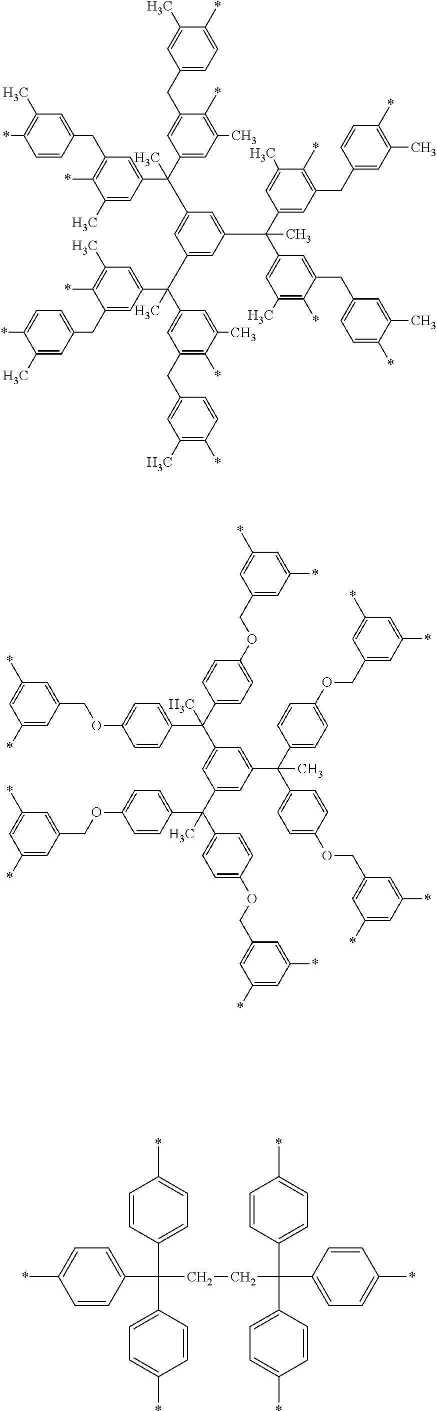

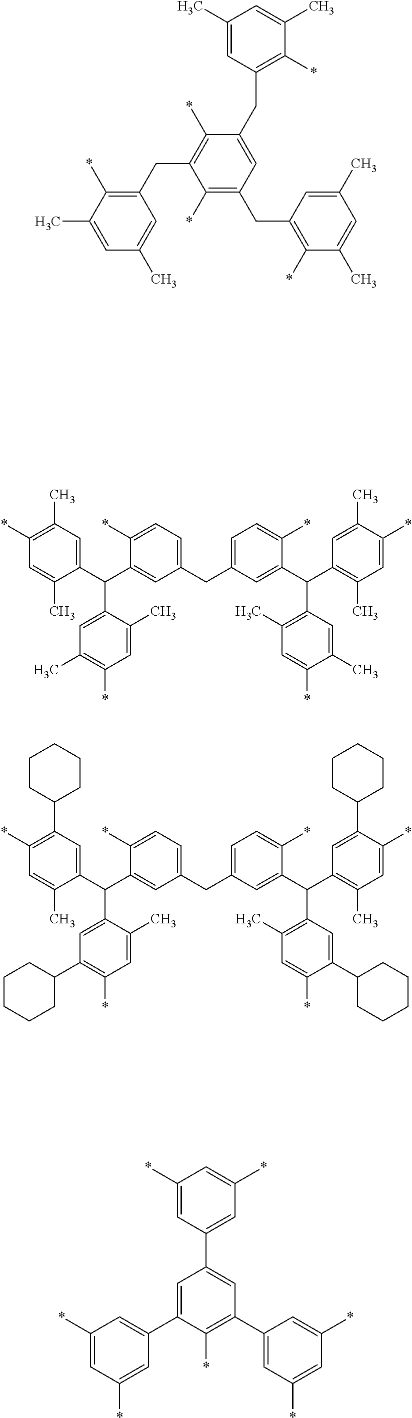

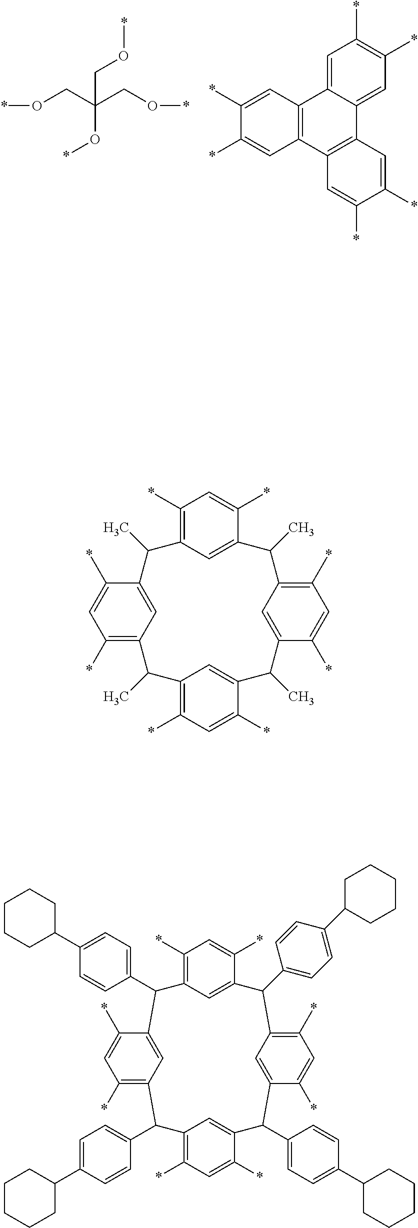

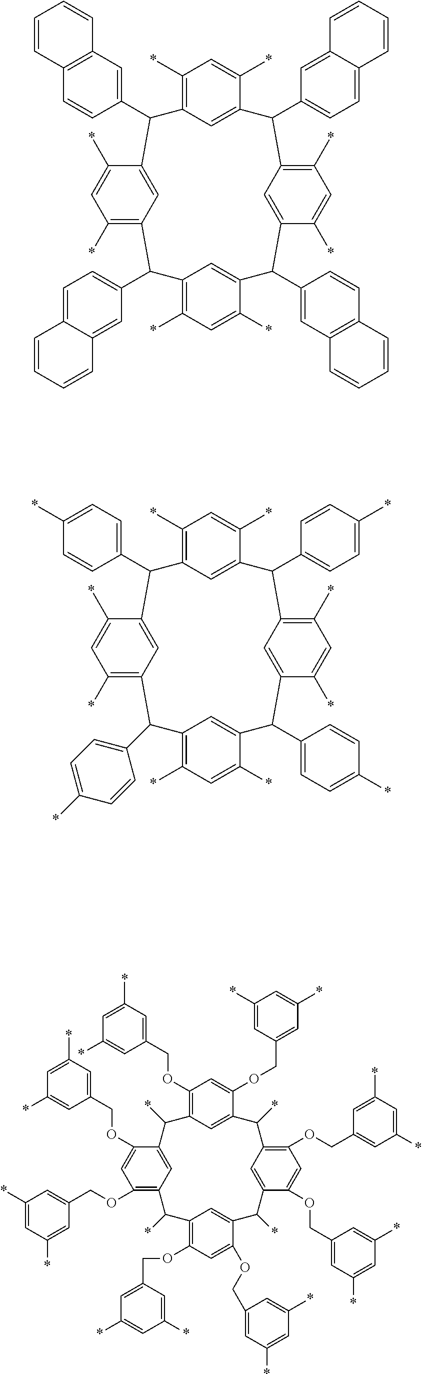

The organic group represented by A₂ is an organic group having a carbon number of 1 to 30, preferably a 3- to 10-valent organic group, more preferably a 5- to 10-valent aromatic ring. Specific examples and preferred examples of the aromatic ring are the same as those of the aromatic ring which is preferably contained in the low molecular compound (1A).

Preferred examples of the organic group represented by A₂ are illustrated below. In the following specific examples of the organic group represented by A₂, the organic group has a bond to Y₁ or Xi in formula (1A-2) at an arbitrary site denoted by *.

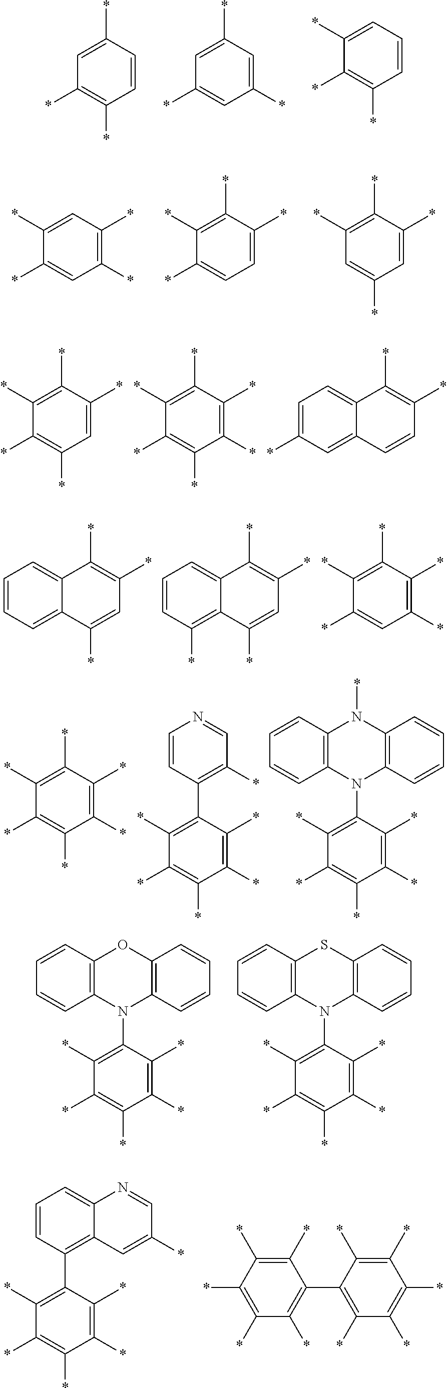

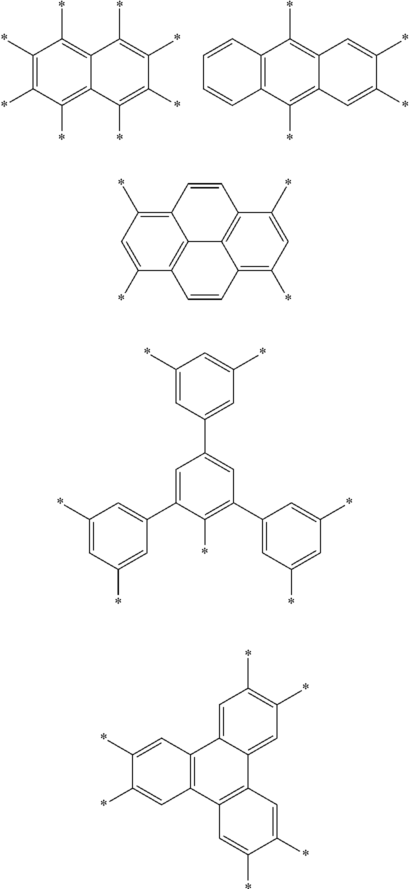

The organic group represented by Xi is an organic group having a carbon number of 1 to 30, preferably a 2- to 6-valent organic group, more preferably a 3- to 5-valent aromatic ring. Specific examples and preferred examples of the aromatic ring are the same as those of the aromatic ring which is preferably contained in the low molecular compound (1A).

Preferred examples of the organic group represented by Xi are illustrated below. In the following specific examples of the organic group represented by Xi, the organic group has a bond to A₂, Y₂ or Y₃ in formula (1A-2) at an arbitrary site denoted by *.

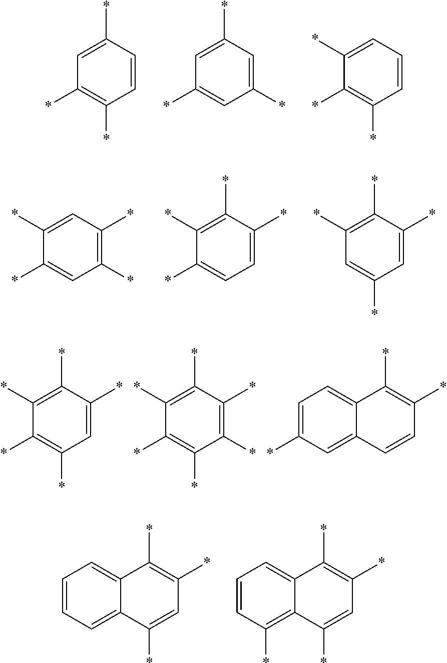

Preferred examples of the divalent linking group represented by Y₁ or Y₃ are the same as those for Yb in formula (1-1), and the divalent group is *—Y₁₁ₐ—, *—Y₁₂ₐ—Y₁₁ₐ, *—Y₁₂ₐ—C(═O)—Y₁₁ₐ—, *—Y₁₂ₐ—SO₂—Y₁₁ₐ—, *—C(═O)—Y₁₂ₐ—Y₁₁ₐ—, *—SO₂—Y₁₂ₐ—Y₁₁ₐ—, *—Y₁₂ₐ—C(═O)—Y₁₂ₐ′—Y₁₁ₐ— or an arbitrary combination thereof (wherein * represents, in the case of Y₁, a site bonded to A₁ or A₂, and in the case of Y₃, a site bonded to A₁ or Xi; Y₁₁ₐ represents a substituted or unsubstituted alkylene group having a carbon number of 1 to 20, a substituted or unsubstituted cycloalkylene group having a carbon number of 3 to 20, a substituted or unsubstituted arylene group having a carbon number of 6 to 20, or a substituted or unsubstituted aralkylene group having a carbon number of 7 to 20, each of Y₁₂ₐ and Y₁₂ₐ′ independently represents an oxygen atom, a sulfur atom or N(Ry), and Ry represents a substituted or unsubstituted alkyl group having a carbon number of 1 to 20, a substituted or unsubstituted cycloalkyl group having a carbon number of 3 to 20, a substituted or unsubstituted aryl group having a carbon number of 6 to 20, or a substituted or unsubstituted aralkyl group having a carbon number of 7 to 20).

The divalent linking group represented by Y₂ is preferably *—Y₂₁ₐ—, *—Y₂₂ₐ—, *—Y₂₂ₐ—Y₂₁ₐ—, *—Y₂₂ₐ—C(═O)—Y₂₁ₐ, *—Y₂₂ₐ—C(═O)—, *—Y₂₂ₐ—SO₂—Y₂₁ₐ—, *—C(═O)—Y₂₂ₐ—Y₂₁ₐ—, *—SO₂—Y₂₂ₐ—Y₂₁ₐ—, *—Y₂₂ₐ—C(═O)—Y₂₂ₐ′-Y₂₁ₐ— or an arbitrary combination thereof (wherein * represents a site bonded to A₁ or Xi, Y₂₁ₐ represents a substituted or unsubstituted alkylene group having a carbon number of 1 to 20, a substituted or unsubstituted cycloalkylene group having a carbon number of 3 to 20, a substituted or unsubstituted arylene group having a carbon number of 6 to 20, or a substituted or unsubstituted aralkylene group having a carbon number of 7 to 20, each of Y₂₂ₐ and Y₂₂ₐ′ independently represents an oxygen atom, a sulfur atom or N(Ry), and Ry represents a substituted or unsubstituted alkyl group having a carbon number of 1 to 20, a substituted or unsubstituted cycloalkyl group having a carbon number of 3 to 20, a substituted or unsubstituted aryl group having a carbon number of 6 to 20, or a substituted or unsubstituted aralkyl group having a carbon number of 7 to 20).

Examples of the substituent which each of the groups above may have include a nitro group, a halogen atom (fluorine, chlorine, bromine, iodine), an amino group, a cyano group, a hydroxyl group, an alkoxy group (preferably having a carbon number of 1 to 15), a cycloalkyl group (preferably having a carbon number of 3 to 15), an aryl group (preferably having a carbon number of 6 to 15), an alkoxycarbonyl group (preferably having a carbon number of 2 to 15), an acyl group (preferably having a carbon number of 2 to 15), an acylamino group (preferably having a carbon number of 2 to 15), a carbamoyl group (preferably having a carbon number of 1 to 15), a sulfonylamino group (preferably having a carbon number of 2 to 15), and a sulfamoyl group (preferably having a carbon number of 1 to 15). As for the aryl group and the ring structure in each group, examples of the substituent further include an alkyl group (preferably having a carbon number of 1 to 15).

A compound where in formula (1A-1), A₁ is a penta or higher valent polynuclear benzene derivative (the number of benzene rings is preferably from 4 to 20) or a calixarene derivative (the number of benzene rings is preferably from 4 to 20) or where in formula (1A-2), A₂ is a penta or higher valent benzene derivative or naphthalene derivative, Z is a sulfonium salt or iodonium salt of sulfonic acid, G is a tertiary ester group or an acetal group and S is a phenolic hydroxyl group, is preferred.

[(Z) Group Capable of Decomposing Upon Irradiation with an Actinic Ray or Radiation to Produce an Acid]

Z represents a structural moiety capable of decomposing upon irradiation with an actinic ray or radiation to produce an acid anion. Specifically, the structural moiety includes structural moieties of a photo-initiator for cationic photopolymerization, a photo-initiator for radical photopolymerization, a photodecoloring agent for dyes, a photodiscoloring agent, and a compound known to generate an acid by the effect of light and used for microresist and the like.

The acid anion produced resulting from decomposition upon irradiation with an actinic ray or radiation may be produced on the mother nuclear side having groups (G) and (S) of the compound (1A) or may be produced on the side that leaves from the mother nucleus. Incidentally, when an acid anion is produced on the leaving side, a cation is produced on the mother nucleus side.

Examples of the structural moiety capable of generating an acid anion upon irradiation with an actinic ray or radiation include onium structural moieties such as diazonium salt, ammonium salt, phosphonium salt, iodonium salt, sulfonium salt, selenonium salt and arsonium salt

Z is more preferably an ionic structural moiety containing a sulfonium or iodonium salt. More specifically, Z is preferably a group represented by the following formula (Z11) or (Z12):

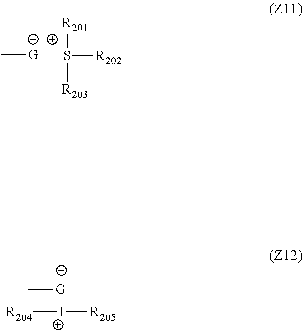

In formula (Z11), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group. The group formed by combining two members out of R₂₀₁ to R₂₀₃ includes an alkylene group (e.g., butylene, pentylene).

G⁻ represents an acid anion generated resulting from decomposition upon irradiation with an actinic ray or radiation and is preferably a non-nucleophilic anion. Examples of the non-nucleophilic anion include sulfonate anion, carboxylate anion, sulfonylimide anion, bis(alkylsulfonyl)imide anion and tris(alkylsulfonyl)methyl anion.

The non-nucleophilic anion is an anion having an extremely low ability of causing a nucleophilic reaction, and this anion can suppress the decomposition with aging due to intramolecular nucleophilic reaction. Thanks to this anion, the aging stability of the compound (1A) and in turn, the aging stability of the composition are enhanced.

Examples of the organic group of R₂₀₁, R₂₀₂ and R₂₀₃ include an aryl group, an alkyl group and a cycloalkyl group.

At least one of three members R₂₀₁, R₂₀₂ and R₂₀₃ is preferably an aryl group, and it is more preferred that these members all are an aryl group. The aryl group may be a heteroaryl group such as indole residue structure and pyrrole residue structure, other than a phenyl group or a naphthyl group. This aryl group may further have a substituent, and examples of the substituent include, but are not limited to, a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12) and an alkoxycarbonyloxy group (preferably having a carbon number of 2 to 7).

The preferred structure when at least one of R₂₀₁, R₂₀₂ and R₂₀₃ is not an aryl group includes cation structures such as compounds illustrated in JP-A-2004-233661, paragraphs 0047 and 0048, and JP-A-2003-35948, paragraphs 0040 to 0046, Compounds (I-1) to (I-70) illustrated in U.S. Patent Application Publication 2003/0224288, and Compounds (1A-1) to (IA-54) and (IB-1) to (IB-24) illustrated in U.S. Patent Application Publication 2003/0077540.

In formula (Z12), each of R₂₀₄ and R₂₀₅ independently represents an aryl group, an alkyl group or a cycloalkyl group. These aryl group, alkyl group and cycloalkyl group have the same meanings as the aryl group, alkyl group and cycloalkyl group of R₂₀₁ to R₂₀₃ in the compound (Z11).

The aryl group, alkyl group and cycloalkyl group of R₂₀₄ and R₂₀₅ may have a substituent. Examples of the substituent include those which the aryl group, alkyl group and cycloalkyl group of R₂₀₁ to R₂₀₃ in the compound (Z11) may have.

G⁻ represents an acid anion generated resulting from decomposition upon irradiation with an actinic ray or radiation and is preferably a non-nucleophilic anion, and examples thereof are the same as those for G⁻ in formula (Z11).

Other examples of the structural moiety capable of generating an acid anion upon irradiation with an actinic ray or radiation include structural moieties of the following photo-acid generators, which are a sulfonic acid precursor:

compounds capable of generating a sulfonic acid resulting from photolysis, as typified by iminosulfonate and the like, described in M. TUNOOKA et al., Polymer Preprints Japan, 35 (8), G. Berner et al., J. Rad. Curing, 13 (4), W. J. Mijs et al., Coating Technol., 55 (697), 45 (1983), Akzo, H. Adachi et al., Polymer Preprints, Japan, 37 (3), European Patents 0,199,672, 84,515, 199, 672, 044,115 and 0,101,122, U.S. Pat. Nos. 618,564, 4,371,605 and 4,431,774, JP-A-64-18143, JP-A-2-245756 and JP-A-3-140109; disulfone compounds described in JP-A-61-166544; and compounds capable of generating an acid by the effect of light described in V.N.R. Pillai, Synthesis, (1), 1 (1980), A. Abad et al., Tetrahedron Lett., 47), 4555 (1971), D. H. R. Barton et al., J. Chem. Soc., (C), 329 (1970), U.S. Pat. No. 3,779,778 and European Patent 126,712.

(Z) is more preferably a structure capable of generating an acid in the molecule of the compound (1A) upon irradiation with an actinic ray or radiation. When such a structure is selected, diffusion of the generated acid anion is suppressed and this is effective from the standpoint of, for example, enhancing the resolution or improving the line edge roughness.

Specific preferred examples of the partial structure represented by Z are illustrated below, but the present invention is not limited thereto.

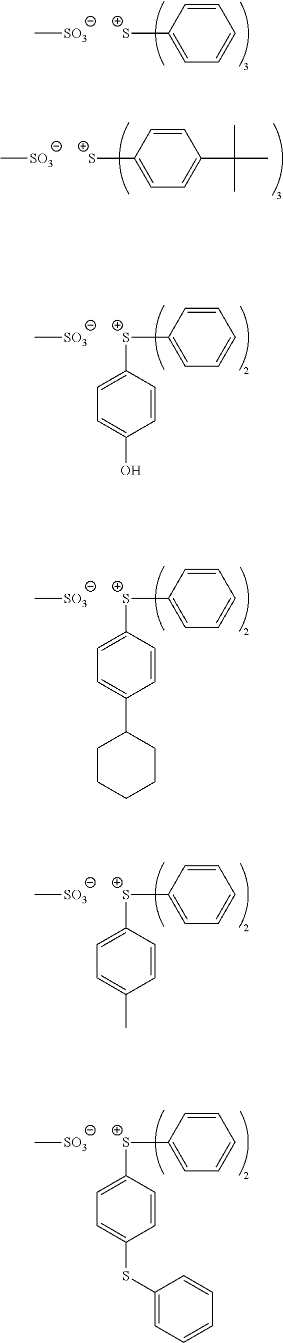

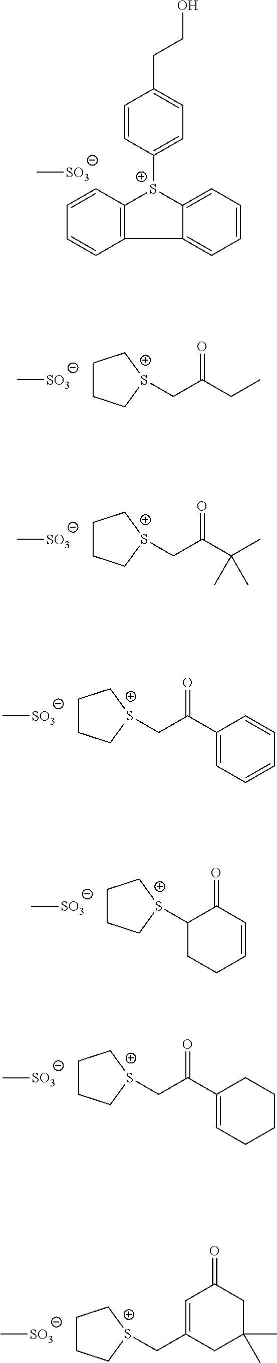

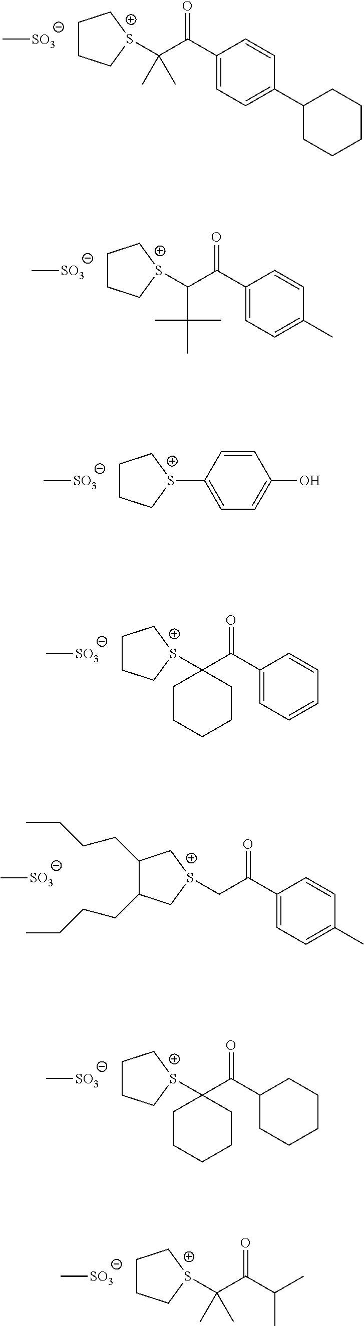

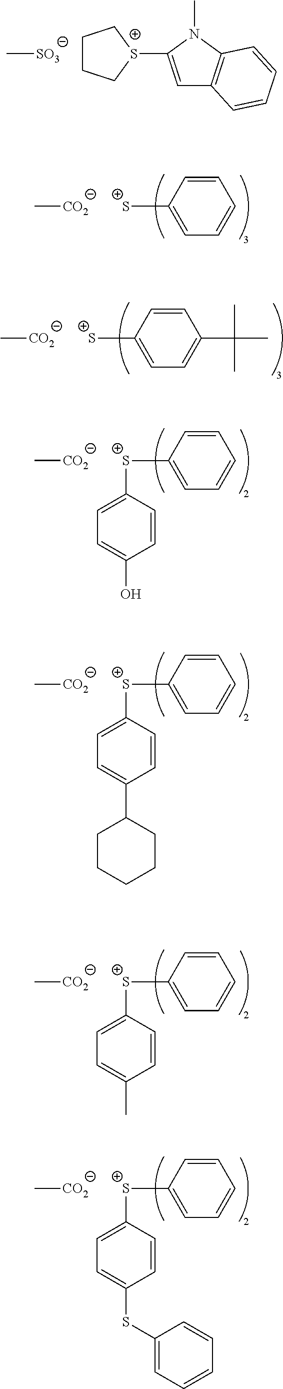

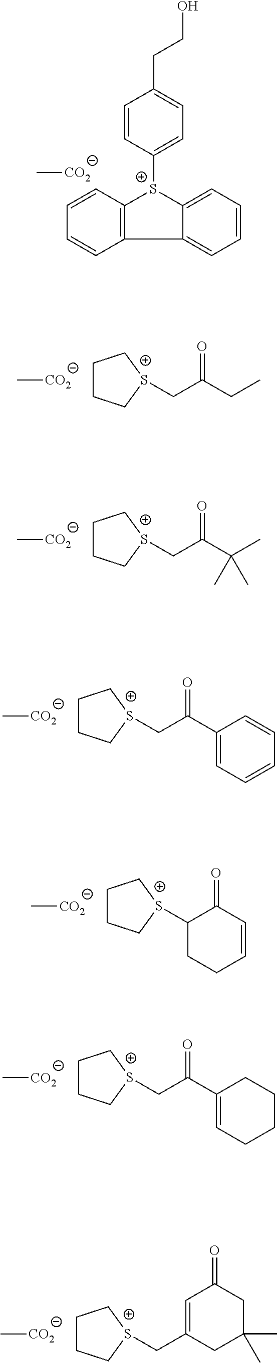

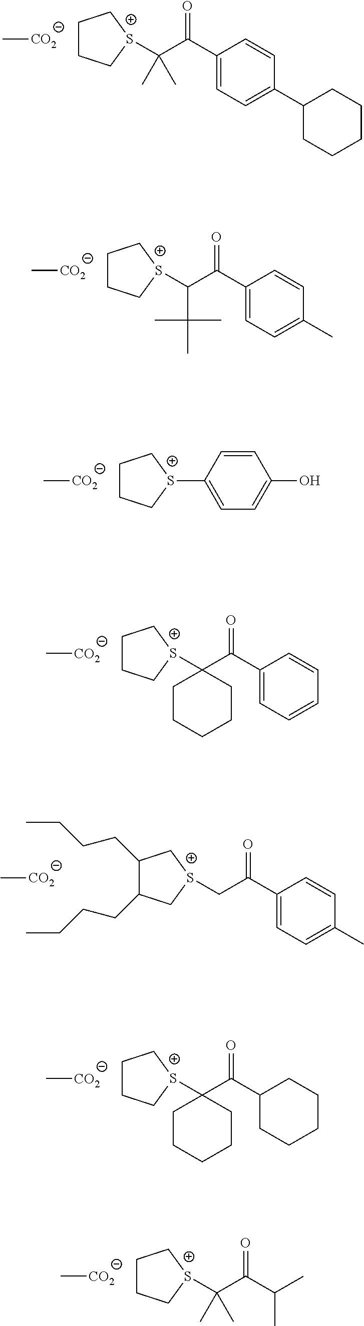

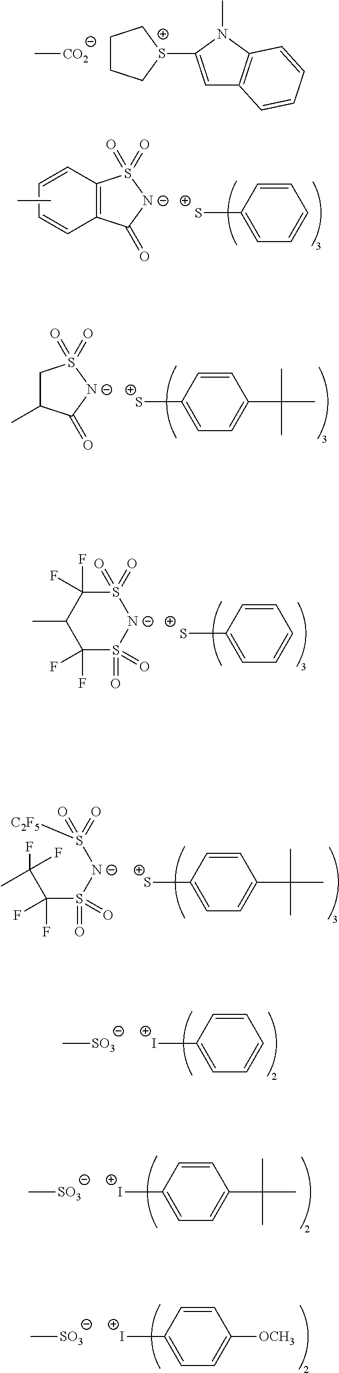

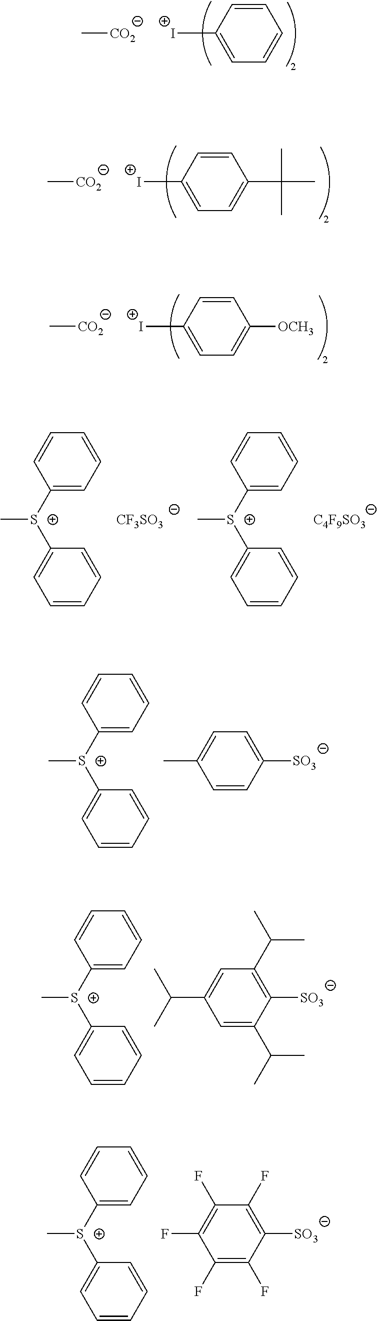

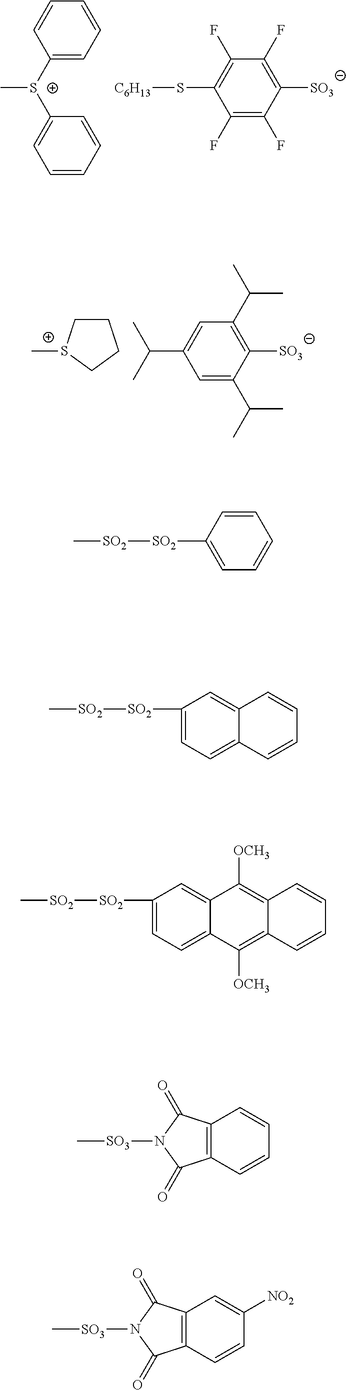

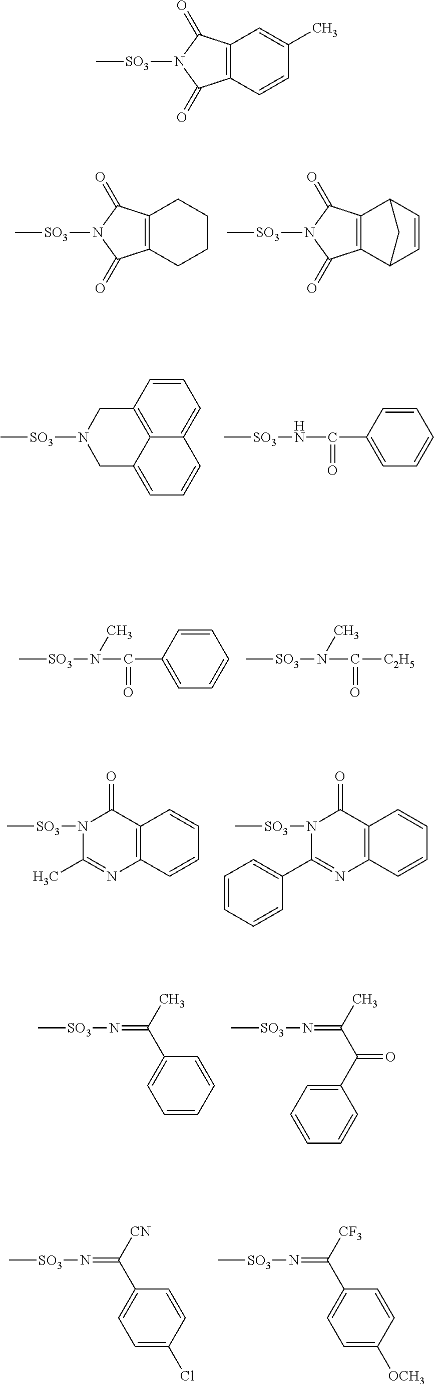

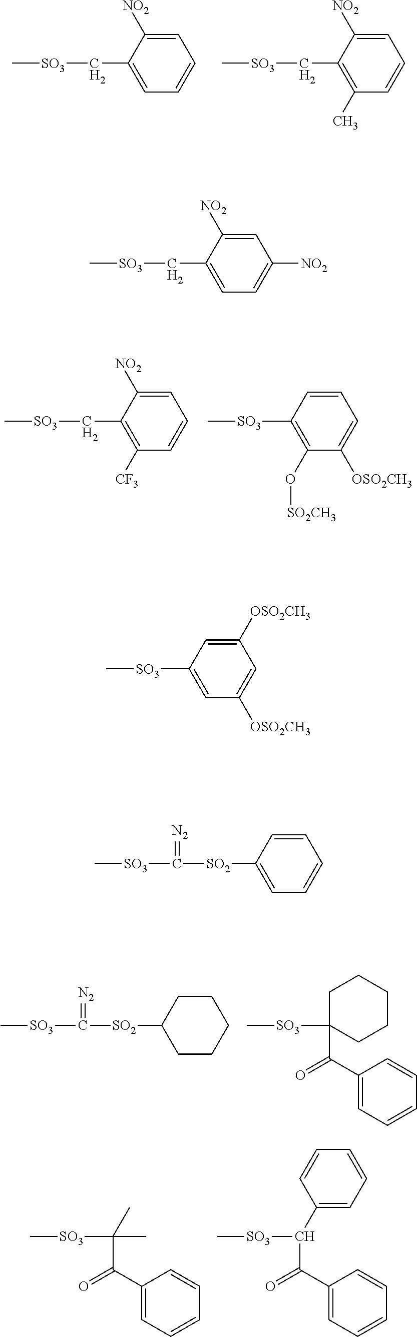

### [(G) Acid-Decomposable Group Capable of Decomposing by the Action of an Acid to Accelerate the Dissolution in an Alkali Developer]

In formulae (1A-1) and (1A-2), G represents an acid-decomposable group capable of decomposing by the action of an acid to accelerate the dissolution in an alkali developer and has the same definition as the (G) acid-decomposable group capable of decomposing by the action of an acid to accelerate the dissolution in an alkali developer, contained in the low molecular compound (1), and the preferred range is also the same.

### [(S) Dissolution Auxiliary Group Capable of Accelerating the Dissolution in an Alkali Developer]

The dissolution auxiliary group capable of accelerating the dissolution in an alkali developer, as S in formula (1A-1) and (1A-2), is the same as the dissolution auxiliary group capable of accelerating the dissolution in an alkali developer, represented by S in formula (1-1), and includes a group having solubility in an alkali developer and a group which reacts with an alkali developer to produce a group having solubility in an alkali developer.

Examples of the group having solubility in an alkali developer include a hydroxyl group, a carboxyl group, a sulfonamide group, a disulfonimide group, an acylsulfonylimide group, a diacylimide group and —C(OH)(Rf₁)(Rf₂) [wherein each of Rf₁ and Rf₂ independently represents a perfluoroalkyl group (preferably having a carbon number of 1 to 8)], with a hydroxyl group being preferred. Incidentally, —C(OH)(Rf₁)(Rf₂) is preferably —C(OH)(CF₃)₂.

As for the configuration of how the hydroxyl group as the group having solubility in an alkali developer is present, a hydroxyl group substituted directly on the aromatic ring is preferred, and a hydroxyl group substituted directly on the benzene or naphthalene ring is more preferred.

The group that reacts with an alkali developer to produce a group having solubility in an alkali developer is preferably a group having a lactone structure. Specific examples and preferred examples of the lactone structure are the same as those for S in formula (1-1).

The synthesis method of the compound (1A) for use in the present invention is not particularly limited, but, for example, the compound represented by formula (1A-1) can be synthesized by sequentially introducing the component Z, the component G and the component S into a compound (1-1S) having a plurality of hydroxyl groups (preferably hydroxyl groups directly bonded to an aromatic ring) (a compound described, for example, in JP-A-2003-183227, JP-A-10-120610, JP-A-11-322656, JP-A-2003-321423, JP-A-10-310545 and JP-A-2005-309421), through the hydroxyl group.

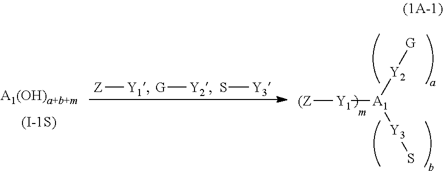

In the formula above, Z—Y₁′, G-Y₂′ and S—Y₃′ represent compounds capable of reacting with a hydroxyl group of the compound (1-1S) to produce bonds between Z—Y₁ and A₁, between G-Y₂ and A₁ and between S—Y₃ and A₁, respectively. The reaction employed when introducing respective components through a hydroxyl group is not particularly limited, but an alkylation (etherification) reaction or an esterification reaction is suitably utilized. In the case of utilizing an alkylation reaction, the terminal of each of Y₁′, Y₂′ and Y₃′ in the formula above is preferably a nucleophilic displaceable halogen atom (e.g., chlorine atom, bromine atom, iodine atom) or a sulfonic acid ester (e.g., p-toluenesulfonate, trifluoromethanesulfonate). In the case of utilizing an esterification reaction, the terminal of each of Y₁′, Y₂′ and Y₃′ is preferably an acid halide (e.g., acid chloride, acid fluoride). The order of introducing respective components Z, G and S is not particularly limited, and a convenient order can be appropriately selected according to the kind or conditions of the introduction reaction. Incidentally, a hydroxyl group remaining after the introduction of the components Z and G may be used directly as the component S. Furthermore, in synthesizing a compound (1-1S) having a plurality of hydroxyl groups (preferably hydroxyl groups directly bonded to an aromatic group), which is used as the starting material, a raw material having introduced thereinto (a part of) components Z, G and S may also be used as the starting material to synthesize a compound in which (a part of) components Z, G and S are introduced into a compound (1-1S).

The compound represented by formula (1A-2) can be synthesized, for example, as in the following route, by reacting n Xi components (I-2SB) having a component G (or a precursor thereof) and a component S (or a precursor thereof) with a component A (I-2SA) (n Xi components may be the same or different, but in view of synthetic suitability, n Xi components are preferably the same) to obtain (I-2SC) and further introducing a component Z. Incidentally, before or after the introduction of a component Z, an appropriate reaction (e.g., protection/deprotection reaction, functional group conversion reaction) may be performed.

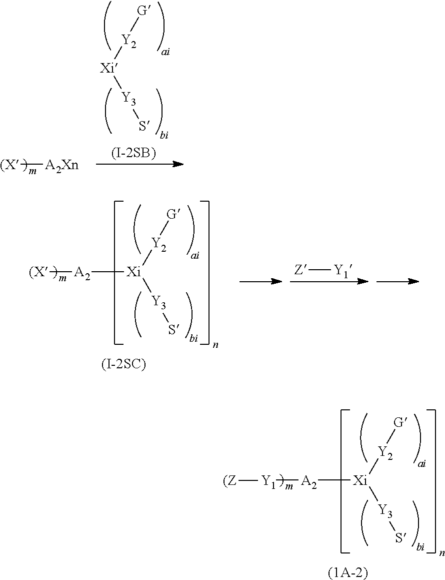

In the formula above, (I-2SB) represents a group capable of producing a bond between A₂ and Xi in (I-2SC) by the reaction with the A₂-X′ moiety in (1-2SA), Z′—Y₁′ represents a compound capable of producing a bond between A₂ and Y₁ in formula (1A-2) by the reaction with the A₂-X′ moiety (or a moiety after appropriate functional group conversion of the moiety) in (I-2SC), and Z′ represents Z or a group capable of converting into Z.

The reaction of (I-2SA) with (I-2SB) is not particularly limited, but a cross-coupling reaction using a transition metal catalyst may also be utilized, in addition to the above-described alkylation (etherification) reaction or esterification reaction. In the case of utilizing an alkylation reaction, it is preferred that X in (I-2SA) is a hydroxyl group directly bonded to an aromatic ring and Xi′ in (I-2SB) is a nucleophilic displaceable halogen atom (e.g., chlorine atom, bromine atom, iodine atom) or a sulfonic acid ester (e.g., p-toluenesulfonate, trifluoromethanesulfonate) or that X is a nucleophilic displaceable halogen atom (e.g., chlorine atom, bromine atom, iodine atom) or a sulfonic acid ester (e.g., p-toluenesulfonate, trifluoromethanesulfonate) and the terminal of Xi′ is a hydroxyl group directly bonded to an aromatic ring.

In the case of utilizing an alkylation reaction, it is preferred that X in (I-2SA) is a hydroxyl group and the terminal of Xi′ in (I-2SB) is an acid halide (e.g., acid chloride, acid fluoride) or that X is an acid halide (e.g., acid chloride, acid fluoride) and Xi′ is a hydroxy group. As the coupling reaction using a transition metal catalyst, for example, a cross-coupling reaction between an organometallic reagent (for example, lithium, magnesium, aluminum, gallium, indium, zinc, zirconium, boron, silicon, tin or bismuth can be used as the metal) and an organic halide (for example, iodine, bromine or chlorine can be used as the halogen element), a Heck reaction between an olefin compound and an organic halogen compound, and a Sonogashira reaction between an acetylene compound and an organic halogen compound, can be used. The transition metal catalyst which can be used is not particularly limited, but preferred examples thereof include palladium, ruthenium, rhodium, iridium, iron, copper, gold, silver, zirconium, zinc and nickel (or a compound or complex containing the metal).

Specific examples of the low molecular compound (1A) for use in the present invention are illustrated below, but the present invention is not limited thereto.

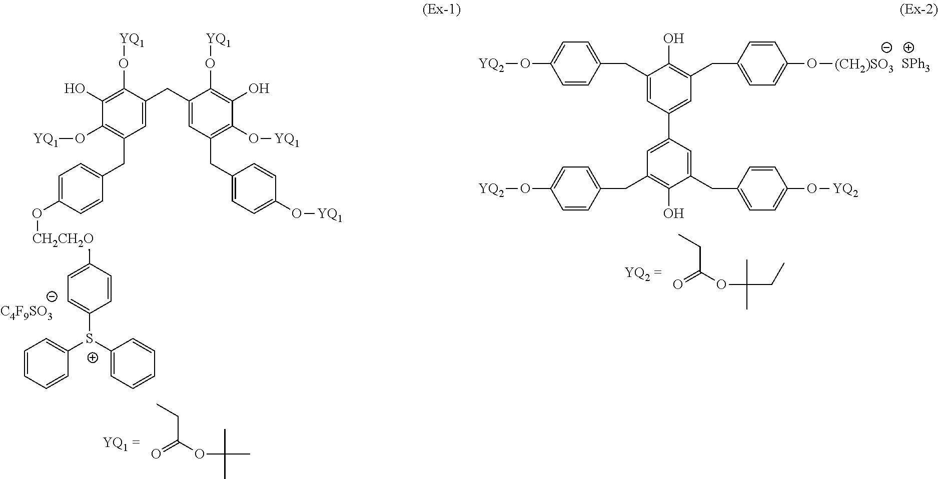

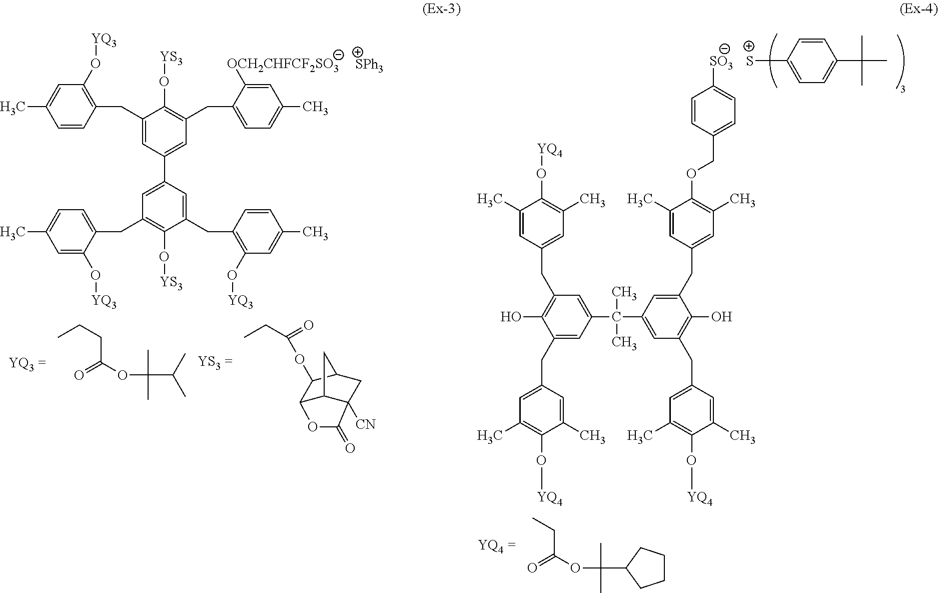

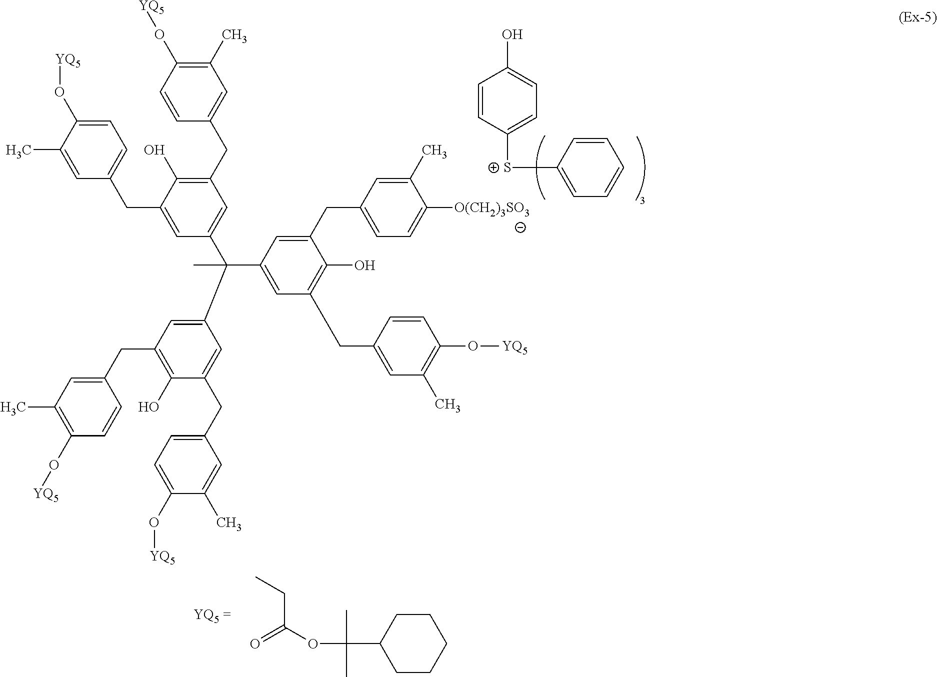

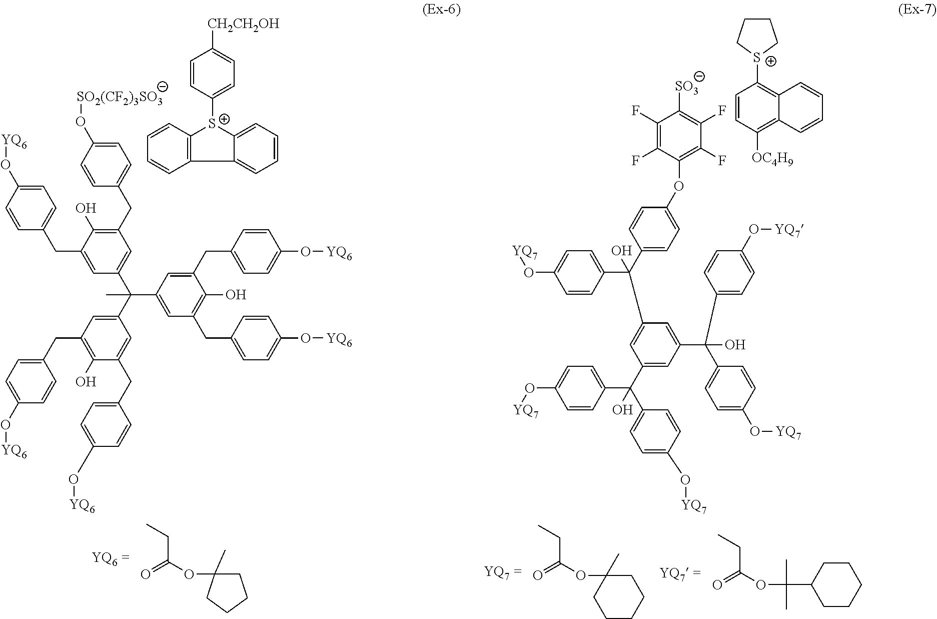

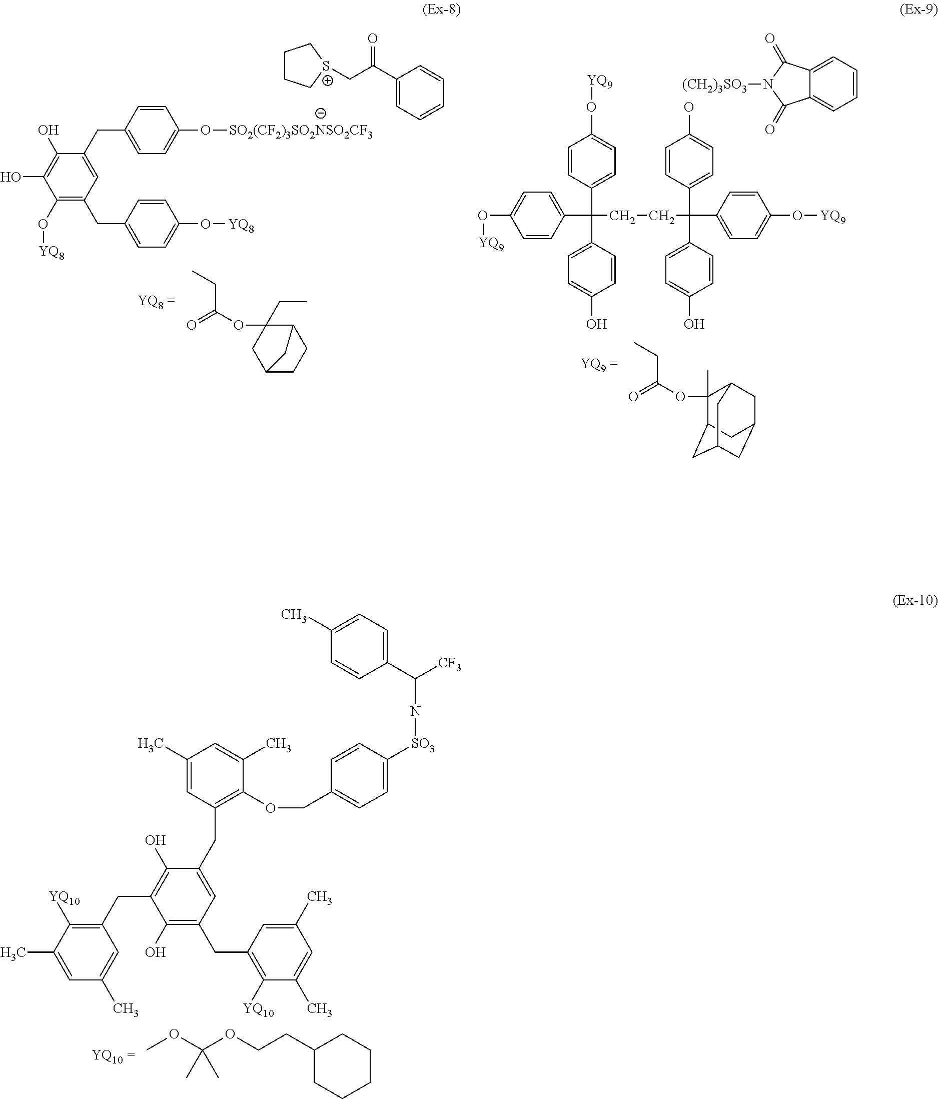

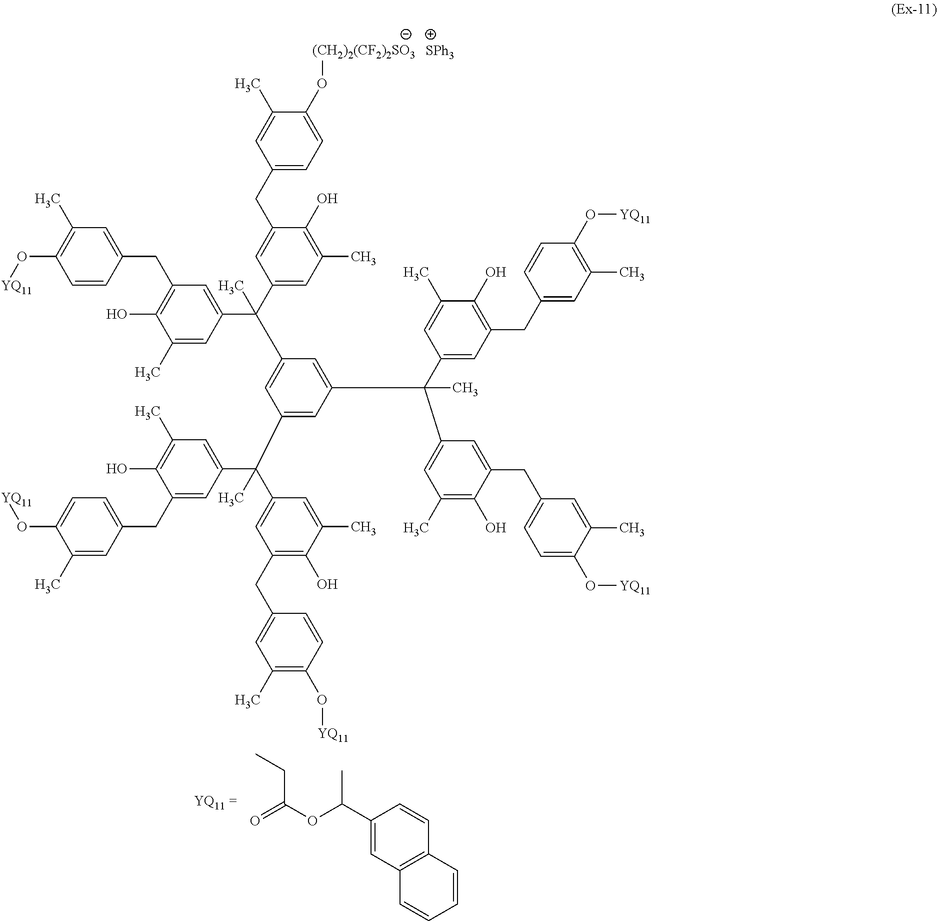

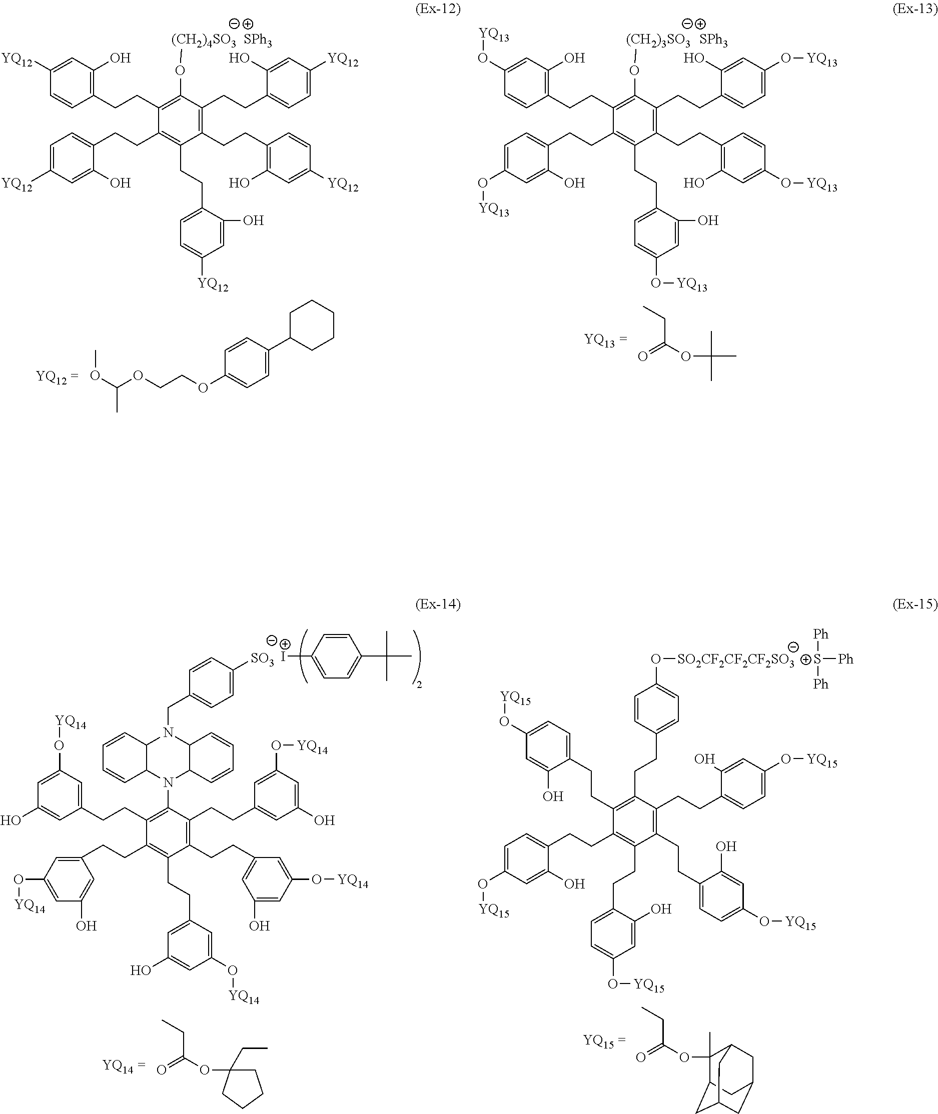

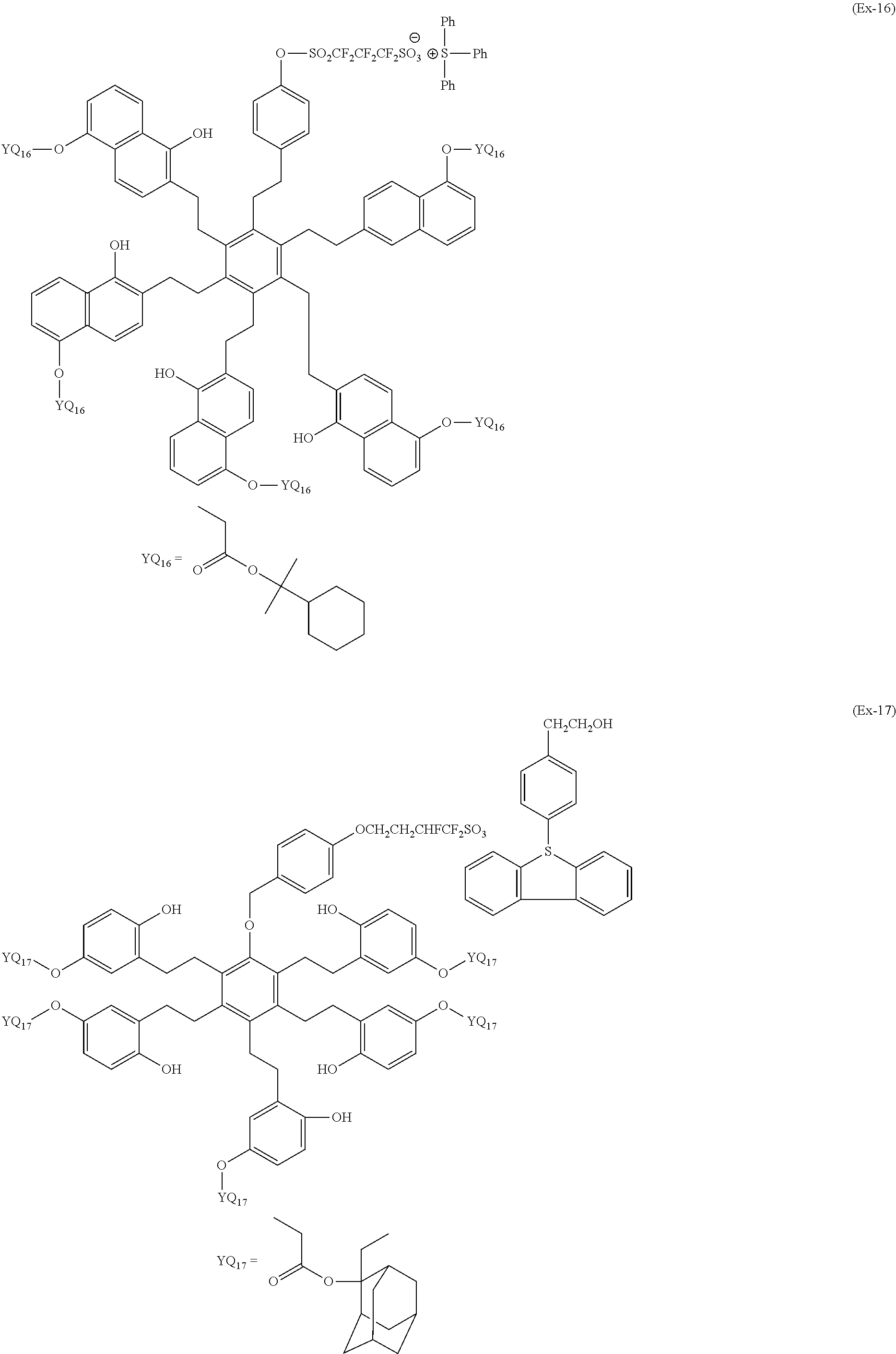

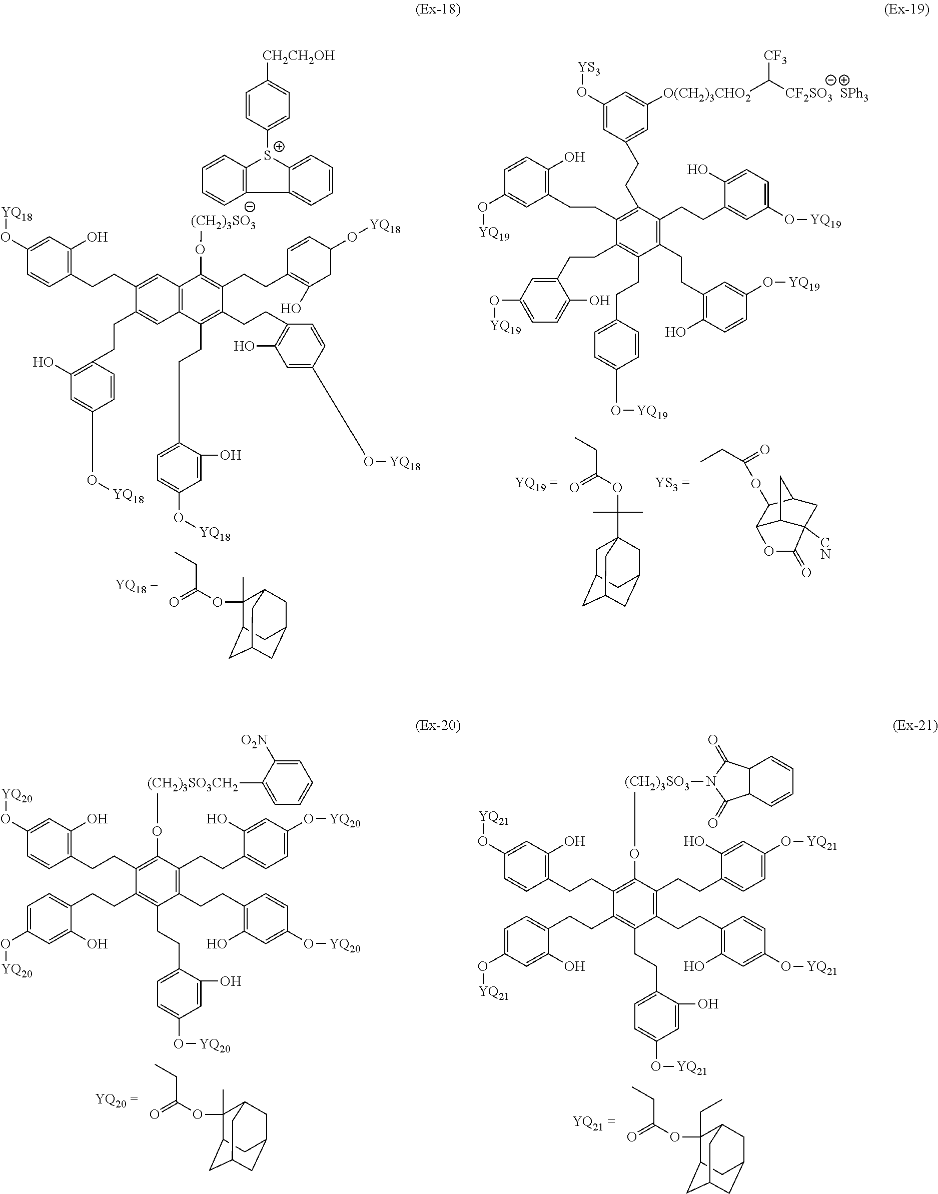

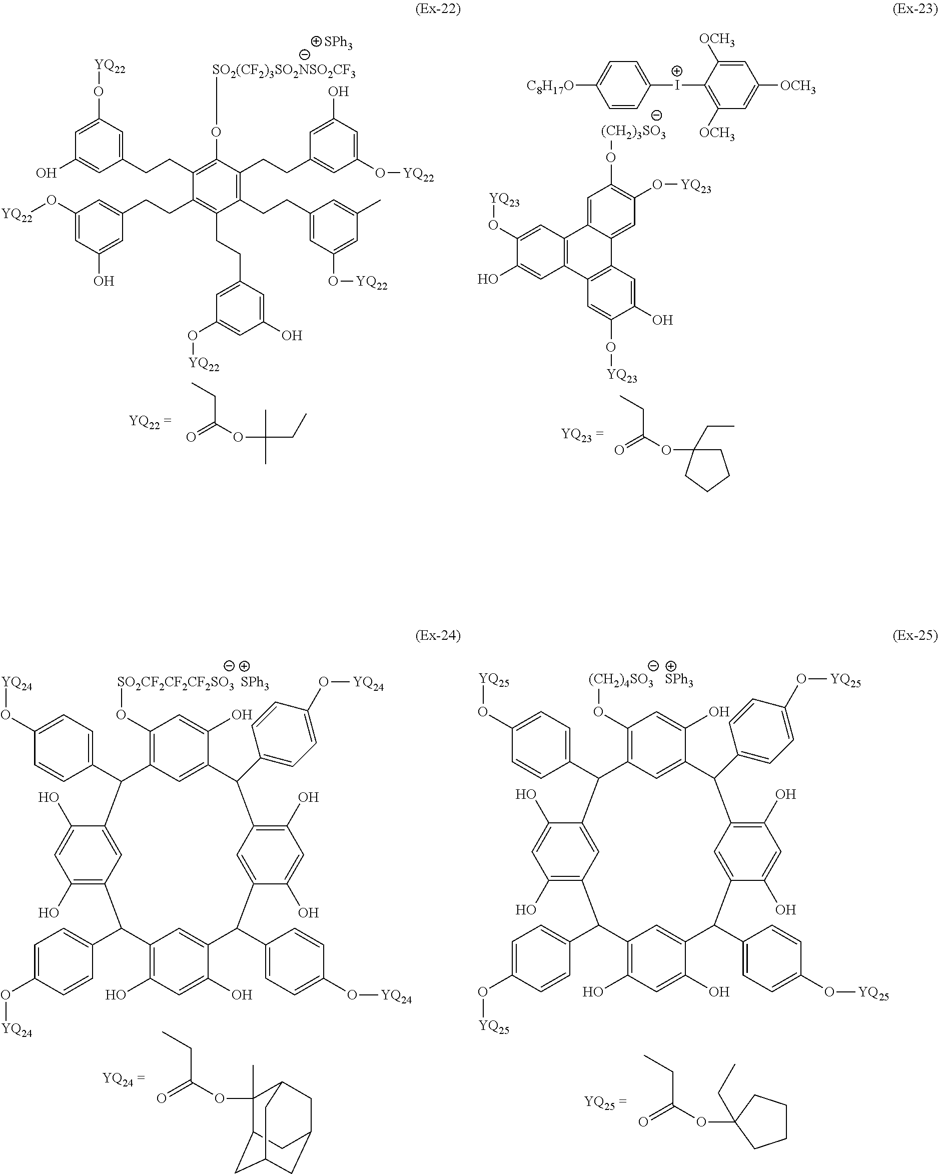

### [Solvent]

The solvent contained in the actinic ray-sensitive or radiation-sensitive composition of the present invention is preferably an organic solvent, and examples thereof include the followings.

Preferred examples of the alkylene glycol monoalkyl ether carboxylate include propylene glycol monomethyl ether acetate (PGMEA: 1-methoxy-2-acetoxypropane), propylene glycol monoethyl ether acetate, propylene glycol monopropyl ether acetate, ethylene glycol monomethyl ether acetate and ethylene glycol monoethyl ether acetate.

Preferred examples of the alkylene glycol monoalkyl ether include propylene glycol monomethyl ether (PGME: 1-methoxy-2-propanol), propylene glycol monoethyl ether, propylene glycol monopropyl ether, propylene glycol monobutyl ether, ethylene glycol monomethyl ether and ethylene glycol monoethyl ether.

Preferred examples of the alkyl lactate include methyl lactate, ethyl lactate, propyl lactate and butyl lactate.

Preferred examples of the alkyl alkoxypropionate include ethyl 3-ethoxypropionate, methyl 3-ethoxypropionate and ethyl 3-methoxypropionate.

Preferred examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoic lactone and α-hydroxy-γ-butyrolactone.

Preferred examples of the monoketone compound which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-2-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone and 3-methylcycloheptanone.

Preferred examples of the alkylene carbonate include propylene carbonate, vinylene carbonate, ethylene carbonate and butylene carbonate.

Preferred examples of the alkyl alkoxyacetate include 2-methoxyethyl acetate, 2-ethoxyethyl acetate, 2-(2-ethoxyethoxy)ethyl acetate and 1-methoxy-2-propyl acetate.

Preferred examples of the alkyl pyruvate include methyl pyruvate, ethyl pyruvate and propyl pyruvate.

The solvent that can be preferably used includes 2-heptanone, cyclopentanone, γ-butyrolactone, cyclohexanone, butyl acetate, ethyl lactate, ethylene glycol monoethyl ether acetate, propylene glycol monomethyl ether acetate, propylene glycol monomethyl ether, ethyl 3-ethoxypropionate, ethyl pyruvate, 2-ethoxyethyl acetate, 2-(2-ethoxyethoxy)ethyl acetate and propylene carbonate, but from the standpoint of reducing the outgas, a solvent having a boiling point of 150° C. or more at ordinary temperature under atmospheric pressure, such as 2-heptanone, propylene glycol monomethyl ether acetate and propylene glycol monomethyl ether, is more preferred. One of these solvents may be used alone, or two or more thereof may be used in combination.

The content of the solvent in the entire amount of the composition of the present invention may be appropriately adjusted according to the desired thickness or the like, but the composition is generally prepared such that the entire solid content concentration of the composition becomes from 0.5 to 30 mass %, preferably from 1.0 to 20 mass %, more preferably from 1.5 to 10 mass %.

Other than the low molecular compound (1) and the acid generator (2) described in the first embodiment or other than the low molecular compound (1A) described in the second embodiment, the actinic ray-sensitive or radiation-sensitive composition of the present invention may further contain, for example, a basic compound, a resin capable of decomposing by the action of an acid to increase the dissolution rate in an aqueous alkali solution, a conventional photo-acid generator, a surfactant, an acid-decomposable dissolution inhibiting compound, a dye, a plasticizer, a photosensitizer, a compound for accelerating the dissolution in a developer, and a compound having a proton acceptor functional group, if desired.

At this time, the total content of the low molecular compound (1) and the acid generator (2) in the first embodiment is preferably from 80 to 100 mass %, more preferably from 90 to 100 mass %, assuming that the amount of the components except for the solvent contained in the actinic ray-sensitive or radiation-sensitive composition is 100 mass %. If the content of the low molecular compound (1) is less than 60 mass %, the effects of the present invention cannot be sufficiently obtained, and the line edge roughness may be worsened.

Also, the content of the low molecular compound (1A) in the second embodiment is preferably from 80 to 100 mass %, more preferably from 90 to 100 mass %, assuming that the amount of the components except for the solvent contained in the actinic ray-sensitive or radiation-sensitive composition is 100 mass %. If the content of the low molecular compound (1A) is less than 80 mass %, the effects of the present invention cannot be sufficiently obtained, and the line edge roughness may be worsened.

### [Other Components]

### <Basic Compound>

The actinic ray-sensitive or radiation-sensitive composition of the present invention preferably contains a basic compound.

The basic compound is preferably a nitrogen-containing organic basic compound.

The usable compound is not particularly limited, but, for example, compounds classified into the following (1) to (4) are preferably used.

### (1) Compound Represented by the Following Formula (BS-1):

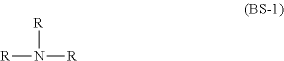

In formula (BS-1), each R independently represents any of a hydrogen atom, an alkyl group (linear or branched), a cycloalkyl group (monocyclic or polycyclic), an aryl group and an aralkyl group, but it is not allowed that three R's all are a hydrogen atom.

The carbon number of the alkyl group as R is not particularly limited but is usually from 1 to 20, preferably from 1 to 12.

The carbon number of the cycloalkyl group as R is not particularly limited but is usually from 3 to 20, preferably from 5 to 15.

The carbon number of the aryl group as R is not particularly limited but is usually from 6 to 20, preferably from 6 to 10. Specific examples thereof include a phenyl group and a naphthyl group.

The carbon number of the aralkyl group as R is not particularly limited but is usually from 7 to 20, preferably from 7 to 11. Specific examples thereof include a benzyl group.

In the alkyl group, cycloalkyl group, aryl group and aralkyl group as R, a hydrogen atom may be replaced by a substituent.

In the compound represented by formula (BS-1), it is preferred that only one of three R's is a hydrogen atom or all R's are not a hydrogen atom.

Specific examples of the compound of formula (BS-1) include tri-n-butylamine, tri-n-pentylamine, tri-n-octylamine, tri-n-decylamine, triisodecylamine, dicyclohexylmethylamine, tetradecylamine, pentadecyl amine, hexadecylamine, octadecylamine, didecylamine, methyloctadecyl amine, dimethylundecylamine, N,N-dimethyldodecylamine, methyldioctadecylamine, N,N-dibutylaniline, N,N-dihexylaniline, 2,6-diisopropylaniline and 2,4,6-tri(tert-butyl)aniline.

Also, one preferred embodiment is a compound where in formula (BS-1), at least one R is an alkyl group substituted with a hydroxyl group. Specific examples of the compound include triethanolamine and N,N-dihydroxyethylaniline.

The alkyl group as R may contain an oxygen atom in the alkyl chain to form an oxyalkylene chain. The oxyalkylene chain is preferably —CH₂CH₂O—. Specific examples thereof include tris(methoxyethoxyethyl)amine and compounds illustrated in U.S. Pat. No. 6,040,112, column 3, line 60 et seq.

### (2) Compound Having a Nitrogen-Containing Heterocyclic Structure

The heterocyclic structure may or may not have aromaticity, may contain a plurality of nitrogen atoms, and may further contain a heteroatom other than nitrogen. Specific examples of the compound include a compound having an imidazole structure (e.g., 2-phenylbenzimidazole), a compound having a piperidine structure (e.g., N-hydroxyethylpiperidine), a compound having a pyridine structure (e.g., 4-dimethylaminopyridine), and a compound having an antipyrine structure (e.g., antipyrine).

A compound having two or more ring structures is also suitably used. Specific examples thereof include 1,5-diazabicyclo[4.3.0]non-5-ene and 1,8-diazabicyclo[5.4.0]undec-7-ene.

### (3) Phenoxy Group-Containing Amine Compound

The phenoxy group-containing amine compound is a compound where the alkyl group of an amine compound has a phenoxy group at the terminal opposite the nitrogen atom. A compound having at least one oxyalkylene chain between the phenoxy group and the nitrogen atom is preferred. The number of oxyalkylene chains in one molecule is preferably from 3 to 9, more preferably from 4 to 6. Among oxyalkylene chains, —CH₂CH₂O— is preferred.

Specific examples of the compound include 2-[2-{2-(2,2-dimethoxy-phenoxyethoxy)ethyl}-bis-(2-methoxyethyl)]-amine and Compounds (C1-1) to (C3-3) illustrated in paragraph [0066] of U.S. Patent Application Publication No. 2007/0224539.

### (4) Ammonium Salt

An ammonium salt is also appropriately used. The ammonium salt is preferably a hydroxide or a carboxylate. More specifically, a tetraalkylammonium hydroxide typified by tetrabutylammonium hydroxide is preferred.

Other examples of the basic compound which can be used include compounds synthesized in Examples of JP-A-2002-363146 and compounds described in paragraph 0108 of JP-A-2007-298569.

As for the basic compound, one kind of a compound is used alone, or two or more kinds of compounds are used in combination.

The amount of the basic compound used is usually from 0.001 to 10 mass %, preferably from 0.01 to 5 mass %, based on the entire solid content of the actinic ray-sensitive or radiation-sensitive composition.

### <Resin Capable of Decomposing by the Action of an Acid to Increase the Dissolution Rate in an Aqueous Alkali Solution>

Other than the low molecular compound (1), the actinic ray-sensitive or radiation-sensitive composition of the present invention may contain a resin capable of decomposing by the action of an acid to increase the dissolution rate in an aqueous alkali solution.

The resin capable of decomposing by the action of an acid to increase the dissolution rate in an alkali developer (hereinafter, sometimes referred to as an “acid-decomposable resin”) is a resin having a group (“acid-decomposable group”) capable of decomposing by the action of an acid to produce an alkali-soluble group, in either one or both of the main chain and the side chain of the resin. Of these, a resin having an acid-decomposable group in the side chain is preferred.

The acid-decomposable resin can be obtained by reacting an acid-decomposable group precursor with an alkali-soluble resin or copolymerizing an acid-decomposable group-bonded alkali-soluble resin monomer with various monomers, as disclosed, for example, in European Patent 254853, JP-A-2-25850, JP-A-3-223860 and JP-A-4-251259.

In a resin having, for example, an alkali-soluble group such as —COOH group or —OH group, the acid-decomposable group is preferably a group where a hydrogen atom of the alkali-soluble group is replaced by a group capable of leaving by the action of an acid.

Specific preferred examples of the acid-decomposable group are the same as those of the acid-decomposable group described above for the component G in the low molecular compound (1) for use in the present invention.

The resin having an alkali-soluble group is not particularly limited, but examples thereof include a poly(o-hydroxystyrene), a poly(m-hydroxystyrene), a poly(p-hydroxystyrene) and a copolymer thereof; a hydrogenated poly(hydroxystyrene); poly(hydroxystyrene)s having a substituent represented by the following structure; a resin having a phenolic hydroxy group; an alkali-soluble resin having a hydroxystyrene structural unit, such as styrene-hydroxystyrene copolymer, α-methylstyrene-hydroxystyrene copolymer and hydrogenated novolak resin; and an alkali-soluble resin containing a repeating unit having a carboxyl group, such as (meth)acrylic acid and norbornene carboxylic acid.

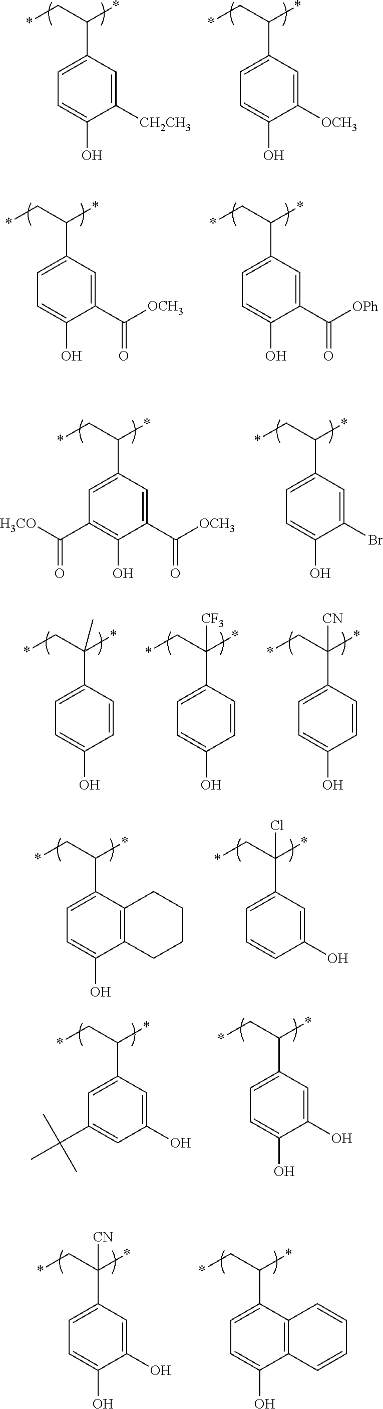

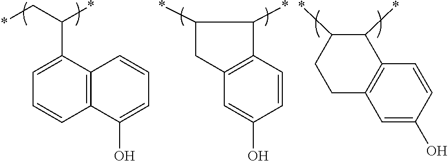

The alkali dissolution rate of such an alkali-soluble resin is preferably 170 Å/sec or more, more preferably 330 Å/sec or more, as measured (at 23° C.) in 2.38 mass % tetramethylammonium hydroxide (TMAH).

The content of the group capable of decomposing by the action of an acid is expressed by X/(X+Y) using the number (X) of repeating units having a group capable of decomposing by the action of an acid and the number (Y) of repeating units having an alkali-soluble group not protected with a group capable of leaving by the action of an acid. The content is preferably from 0.01 to 0.7, more preferably from 0.05 to 0.50, still more preferably from 0.05 to 0.40.

The weight average molecular weight of the acid-decomposable resin is preferably 50,000 or less, more preferably from 1,000 to 20,000, still more preferably from 1,000 to 10,000, as a value in terms of polystyrene determined by the GPC method. The polydispersity (Mw/Mn) of the acid-decomposable resin is preferably from 1.0 to 3.0, more preferably from 1.05 to 2.0, still more preferably from 1.1 to 1.7.

As for the acid-decomposable resin, two or more kinds of resins may be used in combination.

In the actinic ray-sensitive or radiation-sensitive composition of the present invention, the amount of the resin blended in the composition is preferably from 0 to 20 mass %, more preferably from 0 to 10 mass %, based on the entire solid content of the composition.

### <Acid Generator>

The actinic ray-sensitive or radiation-sensitive composition in the second embodiment of the present invention may contain a compound capable of generating an acid upon irradiation with an actinic ray or radiation (hereinafter, sometimes referred to as an “acid generator”), together with the low molecular compound (1A).

The actinic ray-sensitive or radiation-sensitive composition in the first embodiment of the present invention may contain an acid generator other than the above-described acid generator (2), that is, an acid generator capable of generating an acid of less than 305 Å³ in volume upon irradiation with an actinic ray or radiation.

As this acid generator, a photo-initiator for cationic photopolymerization, a photo-initiator for radical photopolymerization, a photodecoloring agent for dyes, a photodiscoloring agent, a compound known to generate an acid upon irradiation with an actinic ray or radiation and used for microresist and the like, or a mixture thereof may be appropriately selected and used.

Examples thereof include diazonium salt, phosphonium salt, sulfonium salt, iodonium salt, imidosulfonate, oxime sulfonate, diazodisulfone, disulfone and o-nitrobenzyl sulfonate. Specific examples of these include the compounds described in paragraphs to [0248] of U.S. Patent Application Publication 2008/0241737A1. Two or more kinds of these acid generators may be used in combination.

In the actinic ray-sensitive or radiation-sensitive composition according to the first embodiment of the present invention, in the case where an acid generator other than the acid generator (2) is used, one kind of an acid generator other than the acid generator (2) may be used alone or two or more kinds thereof may be used in combination. The content of the acid generator other than the acid generator (2) in the composition is preferably from 0 to 10 mass %, more preferably from 0 to 5 mass %, based on the entire solid content of the composition. The acid generator other than the acid generator (2) is not an essential component in the present invention, but for obtaining the effect by the addition, the acid generator is usually used in an amount of 0.01 mass % or more.

In the actinic ray-sensitive or radiation-sensitive composition according to the second embodiment of the present invention, in the case where an acid generator is used together with the low molecular compound (1A), one kind of an acid generator may be used alone or two or more kinds of acid generators may be used in combination. The content of the acid generator in the composition is preferably from 0 to 20 mass %, more preferably from 0 to 10 mass %, still more preferably from 0 to 7 mass %, based on the entire solid content of the composition. The acid generator is not an essential component in the present invention, but for obtaining the effect by the addition, the acid generator is usually used in an amount of 0.01 mass % or more.

### <Surfactant>

The actinic ray-sensitive or radiation-sensitive composition of the present invention preferably further contains a surfactant. The surfactant is preferably a fluorine-containing and/or silicon-containing surfactant.

Examples of the surfactant above include Megaface F176 and Megaface R08 produced by Dainippon Ink & Chemicals, Inc.; PF656 and PF6320 produced by OMNOVA; Troysol S-366 produced by Troy Chemical; Florad FC430 produced by Sumitomo 3M Inc.; and polysiloxane polymer KP-341 produced by Shin-Etsu Chemical Co., Ltd.

A surfactant other than the fluorine-containing and/or silicon-containing surfactant may also be used. Specific examples thereof include polyoxyethylene alkyl ethers and polyoxyethylene alkylaryl ethers.

In addition, known surfactants may be appropriately used. Examples of the surfactant which can be used include surfactants described in paragraph [0273] et seq. of U.S. Patent Application Publication No. 2008/0248425.

One kind of a surfactant may be used alone, or two or more kinds of surfactants may be used in combination.

The amount of the surfactant used is preferably from 0 to 2 mass %, more preferably from 0.001 to 1 mass %, based on the entire solid content of the actinic ray-sensitive or radiation-sensitive composition.

### <Acid-Decomposable Dissolution Inhibiting Compound>

The actinic ray-sensitive or radiation-sensitive composition of the present invention may contain a dissolution inhibiting compound having a molecular weight of 3,000 or less and being capable of decomposing by the action of an acid to increase the dissolution rate in an alkali developer (hereinafter, sometimes referred to as a “dissolution inhibiting compound”).

The dissolution inhibiting compound is preferably an alicyclic or aliphatic compound containing an acid-decomposable group, such as acid-decomposable group-containing cholic acid derivative described in Proceeding of SPIE, 2724, 355 (1996). Examples of the acid-decomposable group and alicyclic structure are the same as those described above with respect to the acid-decomposable resin.

In the case of irradiating the actinic ray-sensitive or radiation-sensitive composition of the present invention with electron beam or EUV light, the dissolution inhibiting compound is preferably a compound containing a structure where a phenolic hydroxyl group of a phenol compound is substituted with an acid-decomposable group. The phenol compound is preferably a compound containing from 1 to 9 phenol structures, more preferably from 2 to 6 phenol structures.

The molecular weight of the dissolution inhibiting compound for use in the present invention is 3,000 or less, preferably from 300 to 3,000, more preferably from 500 to 2,500.

### <Dye>

The suitable dye includes an oily dye and a basic dye.

### <Photosensitizer>

A photosensitizer can be added so as to enhance the acid generation efficiency during exposure.

The compound for accelerating dissolution in an alkali developer, which can be used in the present invention, is a low molecular compound having a molecular weight of 1,000 or less and having two or more phenolic OH groups or one or more carboxy groups. In the case of having a carboxyl group, an alicyclic or aliphatic compound is preferred. Examples of the phenol compound having a molecular weight of 1,000 or less include those described in JP-A-4-122938, JP-A-2-28531, U.S. Pat. No. 4,916,210 and European Patent 219294.

Also, a compound having a proton acceptor functional group described, for example, in JP-A-2006-208781 and JP-A-2007-286574 can also be suitably used in the composition of the present invention.

### <Pattern Forming Method>

The actinic ray-sensitive or radiation-sensitive composition of the present invention is coated on a support such as substrate to form a film. The thickness of the film is preferably from 0.02 to 0.1 μM.

The method for coating the composition on a substrate is preferably spin coating, and the spinning speed is preferably from 1,000 to 3,000 rpm.

For example, the actinic ray-sensitive or radiation-sensitive composition is coated on a substrate used in the production of a precision integrated circuit device by an appropriate coating method such as spinner or coater and dried to form a film. In this connection, a known antireflection film can be previously provided by coating. The substrate is not particularly limited and may be, for example, a quartz substrate having thereon an Si, Si/SiO₂, SiN, TiN or Cr layer.

The film is irradiated with electron beam (EB), X-ray or EUV light through a mask, if desired, then preferably baked, and further developed, whereby a good pattern can be obtained.

Incidentally, in the case of applying the composition of the present invention to the production of an information recording medium (more specifically, the production of a mold structure or a stamper for use in the production of an information recording medium) described above in “Background Art”, the exposure/lithography can be performed while rotating the substrate, that is, controlling the substrate to the r-O direction. For details of this method and the production of a mold structure by this method, refer to Japanese Patent 4,109,085 and JP-A-2008-162101, for example.

In the development step, an alkali developer is used as follows. The alkali developer which can be used is an alkaline aqueous solution such as inorganic alkalis (e.g., sodium hydroxide, potassium hydroxide, sodium carbonate, sodium silicate, sodium metasilicate, aqueous ammonia), primary amines (e.g., ethylamine, n-propylamine), secondary amines (e.g., diethylamine, di-n-butylamine), tertiary amines (e.g., triethylamine, methyldiethylamine), alcohol amines (e.g., dimethylethanolamine, triethanolamine), quaternary ammonium salts (e.g., tetramethylammonium hydroxide, tetraethylammonium hydroxide) and cyclic amines (e.g., pyrrole, piperidine).

In the alkali developer, alcohols and a surfactant may also be added in an appropriate amount.

The alkali concentration of the alkali developer is usually from 0.1 to 20 mass %.

The pH of the alkali developer is usually from 10.0 to 15.0.

Using the thus-formed pattern as a mask, for example, a semiconductor fine circuit or an imprint mold structure is fabricated by performing an etching treatment, ion injection and the like.

### EXAMPLES

The present invention is described in greater detail below by referring to Examples, but the contents of the present invention should not be construed as being limited thereto.

The first embodiment of the present invention is illustrated below.

### Synthesis Example 1

### Synthesis of Low Molecular Compound (B-6)

Low Molecular Compound (B-6) was synthesized by the following route.

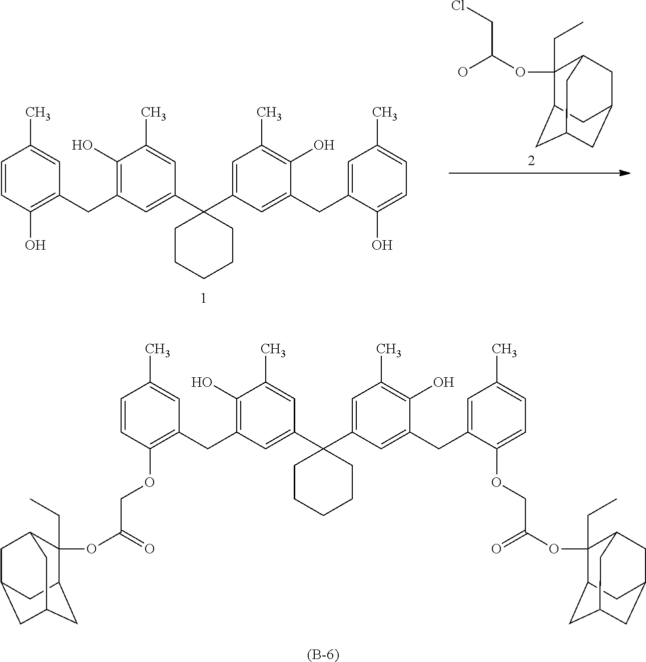

A mixed solution of Compound 1 (5.4 g), Compound 2 (5.2 g), potassium carbonate (3.45 g) and dimethylacetamide (100 ml) was stirred at 90° C. for 3 hours, and the reaction solution was cooled to room temperature, poured in ethyl acetate (300 ml)/aqueous 1 N hydrochloric acid (300 ml) and subjected to liquid separation. The organic layer was washed with water (300 ml× twice) and saturated brine (300 ml) and dried over sodium sulfate. The solvent was concentrated under reduced pressure, and the residue was purified through a silica gel column to obtain Compound (B-6) (2.2 g).

### Synthesis Example 2

### Synthesis of Low Molecular Compound (B-7)

Low Molecular Compound (B-7) was synthesized by the following route.

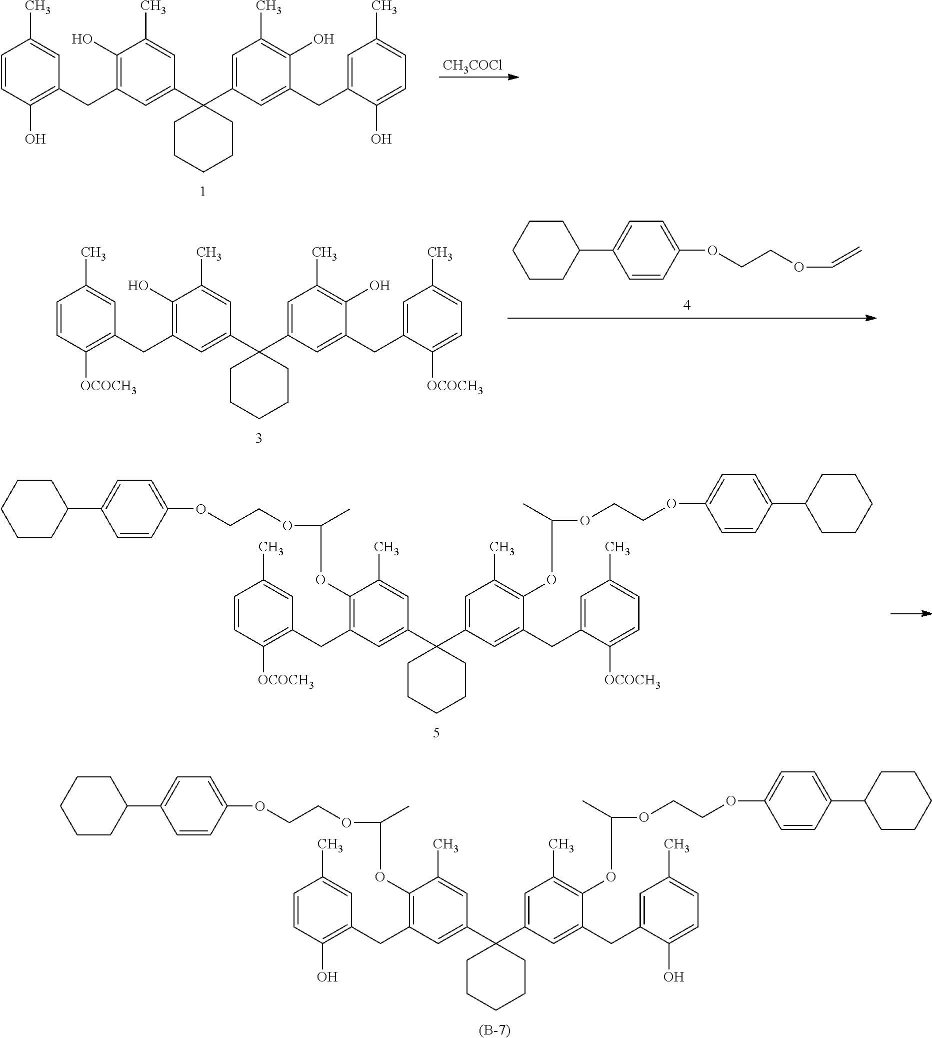

Diisopropylamine (2.0 g) was added dropwise to an acetonitrile (50 ml) solution of Compound 1 (5.4 g) at 0° C., and acetyl chloride (1.57 g) was further added dropwise. The reaction solution was stirred at room temperature for 1 hours and poured in ethyl acetate (300 ml)/aqueous 1 N hydrochloric acid (300 ml), and the resulting solution was subjected to liquid separation. The organic layer was washed with water (300 ml× twice) and saturated brine (300 ml) and dried over sodium sulfate. The solvent was concentrated under reduced pressure, and the residue was recrystallized from ethyl acetate/hexane to obtain Compound 3 (3.2 g).

An ethyl acetate (50 ml) solution of Compound 3 (3.2 g), Compound 4 (2.6 g) and camphorsulfonic acid (0.2 g) was stirred at room temperature for 5 hours to obtain a reaction solution containing Compound 5. To this reaction solution, a 28% sodium methoxide/methanol solution (2.5 g) was added, and the mixture was stirred at 40° C. for 3 hours in a nitrogen atmosphere. The resulting reaction solution was cooled to room temperature, then slowly poured in water (200 ml)/ethyl acetate (200 ml) and subjected to extraction. The organic layer was washed with water (200 ml× twice) and saturated brine (200 ml) and dried over sodium sulfate. The solvent was concentrated under reduced pressure, and the residue was purified through a silica gel column to obtain Compound (B-7) (2.1 g).

### Synthesis Example 3

### Synthesis of Low Molecular Compound (B-13)

Low Molecular Compound (B-13) was synthesized by the following route.

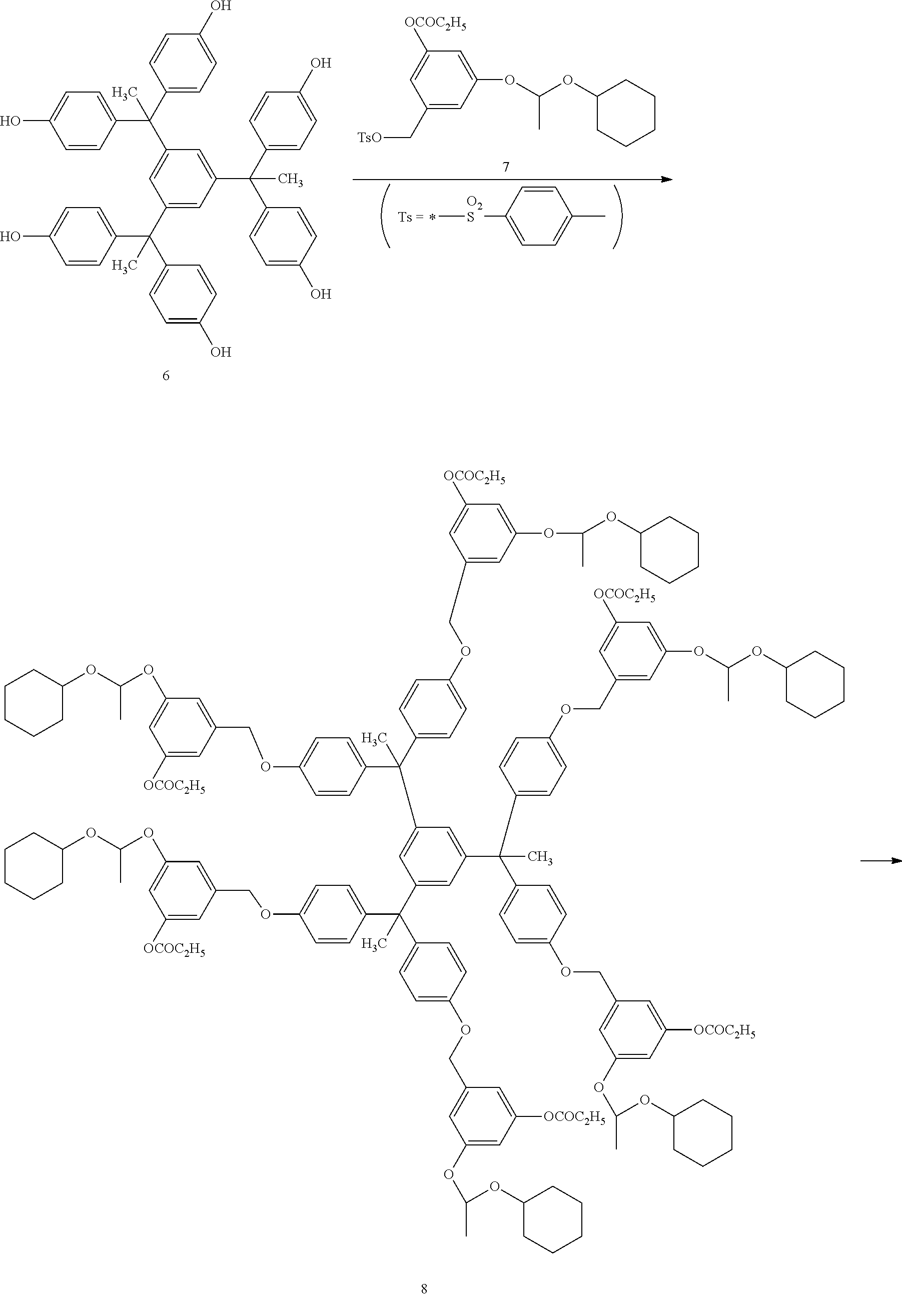

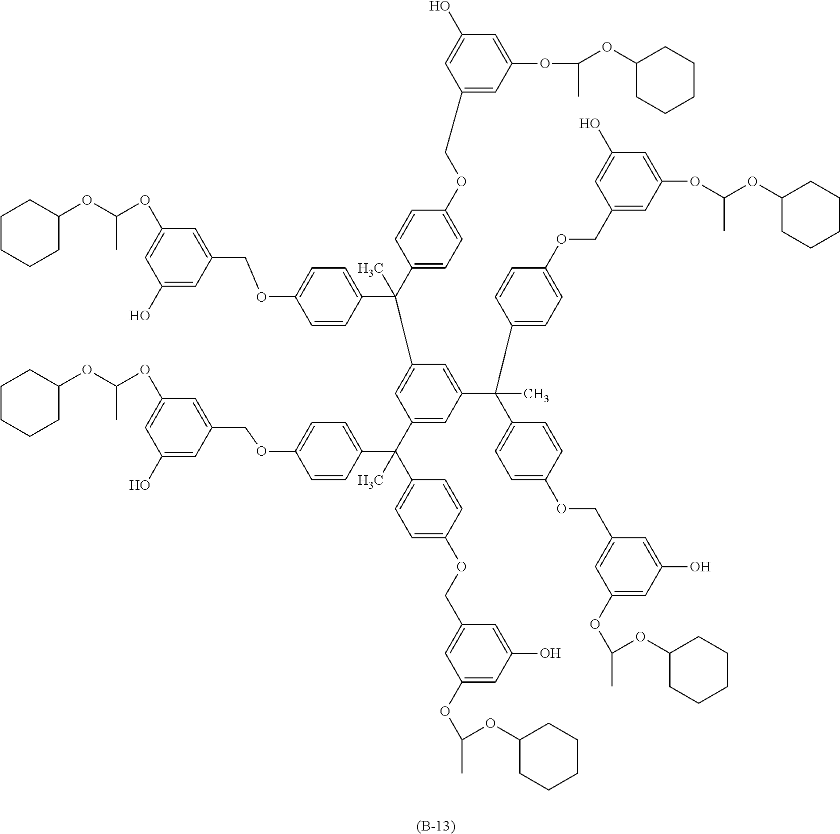

A dimethylacetamide mixed solution of Compound 6 (7.15 g), Compound 7 (47.6 g) and potassium carbonate (16.6 g) was stirred at 30° C. for 48 hours, and the reaction solution was poured in ethyl acetate (1 L)/water (1 L) and subjected to liquid separation. The organic layer was washed with water (500 ml× twice) and saturated brine (500 ml) and dried over sodium sulfate. The solvent was concentrated under reduced pressure, and the residue was purified through a silica gel column to obtain Compound 8 (9.6 g).

A 28% sodium methoxide/methanol solution (10 g) was added to an ethyl acetate (500 ml) solution of Compound 8 (9.6 g), and the mixture was stirred at 40° C. for 3 hours in a nitrogen atmosphere. The reaction solution was cooled to room temperature, then slowly poured in water (500 ml)/ethyl acetate (500 ml) and subjected to extraction. The organic layer was washed with water (500 ml× twice) and saturated brine (200 ml) and dried over sodium sulfate. The solvent was concentrated under reduced pressure, and the residue was purified through a silica gel column to obtain Compound (B-13) (2.65 g).

### Synthesis Example 4

### Synthesis of Low Molecular Compound (B-14)

Low Molecular Compound (B-14) was synthesized by the following route.

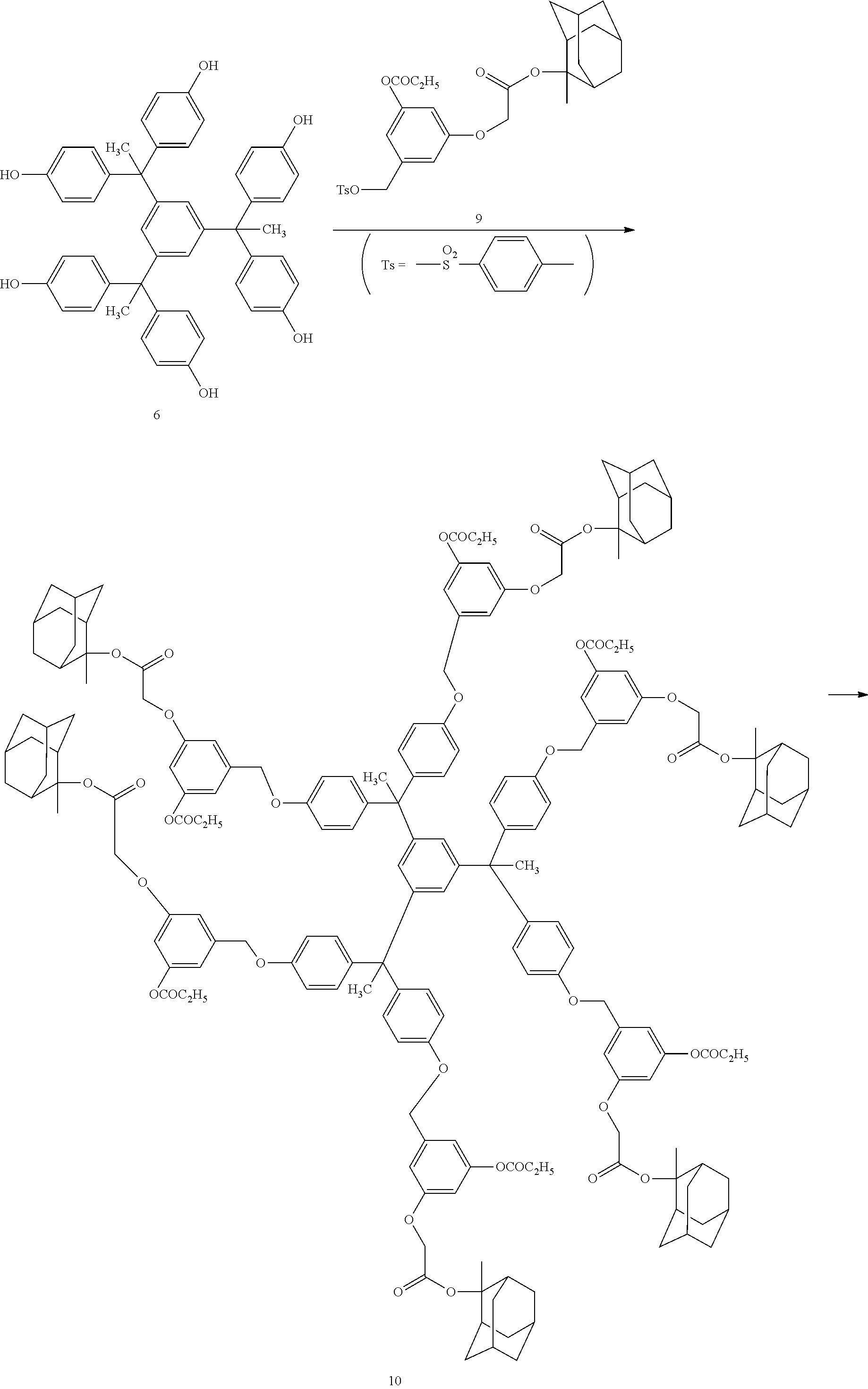

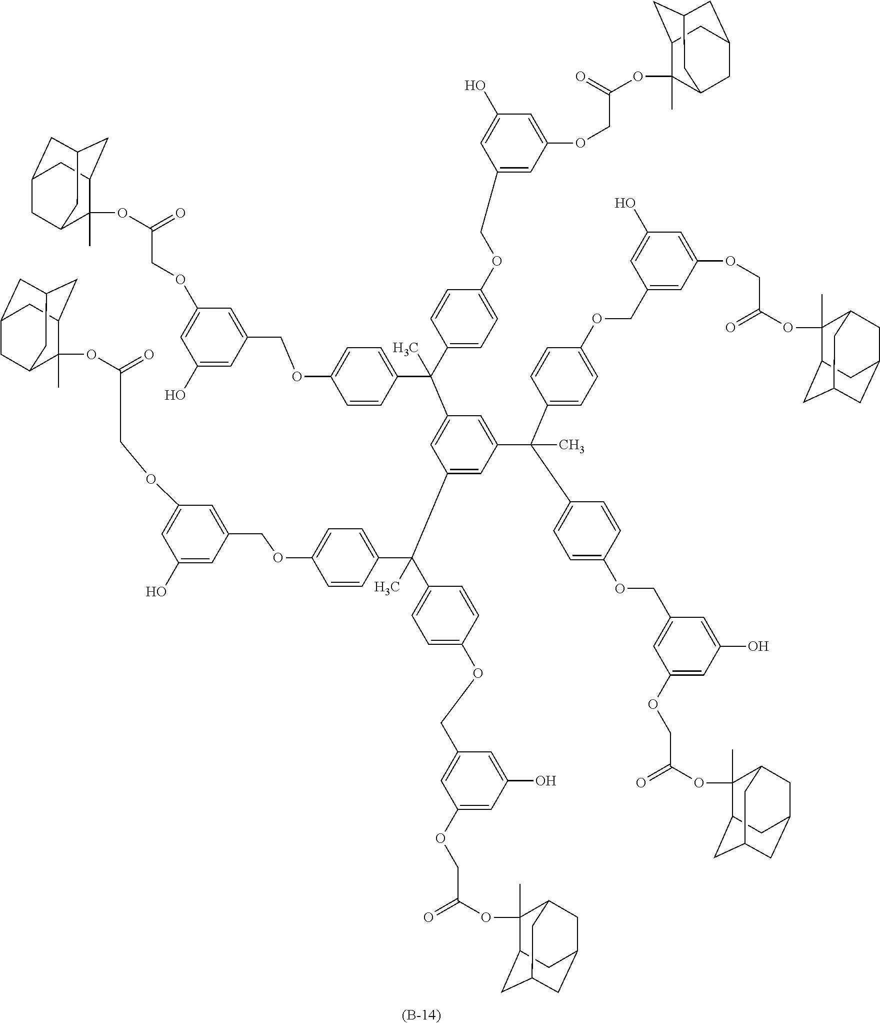

A dimethylacetamide mixed solution of Compound 6 (7.15 g), Compound 9 (55.7 g) and potassium carbonate (16.6 g) was stirred at 30° C. for 48 hours, and the reaction solution was poured in ethyl acetate (1 L)/water (1 L) and subjected to liquid separation. The organic layer was washed with water (500 ml× twice) and saturated brine (500 ml) and dried over sodium sulfate. The solvent was concentrated under reduced pressure, and the residue was purified through a silica gel column to obtain Compound 10 (11.2 g).

A 28% sodium methoxide/methanol solution (10 g) was added to an ethyl acetate (500 ml) solution of Compound 10 (11.2 g), and the mixture was stirred at 40° C. for 3 hours in a nitrogen atmosphere. The reaction solution was cooled to room temperature, then slowly poured in water (500 ml)/ethyl acetate (500 ml) and subjected to extraction. The organic layer was washed with water (500 ml× twice) and saturated brine (200 ml) and dried over sodium sulfate. The solvent was concentrated under reduced pressure, and the residue was purified through a silica gel column to obtain Compound (B-14) (4.1 g).

### Synthesis Example 5

### Synthesis of Low Molecular Compound (B-16)

Low Molecular Compound (B-16) was synthesized by the following route.

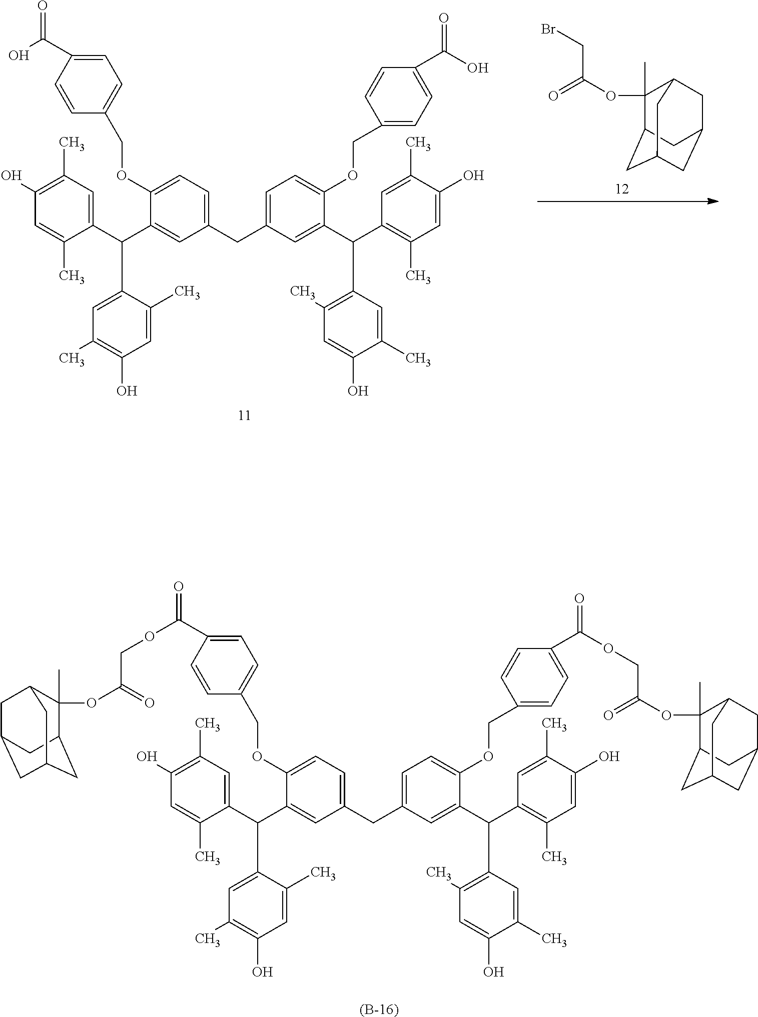

Triethylamine (1.2 g) was added dropwise to a tetrahydrofuran (30 ml) solution of Compound 11 (5.0 g) and Compound 12 (3.3 g) at 0° C., and the mixture was stirred at room temperature for 24 hours. The reaction solution was slowly poured in aqueous 1 N hydrochloric acid (300 ml)/ethyl acetate (300 ml) and subjected to liquid separation. The organic layer was washed with water (300 ml× twice) and saturated brine (300 ml) and dried over sodium sulfate. The solvent was concentrated under reduced pressure, and the residue was purified through a silica gel column to obtain Compound (B-16) (3.8 g).

### Synthesis Example 6

### Synthesis of Low Molecular Compound (B-18)

Low Molecular Compound (B-18) was synthesized by the following route.

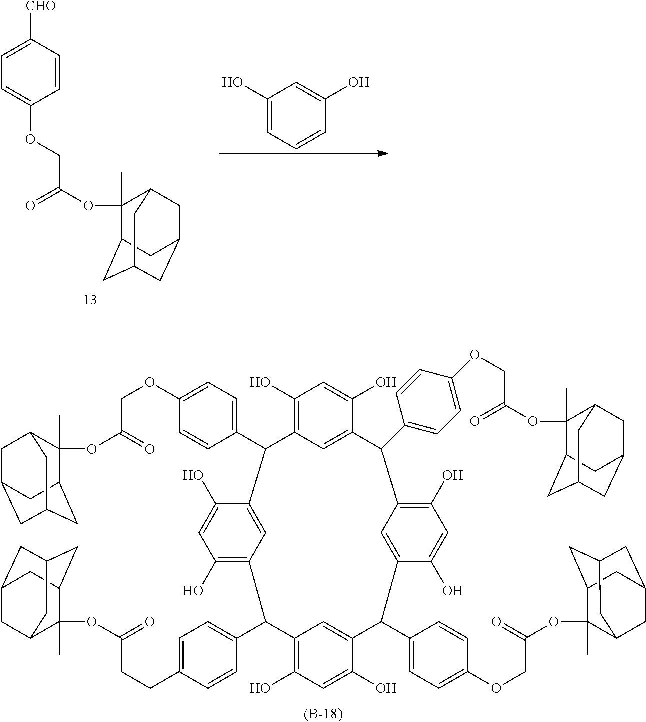

Aqueous hydrochloric acid (10 ml) was added to an ethanol (200 ml) solution of Compound 13 (9.0 g) and resorcinol (3.0 g), and the mixture was stirred at room temperature for 75 hours. The crystal produced was filtered, washed with water, dried and then purified through a silica gel column to obtain Compound (B-18).

### Synthesis Example 7

### Synthesis of Low Molecular Compound (B-19)

Low Molecular Compound (B-19) was synthesized by the following route.

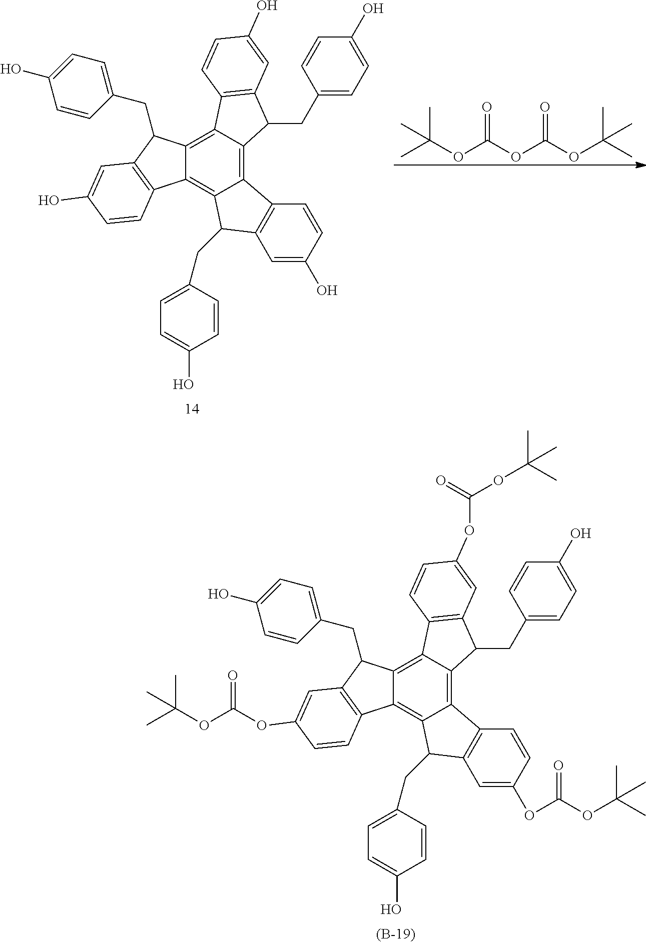

A tetrahydrofuran (180 ml) mixed solution of Compound 14 (3.5 g), di-tert-butyl dicarbonate (17.4 ml), 18-crown-6 (15.1 g) and potassium carbonate (10 g) was stirred at 40° C. for 1 hour and 30 minutes in an argon atmosphere, and the reaction solution was poured in ethyl acetate (500 ml)/water (500 ml) and subjected to liquid separation. The organic layer was washed with aqueous dilute hydrochloric acid (300 ml), aqueous sodium bicarbonate (300 ml), water (300 ml) and saturated brine (300 ml), and dried over sodium sulfate. The solvent was concentrated under reduced pressure, and the residue was purified through a silica gel column to obtain Compound (B-19).

### Synthesis Example 8

### Synthesis of Low Molecular Compound (B-31)

Low Molecular Compound (B-31) was synthesized by the following route.

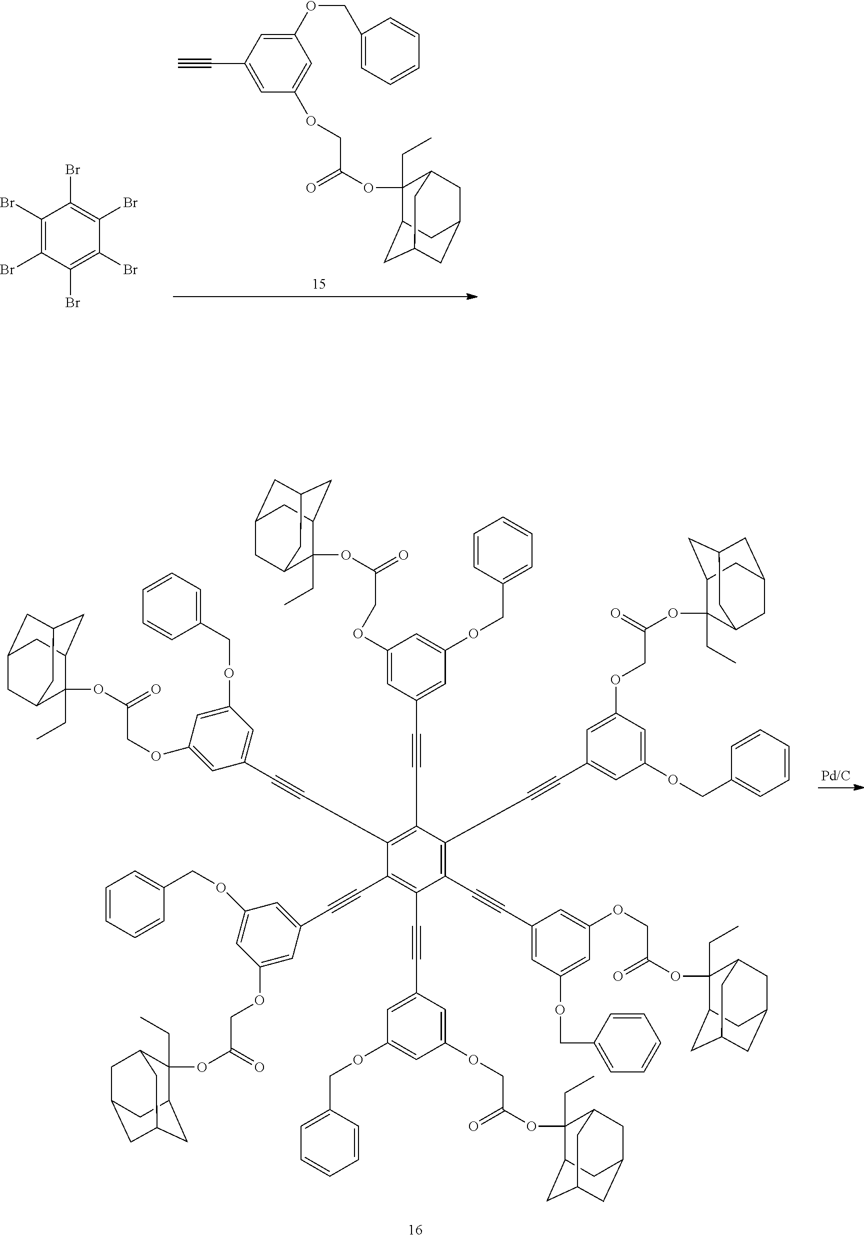

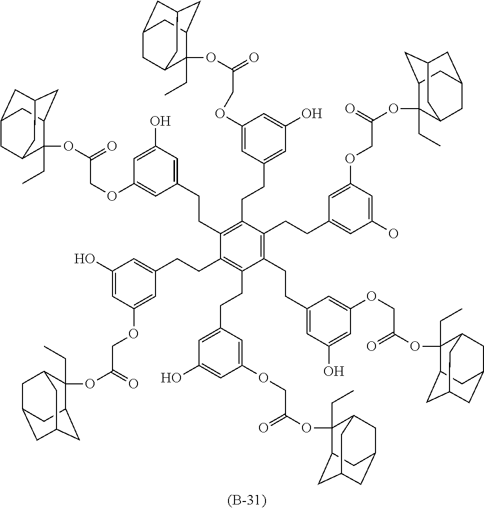

### Synthesis of Compound 16

A mixed solution of hexabromobenzene (1.0 g), Compound 15 (8.9 g), bisacetonitrile palladium(II) chloride complex (0.52 g), triphenylphosphine (2.62 g), cuprous chloride (0.76 g) and triethylamine (100 ml) was stirred at reflux temperature for 6 hours in a nitrogen atmosphere.

The resulting reaction solution was cooled to room temperature, then slowly poured in aqueous 1 N hydrochloric acid (300 ml)/ethyl acetate (300 ml) and subjected to extraction. The organic layer was washed with water (300 ml× twice) and saturated brine (300 ml) and dried over sodium sulfate. The solvent was concentrated under reduced pressure, and the residue was purified through a silica gel column to obtain Compound 16 (1.72 g).

### Synthesis of Compound (B-31)

An ethyl acetate (60 ml)/methanol (60 ml) solution of Compound 16 (1.72 g) and 0.5 mass % palladium carbon (0.15 g) was stirred at 50° C. for 4 hours under a hydrogen pressure (5.0 MPa), and the reaction solution was cooled to room temperature. After removing the catalyst by filtration, the filtrate was concentrated under reduced pressure, and the residue was purified through a silica gel column to obtain Compound (B-31) (0.73 g, 0.33 mmol).

Low Molecular Compounds (B-25) and (B-26) were synthesized in the same manner as Compound (B-31).

### Synthesis Example 9

### Synthesis of Acid Generator (A-1)

Aluminum chloride (20.5 g) was added to benzene (60.0 g) and the mixture was stirred under cooling at 3° C. Thereto, cyclohexyl chloride (121.2 g) was slowly added dropwise. After the dropwise addition, the reaction solution was stirred at room temperature for 5 hours and poured in ice water, and the organic layer was extracted with ethyl acetate. The obtained organic layer was distilled under reduced pressure at 40° C. and further distilled under reduced pressure at 170° C., and the residue was cooled to room temperature. Acetone (150 ml) was added thereto for recrystallization, and the precipitated crystal was collected by filtration to obtain 2,4,6-tricyclohexylbenzene (42 g).

2,4,6-Tricyclohexylbenzene (30 g) was dissolved in methylene chloride (50 ml), and the resulting solution was stirred under cooling at 3° C. Thereto, chlorosulfonic acid (15.2 g) was slowly added dropwise. After the dropwise addition, the reaction solution was stirred at room temperature for 5 hours, and ice (10 g) was poured thereinto. Furthermore, an aqueous 50% sodium hydroxide solution (40 g) was poured therein, and ethanol (20 g) was then added. This mixture was stirred at 50° C. for 1 hour, and insoluble matters were removed by filtration. The residue was distilled under reduced pressure at 40° C., and the precipitated crystal was collected by filtration and washed with hexane to obtain sodium 1,3,5-tricyclohexylbenzenesulfonate (30 g).

Triphenylsulfonium bromide (4.0 g) was dissolved in methanol (20 ml), and sodium 1,3,5-tricyclohexylbenzenesulfonate (5.0 g) dissolved in 20 ml of methanol was added thereto. This mixture was stirred at room temperature for 2 hours and after adding ion-exchanged water (50 ml), subjected to extraction with chloroform. The obtained organic layer was washed with water and distilled under reduced pressure at 40° C., and the obtained crystal was recrystallized from a methanol/ethyl acetate solvent to obtain Acid Generator (A-1) (5.0 g).

### Synthesis Example 10

### Synthesis of Acid Generator (A-20)

2,4,6-Tricyclohexylphenol (20.0 g) was dissolved in diethyl ether (800 ml), and in a nitrogen atmosphere, tetramethylethylenediamine (6.0 g) and n-butyllithium (a 1.63 M hexane solution) (31.9 ml) were added thereto at 0° C. This mixture was stirred at 0° C. for 1 hour, and the resulting reaction solution was added dropwise to a diethyl ether (200 ml) solution of 1,1,2,2,3,3-hexafluoropropane-1,3-disulfonyl difluoride (15.7 g) at 0° C. over 30 minutes. After the dropwise addition, the reaction solution was further stirred for 30 minutes, and distilled water (200 ml) was added. The organic layer was washed with saturated brine twice, and the solvent was removed. Thereto, methanol (100 ml) and an aqueous 1 N sodium hydroxide solution (100 ml) were added, and the mixture was stirred for 1 hour. After removing methanol by distillation, ethyl acetate was added, and the organic layer was washed with saturated brine twice. The solvent was removed by distillation, and the obtained solid was washed with hexane and dissolved in methanol (100 ml). Triphenylsulfonium bromide (10 g) was added thereto, and the mixture was stirred for 2 hours. After removing the solvent by distillation, ethyl acetate was added to the residue, and the organic layer was washed sequentially with an aqueous saturated sodium hydrogencarbonate solution and water. Thereafter, the solvent was removed to obtain Acid Generator (A-20) (23.5 g).

Acid Generators (A-3), (A-9), (A-13), (A-14), (A-17) and (A-23) were synthesized in the same manner as in the synthesis method above.

### Synthesis of Comparative Compound

### Synthesis of Polymer Compound (P-1)

1-Methoxy-2-propanol (50 ml) was heated at 80° C. under nitrogen flow and while stirring this solution, a mixed solution of p-hydroxystyrene (7.2 g, 60 mmol), 1-methyl-1-adamantyl methacrylate (9.4 g, 40 mmol), 0.8 g (3.5 mmol) of dimethyl 2,2′-azobisisobutyrate (V-601, produced by Wako. Pure Chemical Industries, Ltd.), and 1-methoxy-2-propanol (50 ml) was added dropwise over 5 hours. After the completion of dropwise addition, the solution was further stirred at 80° C. for 3 hours. The resulting reaction solution was allowed to cool and then subjected to reprecipitation from a large amount of hexane/ethyl acetate and vacuum drying to obtain Comparative Resin P-1 (12.3 g). ¹H-NMR of the obtained resin was measured, and the compositional ratio (65/35 by mol, repeating units starting from the left in the structural formula above) of the resin was calculated. Also, the weight average molecular weight (Mw: in terms of polystyrene) determined from GPC (carrier: N-methyl-2-pyrrolidone (NMP)) was Mw=4,800, and Mw/Mn=1.56.

Polymer Compound (P-2) was synthesized in the same manner as in the synthesis method of Polymer Compound (P-1).

### Examples 1-1 to 1-12 and Comparative Examples 1-1 to 1-13

### Evaluation (EB)

The components shown in Table 1 below were dissolved in the solvent shown in Table 1 to prepare a solution having an entire solid content concentration of 5.0 mass %, and this solution was filtered through a polytetrafluoroethylene filter having a pore size of 0.1 μm to obtain an actinic ray-sensitive or radiation-sensitive composition (positive resist solution). The prepared positive resist solution was uniformly coated on a hexamethyldisilazane-treated silicon substrate by using a spin coater and dried by heating on a hot plate at 110° C. for 90 seconds to form a resist film having a film thickness of 60 nm.

This resist film was then irradiated with electron beams by using an electron beam irradiation apparatus (HL750, manufactured by Hitachi Ltd., accelerating voltage: 50 KeV). Immediately after the irradiation, the resist film was heated on a hot plate at 120° C. for 90 seconds, developed using an aqueous tetramethylammonium hydroxide solution with a concentration of 2.38 mass % at 23° C. for 60 seconds, rinsed with pure water for 30 seconds and dried to form a line-and-space pattern. The obtained pattern was evaluated by the following methods. The evaluation results are shown in the same Table.

### [Sensitivity]

The cross-sectional profile of the obtained pattern was observed using a scanning electron microscope (S-9220, manufactured by Hitachi Ltd.). The minimum irradiation energy when resolving a 100-nm line (line:space=1:1) was defined as the sensitivity.

### [Resolution]

The limiting resolution (the minimum line width when the line and space were separated and resolved) with the irradiation dose giving the sensitivity above was defined as the resolution.

### [Line Edge Roughness (LER)]

With respect to the region of 50 μm in the longitudinal direction of a 100-nm line pattern at the irradiation dose giving the sensitivity above, the distance from a reference line where the edge should be present was measured at arbitrary 30 points by a scanning electron microscope (S-9220, manufactured by Hitachi, Ltd.). From the values obtained, the standard deviation was determined, and 3σ was computed.

### [Pattern Profile]

The cross-sectional profile of a 100-nm line pattern at the irradiation dose giving the sensitivity above was observed using a scanning electron microscope (S-4300, manufactured by Hitachi, Ltd.) and evaluated on a 3-step scale, that is, rectangular, slightly tapered, and tapered.

### [Dry Etching Resistance]

A resist film having a film thickness of 60 nm was prepared in the same manner as above and subjected to dry etching with an Ar/C₄F₉/O₂=100:4:2 gas for 2 minutes by using a dry etcher (U-621) manufactured by Hitachi High-Technologies Corporation, and the etching rate per second was calculated from the residual film amount measured.

TABLE 1
Evaluation Results in EB Exposure

| | Low | | | | | |
|---|---|---|---|---|---|---|
| | Molecular | Acid Gener- | Volume | Polymer | Basic | |
| | Compound | ator (2) | of Acid | Compound | Compound | Surfactant |
| | (1) (concen- | (concen- | Generated | (concen- | (concen- | (concen- |
| | tration)*¹ | tration)*¹ | (Å³) | tration)*¹ | tration)*¹ | tration)*¹ |
| Example 1-1 | (B-6) | (A-1) | 437 | P-1 | C-1 | W-1 |
| | (42.65) | (13.65) | | (42.65) | (1) | (0.05) |
| Example 1-2 | (B-7) | (A-3) | 437 | P-2 | C-1 | W-1 |
| | (42.0) | (14.95) | | (42.0) | (1) | (0.05) |
| Example 1-3 | (B-13) | (A-9) | 437 | P-2 | C-1 | W-1 |
| | (61.80) | (13.65) | | (23.50) | (1) | (0.05) |
| Example 1-4 | (B-14) | (A-14) | 347 | none | C-1 | W-2 |
| | (85.30) | (13.65) | | | (1) | (0.05) |
| Example 1-5 | (B-16) | (A-13) | 380 | P-1 | C-2 | none |
| | (57.50) | (13.7) | | (27.80) | (1) | |
| Example 1-6 | (B-18) | (A-17) | 380 | none | C-1 (0.5) + | W-1 (0.025) + |
| | (85.30) | (13.65) | | | C-2 (0.5) | W-2 (0.025) |
| Example 1-7 | (B-19) | (A-20) | 526 | P-1 | C-2 | W-1 |
| | (47.70) | (15.00) | | (36.25) | (1) | (0.05) |
| Example 1-8 | (B-25) | (A-23) | 426 | none | C-1 | W-1 |
| | (83.95) | (15.00) | | | (1) | (0.05) |
| Example 1-9 | (B-26) | (A-1) | 437 | none | C-1 | W-1 |
| | (85.30) | (13.65) | | | (1) | (0.05) |
| Example 1-10 | (B-31) | (A-1) | 437 | none | C-1 | W-1 |
| | (85.30) | (13.65) | | | (1) | (0.05) |
| Example 1-11 | (B-31) | (A-1) | 437 | (P-1) | C-1 | W-2 |
| | (56.90) | (13.65) | | (28.40) | (1) | (0.05) |
| Example 1-12 | (B-31) | (A-20) | 526 | none | C-1 | W-3 |
| | (83.95) | (15.00) | | | (1) | (0.05) |
| Comparative | (B-6) | (R-1) | 186 | P-1 | C-1 | W-1 |
| Example 1-1 | (45.0) | (8.95) | | (45.0) | (1) | (0.05) |
| Comparative | (B-6) | (R-2) | 303 | P-1 | C-1 | W-1 |
| Example 1-2 | (44.25) | (10.45) | | (44.25) | (1) | (0.05) |
| Comparative | none | (A-1) | 437 | P-1 | C-1 | W-1 |
| Example 1-3 | | (13.65) | | (85.30) | (1) | (0.05) |
| Comparative | (B-7) | (R-2) | 303 | P-2 | C-1 | W-1 |
| Example 1-4 | (43.65) | (11.65) | | (43.65) | (1) | (0.05) |
| Comparative | none | (A-3) | 437 | P-2 | C-1 | W-1 |
| Example 1-5 | | (15.00) | | (83.95) | (1) | (0.05) |
| Comparative | (B-13) | (R-2) | 303 | P-1 | C-1 | W-1 |
| Example 1-6 | (63.40) | (11.30) | | (24.25) | (1) | (0.05) |
| Comparative | (B-14) | (R-3) | 284 | none | C-1 | W-2 |
| Example 1-7 | (88.05) | (10.90) | | | (1) | (0.05) |
| Comparative | (B-16) | (R-2) | 303 | P-1 | C-2 | W-3 |
| Example 1-8 | (59.15) | (11.30) | | (28.5) | (1) | (0.05) |
| Comparative | (B-18) | (R-3) | 284 | none | C-1 (0.5) + | W-1 (0.025) + |
| Example 1-9 | (87.75) | (11.20) | | | C-2 (0.5) | W-2 (0.025) |
| Comparative | (B-19) | (R-3) | 284 | P-1 | C-2 | W-1 |
| Example 1-10 | (50.0) | (11.00) | | (37.95) | (1) | (0.05) |
| Comparative | (B-25) | (R-3) | 284 | none | C-1 | W-1 |
| Example 1-11 | (87.65) | (11.30) | | | (1) | (0.05) |
| Comparative | (B-26) | (R-2) | 303 | none | C-1 | W-1 |
| Example 1-12 | (87.65) | (11.30) | | | (1) | (0.05) |
| Comparative | (B-31) | (R-2) | 303 | none | C-1 | W-1 |
| Example 1-13 | (87.65) | (11.30) | | | (1) | (0.05) |

| | Organic | | | | | Dry |
|---|---|---|---|---|---|---|
| | Solvent | | | | | Etching |
| | (mixing | Sensitivity | Resolution | Pattern | LER | Resistance |
| | ratio)*² | (μC/cm²) | (nm) | Profile | (nm) | (nm/s) |
| Example 1-1 | S1/S2 | 30.5 | 70 | rectangular | 4.8 | 0.20 |
| | (60/40) | | | | | |
| Example 1-2 | S1/S3 | 35.7 | 65 | rectangular | 4.5 | 0.21 |
| | (50/50) | | | | | |
| Example 1-3 | S1/S4 | 33.5 | 65 | rectangular | 4.6 | 0.22 |
| | (60/40) | | | | | |
| Example 1-4 | S1/S3 | 28.5 | 60 | rectangular | 4.3 | 0.22 |
| | (50/50) | | | | | |
| Example 1-5 | S1/S3 | 31.5 | 65 | rectangular | 4.8 | 0.23 |
| | (50/50) | | | | | |
| Example 1-6 | S1/S2/S4 | 29.5 | 60 | rectangular | 4.5 | 0.20 |
| | (30/30/40) | | | | | |
| Example 1-7 | S1/S3 | 31.5 | 60 | rectangular | 4.3 | 0.21 |
| | (50/50) | | | | | |
| Example 1-8 | S1/S2 | 27.5 | 60 | rectangular | 4.2 | 0.20 |
| | (60/40) | | | | | |
| Example 1-9 | S1/S3 | 26.5 | 60 | rectangular | 4.1 | 0.17 |
| | (50/50) | | | | | |
| Example 1-10 | S1/S3 | 27.1 | 60 | rectangular | 4.1 | 0.19 |
| | (50/50) | | | | | |
| Example 1-11 | S1/S3 | 28.5 | 60 | rectangular | 4.5 | 0.20 |
| | (50/50) | | | | | |
| Example 1-12 | S1/S3 | 27.0 | 60 | rectangular | 4.0 | 0.19 |
| | (50/50) | | | | | |
| Comparative | S1/S2 | 29.8 | 80 | tapered | 6.5 | 0.25 |
| Example 1-1 | (60/40) | | | | | |
| Comparative | S1/S2 | 31.1 | 70 | rectangular | 5.1 | 0.22 |
| Example 1-2 | (60/40) | | | | | |
| Comparative | S1/S2 | 36.4 | 80 | rectangular | 5.4 | 0.20 |
| Example 1-3 | (60/40) | | | | | |
| Comparative | S1/S3 | 36.0 | 70 | rectangular | 5.1 | 0.23 |
| Example 1-4 | (50/50) | | | | | |
| Comparative | S1/S3 | 35.8 | 65 | rectangular | 4.8 | 0.25 |
| Example 1-5 | (50/50) | | | | | |
| Comparative | S1/S4 | 34 | 70 | rectangular | 5 | 0.24 |
| Example 1-6 | (60/40) | | | | | |
| Comparative | S1/S3 | 30.5 | 65 | tapered | 5.2 | 0.25 |
| Example 1-7 | (50/50) | | | | | |
| Comparative | S1/S3 | 32.2 | 70 | rectangular | 5.4 | 0.25 |
| Example 1-8 | (50/50) | | | | | |
| Comparative | S1/S2/S4 | 30.5 | 65 | rectangular | 5.1 | 0.23 |
| Example 1-9 | (30/30/40) | | | | | |
| Comparative | S1/S3 | 32.5 | 65 | rectangular | 4.8 | 0.24 |
| Example 1-10 | (50/50) | | | | | |
| Comparative | S1/S2 | 29.5 | 70 | rectangular | 5.1 | 0.23 |
| Example 1-11 | (60/40) | | | | | |
| Comparative | S1/S3 | 27.5 | 65 | rectangular | 4.9 | 0.2 |
| Example 1-12 | (50/50) | | | | | |
| Comparative | S1/S3 | 28.1 | 65 | rectangular | 5 | 0.22 |
| Example 1-13 | (50/50) | | | | | |

*¹mass % in the entire sold content,
*²ratio by mass.

Structures of the polymer compounds, basic compounds and acid generators used in Examples and Comparative Examples are shown below.

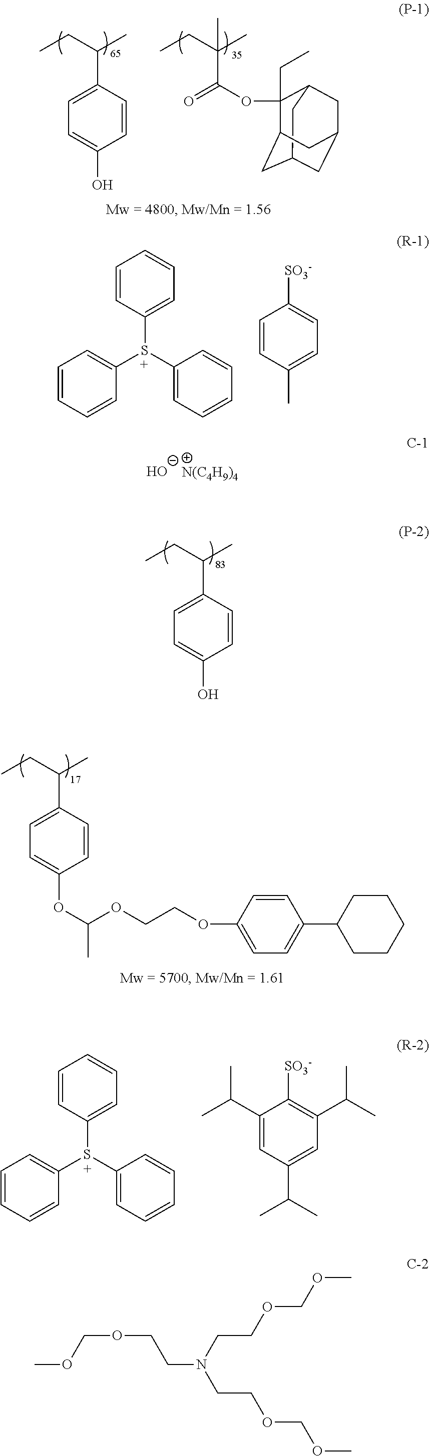

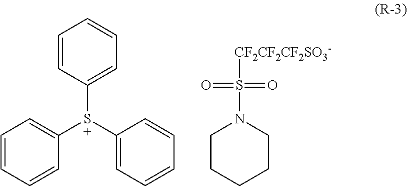

Surfactants and solvents used in Examples and Comparative Examples are set forth below.

### [Surfactant]

W-1: Megaface F176 (produced by Dainippon Ink & Chemicals, Inc., fluorine-containing)
W-2: Megaface R08 (produced by Dainippon Ink & Chemicals, Inc., fluorine- and silicon-containing)
W-3: Polysiloxane polymer (produced by Shin-Etsu Chemical Co., Ltd., silicon-containing)

### [Solvent]

S1: Propylene glycol monomethyl ether acetate (PGMEA)
S2: Propylene glycol monomethyl ether (PGME)
S3: Ethyl lactate

### S4: Cyclohexanone

As apparent from the results shown in Table 1, particularly from comparison of Example 1 with Comparative Examples 1, 2 and 3, Example 2 with Comparative Examples 4 and 5, Example 3 with Comparative Example 6, Example 4 with Comparative Example 7, Example 5 with Comparative Example 8, Example 6 with Comparative Example 9, Example 7 with Comparative Example 10, Example 8 with Comparative Example 11, Example 9 with Comparative Example 12, Examples 10, 11 and 12 with Comparative Example 13, the actinic ray-sensitive or radiation-sensitive composition of the present invention satisfies all of high sensitivity, high resolution, good pattern profile, improved line edge roughness and good dry etching resistance at the same time.

The second embodiment of the present invention is described in greater detail below by referring to Examples, but the second embodiment of the present invention should not be construed as being limited thereto.

### Synthesis Example 11

### Synthesis of Low Molecular Compound (Ex-2)

(Ex-2) was synthesized by the following route.

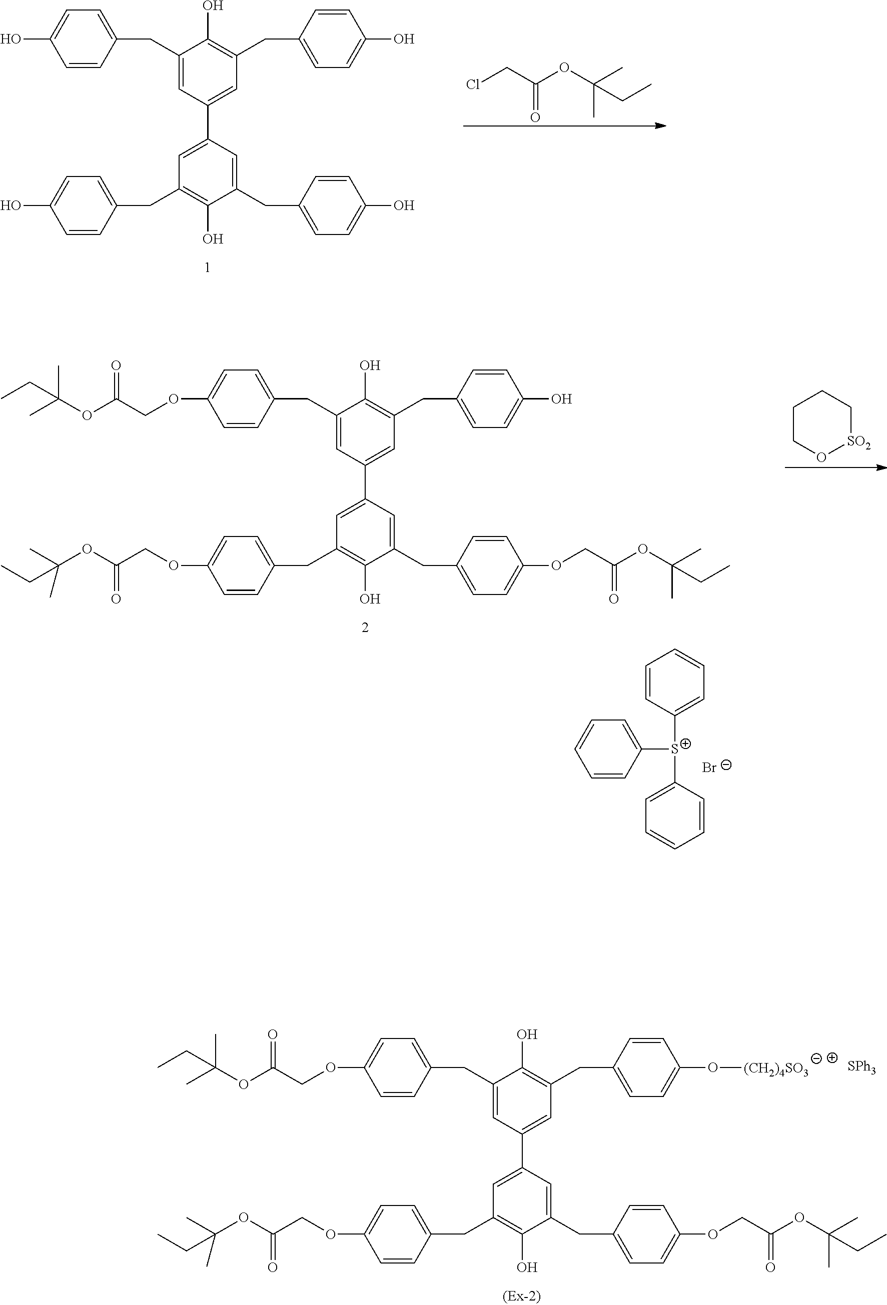

### Synthesis of Compound 2

A mixed solution of Compound 1 (6.1 g, 10 mmol), tert-amyl chloroacetate (4.93 g, 30 mmol), potassium carbonate (4.5 g, 33 mmol) and dimethylacetamide (100 ml) was stirred at 90° C. for 3 hours, and the reaction solution was cooled to room temperature, poured in ethyl acetate (300 ml)/aqueous 1 N hydrochloric acid (300 ml) and subjected to liquid separation. The organic layer was washed with water (300 ml× twice) and saturated brine (300 ml) and dried over sodium sulfate. The solvent was concentrated under reduced pressure, and the residue was purified through a silica gel column to obtain Compound 2 (3.4 g).

### Synthesis of (Ex-2)

Sodium hydride (48 mg, 2 mmol) was added to a dehydrated dimethylformamide solution (50 ml) of Compound 2 (1.99 g, 2 mmol), and the mixture was stirred at 25° C. for 30 minutes. To this solution, 1,4-butane sultone (0.27 g, 2 mmol) was added dropwise, and the mixture was further stirred at room temperature for 24 hours. To this solution, a methanol (30 ml) solution containing 5 g of triphenylsulfonium Br salt was added dropwise, and the resulting solution was stirred at room temperature for 30 minutes. Ion-exchanged water and chloroform were added thereto, and the solution was subjected to extraction and washing. The organic layer was concentrated under reduced pressure, and the residue was purified through a silica gel column to obtain 1.1 g of (Ex-2).

### Synthesis Example 12

### Synthesis of Low Molecular Compound (Ex-15)

(Ex-15) was synthesized by the following route.

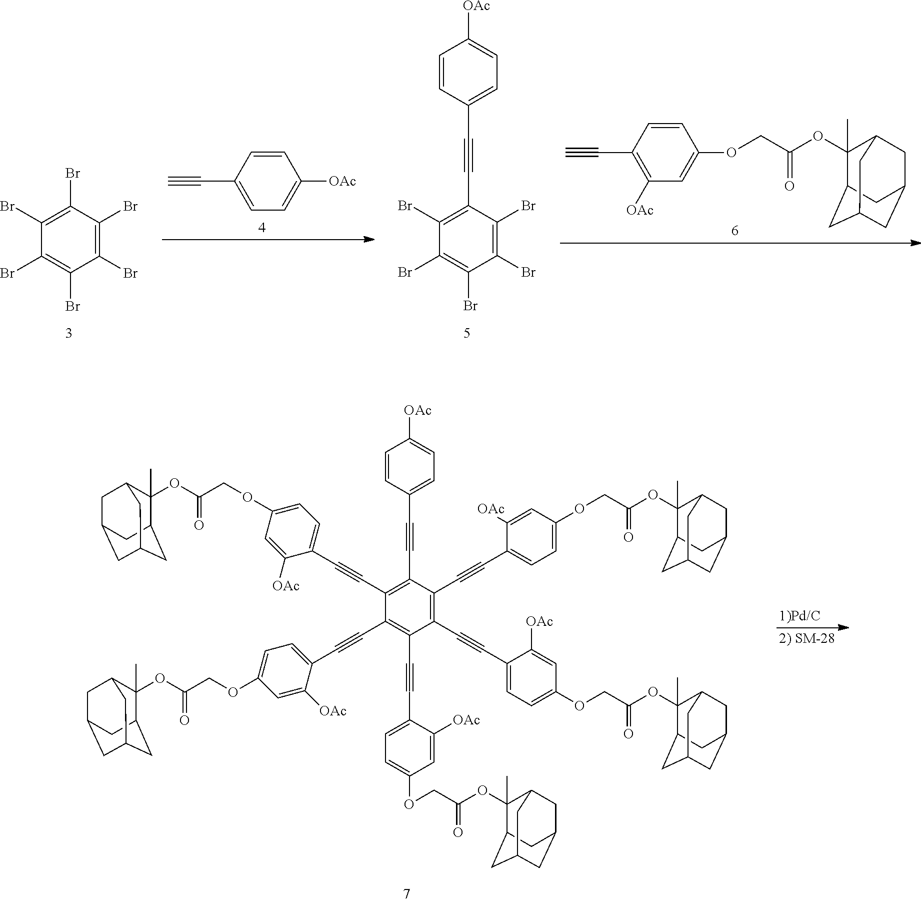

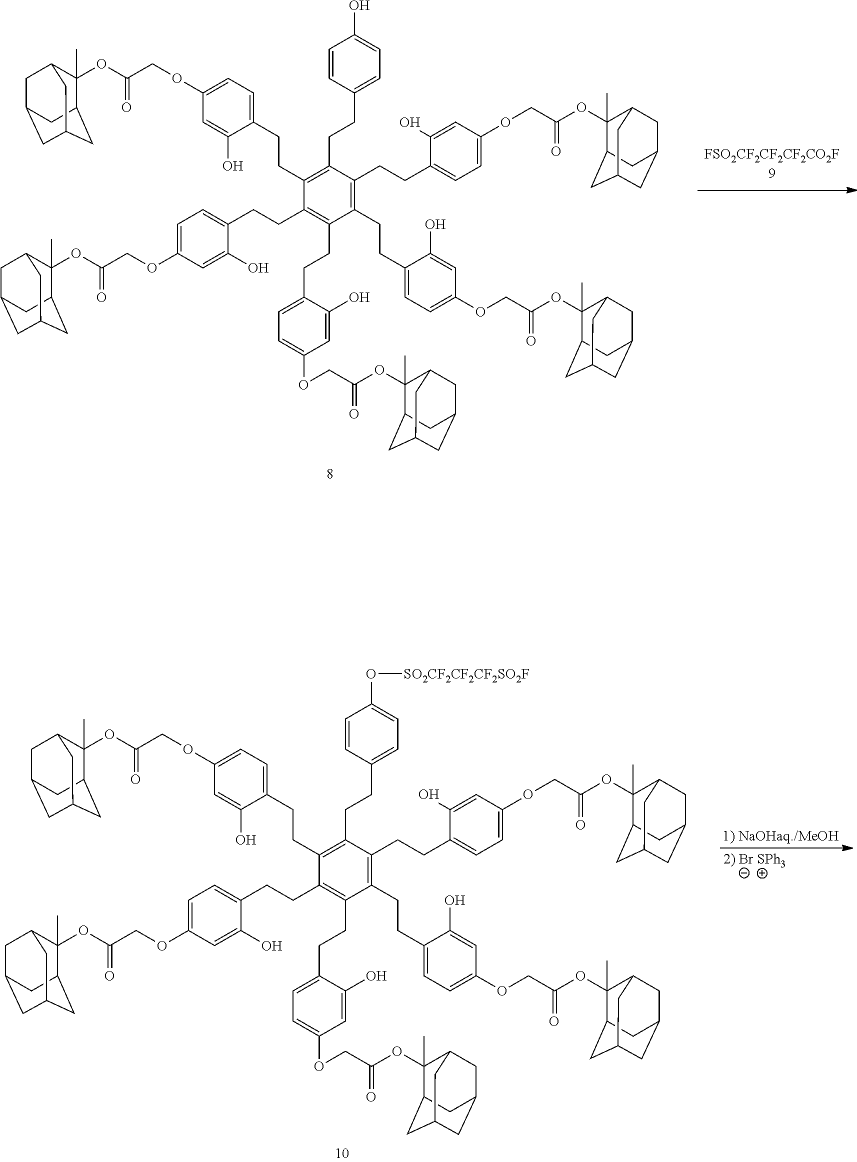

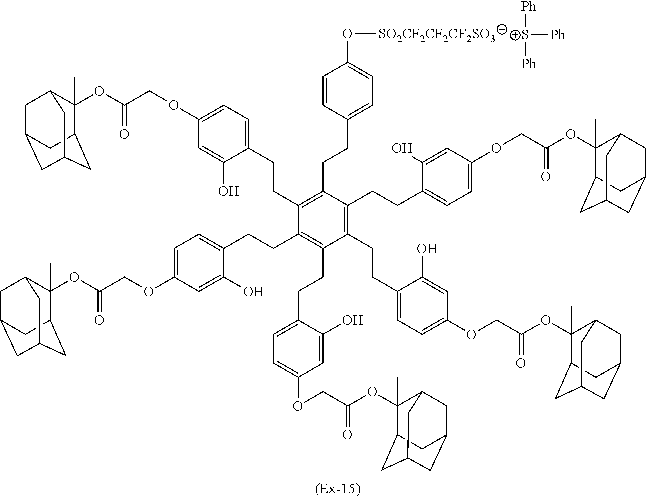

### Synthesis of Compound 5

A mixed solution of hexabromobenzene 3 (5.5 g, 10 mmol), 4-acetoxyphenylacetylene (0.5 g, 3.1 mmol), bisacetonitrile palladium(II) chloride complex (78 mg, 0.3 mmol), triphenylphosphine (0.39 g, 1.5 mmol), cuprous chloride (0.11 g, 0.6 mmol) and triethylamine (30 ml) was stirred at reflux temperature for 1 hour in a nitrogen atmosphere, and the reaction solution was cooled to room temperature, then slowly poured in aqueous 1 N hydrochloric acid (300 ml)/ethyl acetate (300 ml) and subjected to extraction. The organic layer was washed with water (300 ml× twice) and saturated brine (300 ml) and dried over sodium sulfate. The solvent was concentrated under reduced pressure, and the residue was purified through a silica gel column to obtain Compound 5 (1.32 g, 2.1 mmol).

### Synthesis of Compound 7

A mixed solution of Compound 5 (1.26 g, 2.0 mmol), Compound 6 (7.65 g, 20 mmol), bisacetonitrile palladium(II) chloride complex (0.52 g, 2.0 mmol), triphenylphosphine (2.62 g, 10 mmol), cuprous chloride (0.76 g, 4.0 mmol) and triethylamine (100 ml) was stirred at reflux temperature for 5 hours in a nitrogen atmosphere, and the reaction solution was cooled to room temperature, then slowly poured in aqueous 1 N hydrochloric acid (1 L)/ethyl acetate (1 L) and subjected to extraction. The organic layer was washed with water (1 L× twice) and saturated brine (1 L) and dried over sodium sulfate. The solvent was concentrated under reduced pressure, and the residue was purified through a silica gel column to obtain Compound 7 (2.35 g, 1.1 mmol).

### Synthesis of Compound 8

An ethyl acetate (50 ml)/methanol (50 ml) solution of Compound 7 (2.35 g, 1.1 mmol) and 0.5 mass % palladium carbon (0.1 g) was stirred at 50° C. for 3 hours under a hydrogen pressure (5.0 MPa), and the reaction solution was cooled to room temperature. Thereafter, the catalyst was removed by filtration, and a 28% sodium methoxide methanol solution SM-28 (2.5 g, 13.0 mmol) was added to the reaction solution. The resulting solution was stirred at 50° C. for 2 hours in a nitrogen atmosphere, and the obtained reaction solution was cooled to room temperature, slowly poured in aqueous 1 N hydrochloric acid (200 ml)/ethyl acetate (200 ml) and subjected to extraction. The organic layer was washed with water (200 ml× twice) and saturated brine (200 ml) and dried over sodium sulfate and after concentrating the solvent under reduced pressure, the residue was purified through a silica gel column to obtain Compound 8 (1.57 g, 0.82 mmol).

### Synthesis of Compound 10

Triethylamine (0.12 ml, 0.86 mmol) was added dropwise to an ethyl acetate (100 ml) solution of Compound 8 (1.57 g, 0.82 mmol) and Compound 9 (0.26 g, 0.82 mmol) at 5° C., and the mixture was stirred at 5° C. for 3 hours. After adding thereto aqueous 1 N hydrochloric acid (50 ml), the reaction solution was subjected to extraction, and the organic layer was washed with water (50 ml× twice) and saturated brine (50 ml) and dried over sodium sulfate. The solvent as concentrated under reduced pressure, and the residue was purified through a silica gel column to obtain Compound 10 (0.83 g, 0.38 mmol).

### Synthesis of (Ex-15)

An aqueous 1 N sodium hydroxide solution (2 ml) was added to a tetrahydrofuran (10 ml)/methanol (10 ml) solution of Compound 10 (0.83 g, 0.38 mmol), and the resulting solution was stirred at 40° C. for 1 hour. The reaction solution was cooled to room temperature, poured in saturated brine (100 ml)/ethyl acetate (100 ml) and subjected to extraction. The organic layer was further washed with saturated brine (100 ml) twice and dried over sodium sulfate and after concentrating the solvent under reduced pressure, the residue was dissolved in methanol (30 ml). To this solution, triphenylsulfonium Br salt (0.13 g, 0.38 mmol) was added, and the mixture was stirred at room temperature for 15 minutes, then poured in ion-exchanged water (100 ml)/chloroform (100 ml) and subjected to extraction. The organic layer was washed with ion-exchanged water (100 ml) twice and concentrated under reduced pressure, and the residue was purified through a silica gel column to obtain Ex-15 (0.72 g).

### Synthesis Example 13

### Synthesis of Low Molecular Compound (Ex-16)

(Ex-16) was synthesized by the following route.

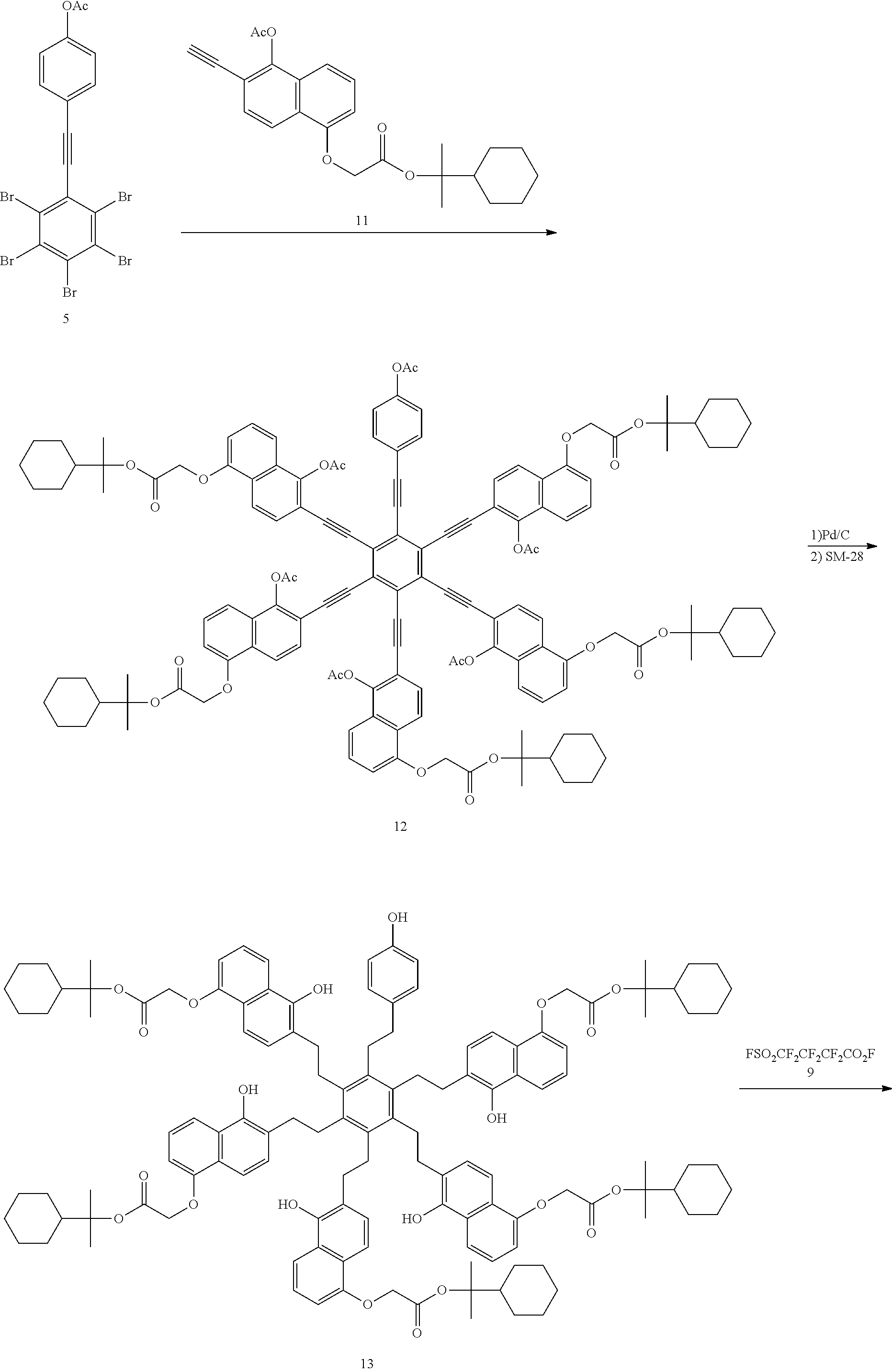

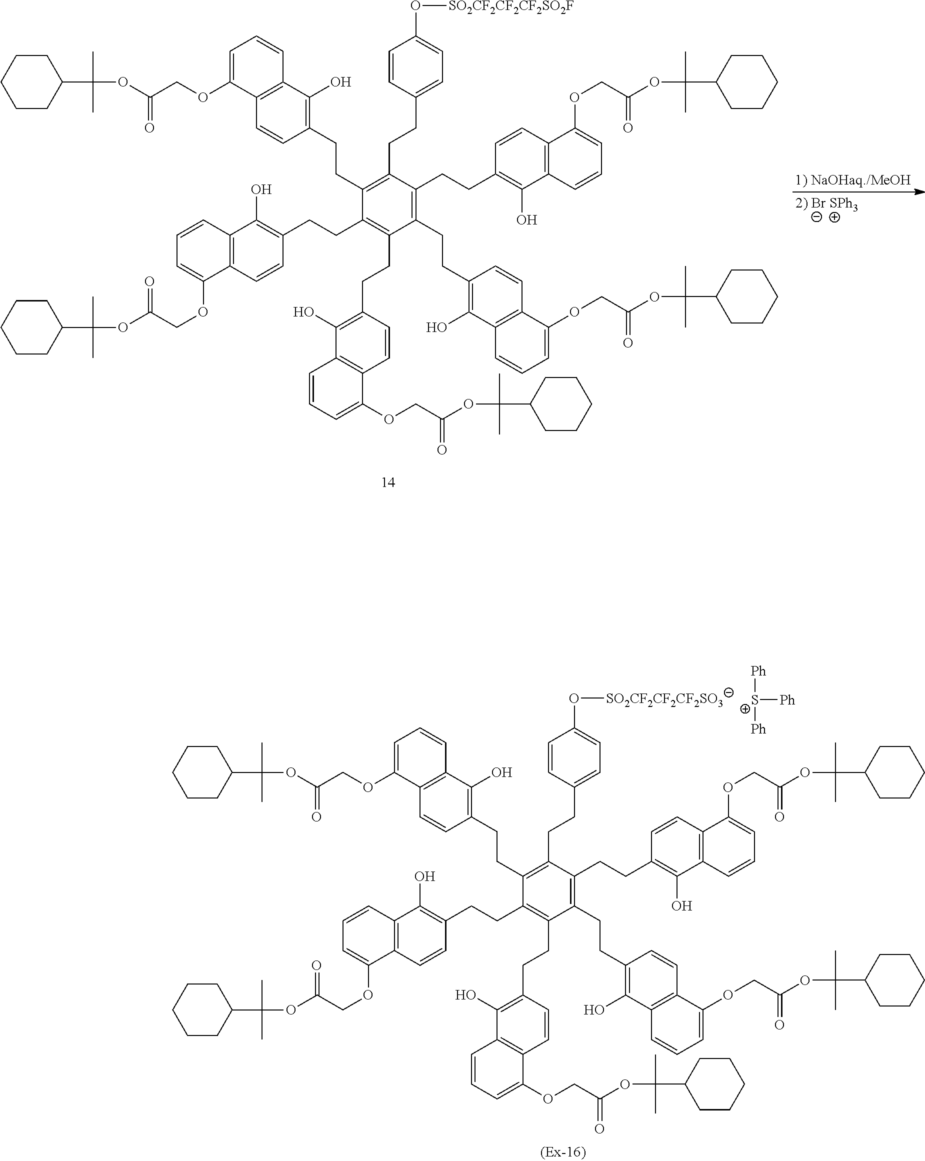

### Synthesis of Compound 12

A mixed solution of Compound 5 (1.26 g, 2.0 mmol), Compound 11 (8.17 g, 20 mmol), bisacetonitrile palladium(II) chloride complex (0.52 g, 2.0 mmol), triphenylphosphine (2.62 g, 10 mmol), cuprous chloride (0.76 g, 4.0 mmol), triethylamine (100 ml) and tetrahydrofuran (100 ml) was stirred at reflux temperature for 8 hours in a nitrogen atmosphere, and the reaction solution was cooled to room temperature, then slowly poured in aqueous 1 N hydrochloric acid (1 L)/ethyl acetate (1 L) and subjected to extraction. The organic layer was washed with water (1 L× twice) and saturated brine (1 L) and dried over sodium sulfate. The solvent was concentrated under reduced pressure, and the residue was purified through a silica gel column to obtain Compound 12 (2.04 g, 0.9 mmol).

### Synthesis of Compound 13

An ethyl acetate (50 ml)/methanol (50 ml) solution of Compound 12 (2.04 g, 0.9 mmol) and 0.5 mass % palladium carbon (0.1 g) was stirred at 50° C. for 4 hours under a hydrogen pressure (5.0 MPa), and the reaction solution was cooled to room temperature. Thereafter, the catalyst was removed by filtration, and a 28% sodium methoxide methanol solution SM-28 (2.4 g, 12.4 mmol) was added to the reaction solution. The resulting solution was stirred at 50° C. for 3 hours in a nitrogen atmosphere, and the obtained reaction solution was cooled to room temperature, slowly poured in aqueous 1 N hydrochloric acid (200 ml)/ethyl acetate (200 ml) and subjected to extraction. The organic layer was washed with water (200 ml× twice) and saturated brine (200 ml) and dried over sodium sulfate and after concentrating the solvent under reduced pressure, the residue was purified through a silica gel column to obtain Compound 13 (1.25 g, 0.61 mmol).

### Synthesis of Compound 14

Triethylamine (0.10 ml, 0.79 mmol) was added dropwise to an ethyl acetate (100 ml) solution of Compound 13 (1.25 g, 0.61 mmol) and Compound 9 (0.19 g, 0.61 mmol) at 5° C., and the mixture was stirred at 5° C. for 3 hours. After adding thereto aqueous 1 N hydrochloric acid (50 ml), the reaction solution was subjected to extraction, and the organic layer was washed with water (50 ml× twice) and saturated brine (50 ml) and dried over sodium sulfate. The solvent as concentrated under reduced pressure, and the residue was purified through a silica gel column to obtain Compound 14 (0.61 g, 0.26 mmol).

### Synthesis of (Ex-16)

An aqueous 1 N sodium hydroxide solution (2 ml) was added to a tetrahydrofuran (10 ml)/methanol (10 ml) solution of Compound 14 (0.61 g, 0.26 mmol), and the resulting solution was stirred at 40° C. for 1 hour. The reaction solution was cooled to room temperature, poured in saturated brine (100 ml)/ethyl acetate (100 ml) and subjected to extraction. The organic layer was further washed with saturated brine (100 ml) twice and dried over sodium sulfate and after concentrating the solvent under reduced pressure, the residue was dissolved in methanol (30 ml). To this solution, triphenylsulfonium Br salt (0.089 g, 0.26 mmol) was added, and the mixture was stirred at room temperature for 15 minutes, then poured in ion-exchanged water (100 ml)/chloroform (100 ml) and subjected to extraction. The organic layer was washed with ion-exchanged water (100 ml) twice and concentrated under reduced pressure, and the residue was purified through a silica gel column to obtain Ex-16 (0.55 g).

### Synthesis 1 of Comparative Compound

### Synthesis of Low Molecular Compound (R-1)

(R-1) was synthesized by the following route.

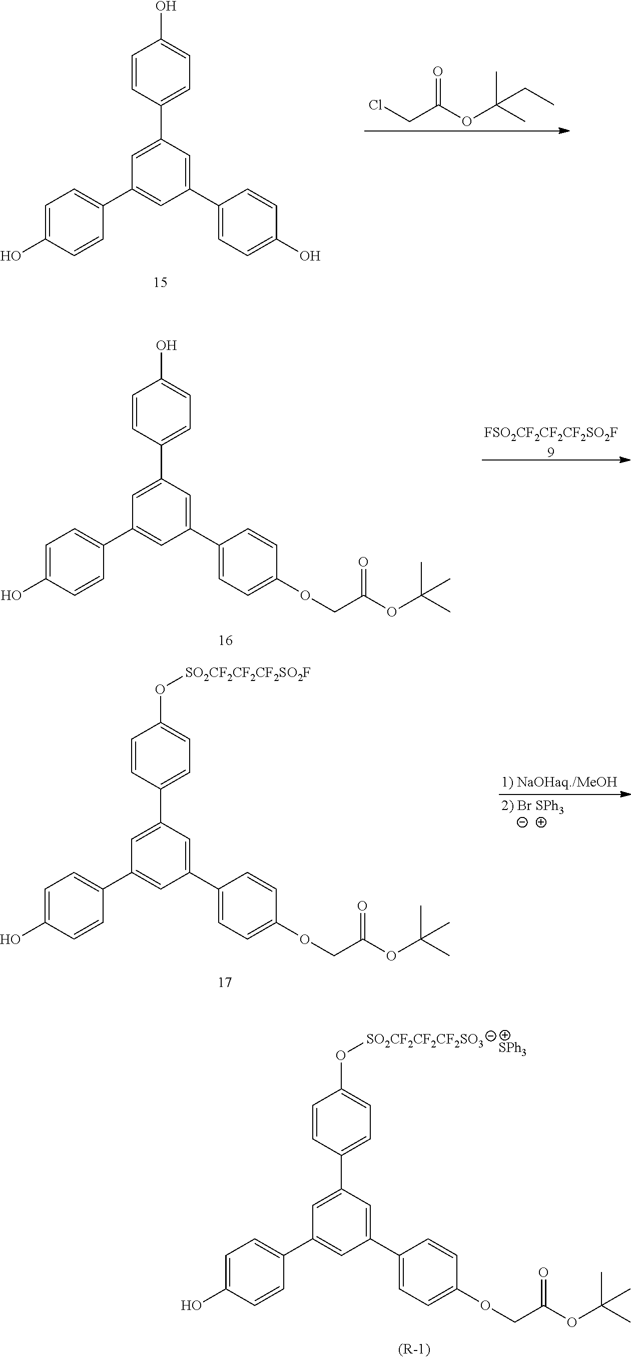

### Synthesis of Compound 16

A mixed solution of Compound 15 (7.1 g, 0.02 mol), tert-amyl chloroacetate (3.3 g, 0.02 mol), potassium carbonate (3.0 g, 0.022 mol) and dimethylacetamide (30 ml) was stirred at 100° C. for 3 hours in a nitrogen atmosphere, and the reaction solution was cooled to room temperature, poured in ethyl acetate (100 ml)/aqueous 1 N hydrochloric acid (100 ml) and subjected to liquid separation. The organic layer was washed with water (100 ml× twice) and saturated brine (100 ml) and dried over sodium sulfate. The solvent was concentrated under reduced pressure, and the residue was purified through a silica gel column to obtain Compound 16 (5.6 g, 0.012 mol).

### Synthesis of Compound 17

Triethylamine (1.5 ml, 0.012 mol) was added dropwise to an ethyl acetate (200 ml) solution of Compound 16 (5.6 g, 0.012 mol) and Compound 9 (3.8 g, 0.012 mol) at 5° C., and the mixture was stirred at 5° C. for 3 hours. After adding thereto aqueous 1 N hydrochloric acid (100 ml), the reaction solution was subjected to extraction, and the organic layer was washed with water (100 ml× twice) and saturated brine (100 ml) and dried over sodium sulfate. The solvent as concentrated under reduced pressure, and the residue was purified through a silica gel column to obtain Compound 17 (5.5 g, 7.0 mmol).

### Synthesis of (R-1)

An aqueous 1 N sodium hydroxide solution (20 ml) was added to a tetrahydrofuran (100 ml)/methanol (100 ml) solution of Compound 17 (5.5 g, 7.0 mmol), and the resulting solution was stirred at 40° C. for 1 hour. The reaction solution was cooled to room temperature, poured in saturated brine (500 ml)/ethyl acetate (500 ml) and subjected to extraction. The organic layer was further washed with saturated brine (500 ml) twice and dried over sodium sulfate and after concentrating the solvent under reduced pressure, the residue was dissolved in methanol (300 ml). To this solution, triphenylsulfonium Br salt (2.4 g, 7.0 mmol) was added, and the mixture was stirred at room temperature for 15 minutes, then poured in ion-exchanged water (500 ml)/chloroform (500 ml) and subjected to extraction. The organic layer was washed with ion-exchanged water (500 ml) twice and concentrated under reduced pressure, and the residue was purified through a silica gel column to obtain R-1 (4.4 g, 4.8 mmol).

### Synthesis 2 of Comparative Compound

### Synthesis of Polymer Compound (R-2)

Copolymer (R-2) of p-hydroxystyrene 18 and 1-methyl-1-adamantyl methacrylate 19 was synthesized by radical polymerization of these monomers.

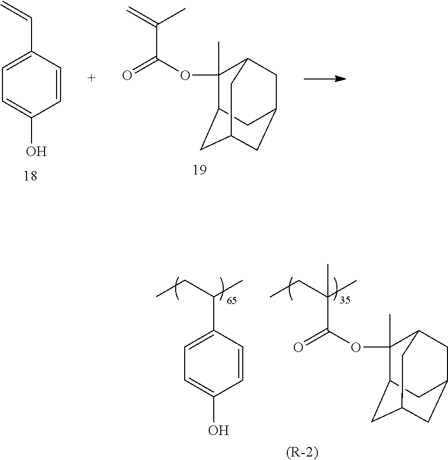

1-Methoxy-2-propanol (50 ml) was heated at 80° C. under nitrogen flow and while stirring this solution, a mixed solution of Monomer 18 (7.2 g, 60 mmol), Monomer 19 (9.4 g, 40 mmol), 0.8 g (3.5 mmol) of dimethyl 2,2′-azobisisobutyrate (V-601, produced by Wako Pure Chemical Industries, Ltd.), and 1-methoxy-2-propanol (50 ml) was added dropwise over 5 hours. After the completion of dropwise addition, the solution was further stirred at 80° C. for 3 hours. The resulting reaction solution was allowed to cool and then subjected to reprecipitation from a large amount of hexane/ethyl acetate and vacuum drying to obtain Comparative Resin R-2 (12.3 g). ¹H-NMR of the obtained resin was measured, and the compositional ratio (65/35 by mol, repeating units starting from the left in the structural formula above) of the resin was calculated. Also, the weight average molecular weight (Mw: in terms of polystyrene) determined from GPC (carrier: N-methyl-2-pyrrolidone (NMP)) was Mw=4,800, and Mw/Mn=1.56.

### Synthesis 3 of Comparative Compound

### Synthesis of Polymer Compound (R-3)

Copolymer (R-3) of p-hydroxystyrene 18,2-cyclohexyl-2-propyl methacrylate 20 and triphenylsulfonium 4-styrenesulfonate 21 was synthesized by radical polymerization of these monomers.

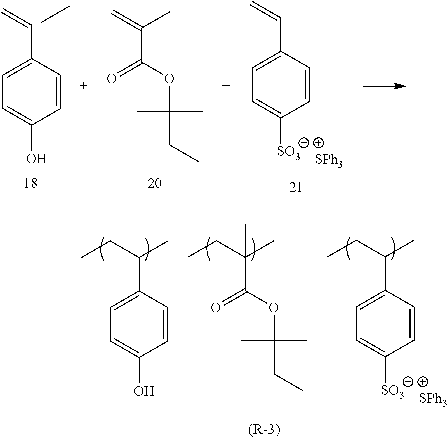

1-Methoxy-2-propanol (17.5 ml) was heated at 80° C. under nitrogen flow and while stirring this solution, a mixed solution of Monomer 18 (10.3 g, 85.4 mmol), Monomer 20 (6.0 g, 38.2 mmol), Monomer 21 (1.7 g, 3.8 mmol), 5.9 g (25.5 mmol) of dimethyl 2,2′-azobisisobutyrate (V-601, produced by Wako Pure Chemical Industries, Ltd.), and 1-methoxy-2-propanol (70 ml) was added dropwise over 4 hours. After the completion of dropwise addition, the solution was further stirred at 80° C. for 2 hours. The resulting reaction solution was allowed to cool and then subjected to reprecipitation from a large amount of hexane/ethyl acetate and vacuum drying to obtain Comparative Resin R-3 (15.0 g). ¹H-NMR of the obtained resin was measured, and the compositional ratio (59/38/3 by mol, repeating units starting from the left in the structural formula above) of the resin was calculated. Also, the weight average molecular weight (Mw: in terms of polystyrene) determined from GPC (carrier: N-methyl-2-pyrrolidone (NMP)) was Mw=4,900, and Mw/Mn=1.6.

### Examples 2-1 to 2-7 and Comparative Examples 2-1 to 2-3

### Evaluation (EB)

The components shown in Table 2 below were dissolved in the solvent shown in Table 2 to prepare a solution having an entire solid content concentration of 5.0 mass %, and this solution was filtered through a polytetrafluoroethylene filter having a pore size of 0.1 μm to obtain an actinic ray-sensitive or radiation-sensitive composition (positive resist solution). The prepared positive resist solution was uniformly coated on a hexamethyldisilazane-treated silicon substrate by using a spin coater and dried by heating on a hot plate at 110° C. for 90 seconds to form a resist film having a film thickness of 60 nm.

This resist film was then irradiated with electron beams by using an electron beam irradiation apparatus (HL750, manufactured by Hitachi Ltd., accelerating voltage: 50 KeV) and immediately after the irradiation, heated on a hot plate at 120° C. for 90 seconds. Furthermore, the resist film was developed using an aqueous tetramethylammonium hydroxide solution with a concentration of 2.38 mass % at 23° C. for 60 seconds, rinsed with pure water for 30 seconds and dried to form a line-and-space pattern. The obtained pattern was evaluated for sensitivity, resolution, line edge roughness, pattern profile and dry etching resistance in the same manner as in Examples 1-1 to 1-12 and Comparative Examples 1-1 to 1-13. The evaluation results are shown in Table 2.

TABLE 2
Evaluation Results in EB Exposure

| | Low | | | | | |
|---|---|---|---|---|---|---|
| | Molecular | Polymer | Acid Gener- | Basic | | Organic |
| | Compound | Compound | ator | Compound | Surfactant | Solvent |
| | (concen- | (concen- | (concen- | (concen- | (concen- | (mixing |
| | tration)*¹ | tration)*¹ | tration)*¹ | tration)*¹ | tration)*¹ | ratio)*² |
| Example 2-1 | (Ex-2) | none | none | TOA | W-1 | S1/S2 |
| | (98.95) | | | (1) | (0.05) | (10/90) |
| Example 2-2 | (Ex-15) | none | none | TOA | W-1 | S1/S5 |
| | (98.95) | | | (1) | (0.05) | (10/90) |
| Example 2-3 | (Ex-16) | none | none | TOA | W-1 | S1/S4 |
| | (98.95) | | | (1) | (0.05) | (10/90) |
| Example 2-4 | (Ex-17) | none | none | TBAH | W-2 | S1/S2 |
| | (98.95) | | | (1) | (0.05) | (10/90) |
| Example 2-5 | (Ex-24) | none | none | TOA | W-3 | S1/S2 |
| | (98.95) | | | (1) | (0.05) | (10/90) |
| Example 2-6 | (Ex-16) (49.475) + | none | none | TOA (0.5) + | W-1 (0.025) + | S1/S2/S4 |
| | (Ex-17) (49.475) | | | TBAH (0.5) | W-2 (0.025) | (10/45/45) |
| Example 2-7 | (Ex-15) | (R-2) | PAG-1 | TOA | W-1 | S1/S2/S5 |
| | (66.0) | (29.65) | (3.3) | (1) | (0.05) | (33.3/6.7/60) |
| Comparative | (R-1) | none | none | TOA | W-1 | S1/S2 |
| Example 2-1 | (98.95) | | | (1) | (0.05) | (15/85) |
| Comparative | none | (R-2) | PAG-1 | TOA | W-1 | S1/S2 |
| Example 2-2 | | (88.95) | (10) | (1) | (0.05) | (80/20) |
| Comparative | none | (R-3) | none | TOA | W-1 | S1/S2 |
| Example 2-3 | | (98.95) | | (1) | (0.05) | (5/95) |

| | | | | | Dry | |
|---|---|---|---|---|---|---|
| | | | | | Etching | |
| | Sensitivity | Resolution | Pattern | LER | Resistance | |
| | (μC/cm²) | (nm) | Profile | (nm) | (nm/s) | Remarks |
| Example 2-1 | 23.6 | 70 | rectangular | 5.1 | 2.1 | |
| Example 2-2 | 24.1 | 65 | rectangular | 4.8 | 1.8 | |
| Example 2-3 | 20.5 | 60 | rectangular | 4.6 | 1.5 | |
| Example 2-4 | 22.5 | 65 | rectangular | 4.1 | 1.9 | |
| Example 2-5 | 23.5 | 65 | rectangular | 4.8 | 2 | |
| Example 2-6 | 21 | 60 | rectangular | 4.2 | 1.7 | |
| Example 2-7 | 26.2 | 70 | rectangular | 5.4 | 19.5 | |
| Comparative | — | — | — | — | — | 100-nm |
| Example 2-1 | | | | | | L/S pattern |
| | | | | | | could not |
| | | | | | | be formed |
| Comparative | 30.5 | 90 | tapered | 7.5 | 2.2 | |
| Example 2-2 | | | | | | |
| Comparative | 27.5 | 70 | rectangular | 5.5 | 2.3 | |
| Example 2-3 | | | | | | |

*¹mass % in the entire sold content,
*²ratio by mass.

Structures of the basic compounds and acid generators used in Examples and Comparative Examples are shown below.

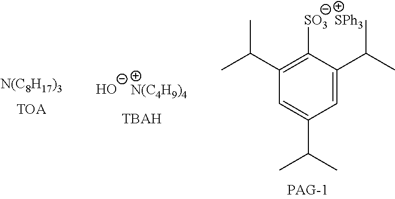

Surfactants and solvents used in Examples and Comparative Examples are set forth below.

W-1: Megaface F176 (produced by Dainippon Ink & Chemicals, Inc., fluorine-containing)
W-2: Megaface R08 (produced by Dainippon Ink & Chemicals, Inc., fluorine- and silicon-containing)
W-3: Polysiloxane polymer (produced by Shin-Etsu Chemical Co., Ltd., silicon-containing)
S1: Propylene glycol monomethyl ether acetate (PGMEA)
S2: Propylene glycol monomethyl ether (PGME)

### S4: Cyclohexanone

S5: Ethyl lactate

As apparent from Table 2, the actinic ray-sensitive or radiation-sensitive composition of the present invention satisfies all of high sensitivity, high resolution, good pattern profile, improved line edge roughness and good dry etching resistance at the same time.

### Examples 2-8 to 2-10

### Evaluation (EUV)

### Resist Evaluation (EUV Light)

The components shown in Table 3 below were dissolved in the mixed solvent shown in Table 3 to prepare a solution having a solid content concentration of 5.0 mass %, and this solution was filtered through a polytetrafluoroethylene filter having a pore size of 0.1 μm to obtain a positive resist solution. Incidentally, the symbols of compounds in Table 3 are the same as those in Table 2.

The prepared positive resist solution was uniformly coated on a hexamethyldisilazane-treated silicon substrate by using a spin coater and dried by heating on a hot plate at 110° C. for 90 seconds to form a resist film having a film thickness of 100 nm.

This resist film was irradiated using an EUV exposure apparatus (manufactured by Lithotrack Japan, wavelength: 13 nm) and immediately after the irradiation, heated on a hot plate at 120° C. for 90 seconds. Furthermore, the resist film was developed using an aqueous tetramethylammonium hydroxide solution with a concentration of 2.38 mass % at 23° C. for 60 seconds, rinsed with pure water for 30 seconds and dried to form a line-and-space pattern (line:space=1:1). The obtained pattern was evaluated by the following methods.

### [Sensitivity]

The cross-sectional profile of the obtained pattern was observed using a scanning electron microscope (S-9220, manufactured by Hitachi Ltd.). The minimum irradiation energy when resolving a 100-nm line (line:space=1:1) was defined as the sensitivity.

### [Pattern Profile]

The cross-sectional profile of a 100-nm line pattern at the irradiation dose giving the sensitivity above was observed using a scanning electron microscope (S-4300, manufactured by Hitachi, Ltd.) and evaluated on a 3-step scale, that is, rectangular, slightly tapered, and tapered.

TABLE 3
Evaluation Results in EUV Exposure

| | Low | | | | | | | |
|---|---|---|---|---|---|---|---|---|
| | Molecular | Polymer | Acid Gener- | Basic | | Organic | | |
| | Compound | Compound | ator | Compound | Surfactant | Solvent | | |
| | (concen- | (concen- | (concen- | (concen- | (concen- | (mixing | Sensitivity | Pattern |
| | tration)*¹ | tration)*¹ | tration)*¹ | tration)*¹ | tration)*¹ | ratio)*² | (mJ/cm²) | Profile |
| Example 2-8 | (Ex-15) | none | none | TOA | W-1 | S1/S5 | 15.6 | rectangular |
| | (98.95) | | | (1) | (0.05) | (10/90) | | |
| Example 2-9 | (Ex-16) | none | none | TOA | W-1 | S1/S4 | 14.8 | rectangular |
| | (98.95) | | | (1) | (0.05) | (10/90) | | |
| Example 2-10 | (Ex-17) | none | none | TBAH | W-2 | S1/S2 | 15.2 | rectangular |
| | (98.95) | | | (1) | (0.05) | (10/90) | | |

*¹mass % in the entire sold content,
*²ratio by mass.

As seen from the results in Table 3, the actinic ray-sensitive or radiation-sensitive composition of the present invention exhibits good sensitivity also in EUV exposure and can form a pattern with good profile.

### INDUSTRIAL APPLICABILITY

According to the present invention, an actinic ray-sensitive or radiation-sensitive low molecular compound-containing composition which can satisfy high sensitivity, high resolution, good pattern profile and improved line edge roughness in the ultrafine region, particularly in the lithography using electron beam, X-ray or EUV light, as well as the dry etching resistance all at the same time and which is suitable in particular as a positive resist composition, and a pattern forming method using the composition, can be provided.

This application is based on Japanese patent applications No. 2009-180207 filed on Jul. 31, 2009 and No. 2009-204998 filed on Sep. 4, 2009, the entire content of which is hereby incorporated by reference, the same as if set forth at length.

1. An actinic ray-sensitive or radiation-sensitive composition, comprising:
(1) a low molecular compound having a molecular weight of 500 to 5,000 and containing (G) an acid-decomposable group capable of decomposing by an action of an acid to accelerate a dissolution of the low molecular compound (1) in an alkali developer; and
(2) a compound capable of generating an acid of 305 Å³ or more in volume upon irradiation with an actinic ray or radiation.

2. The actinic ray-sensitive or radiation-sensitive composition according to claim 1,
wherein the compound (2) is represented by the following formula (2-1) or (2-2): 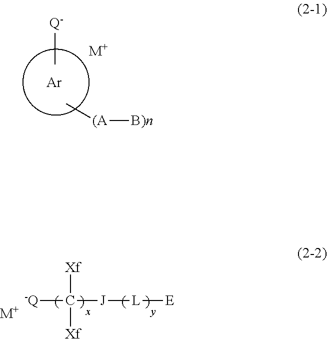
wherein in formula (2-1), Ar represents an aromatic ring and may further have a substituent other than the -(A-B) group;
n represents an integer of 1 or more;
A represents a single bond or a divalent linking group;
B represents a group containing a hydrocarbon group;
when n is 2 or more, a plurality of the -(A-B) groups are the same or different from each other;
Q⁻ represents an anion with pKa of the conjugated acid of the anion represented by Q⁻ being 6 or less; and
M⁺ represents an organic onium ion, and in formula (2-2), each Xf independently represents a fluorine atom or an alkyl group substituted with at least one fluorine atom;
J represents a single bond, a linear, branched or cyclic alkylene group which may contain an ether oxygen, an arylene group, or a group containing a combination of these groups, and the groups combined may be connected through an oxygen atom;
L represents a divalent linking group, and when a plurality of L's are present, the plurality of L's are the same or different from each other;
E represents a group having a ring structure;
x represents an integer of 1 to 20;
y represents an integer of 0 to 10; and
Q⁻ and M⁺ have the same meanings as those in formula (2-1).

3. The actinic ray-sensitive or radiation-sensitive composition according to claim 2,
wherein the compound (2) is represented by formula (2-2), and formula (2-2) is represented by the following formula (2-3): 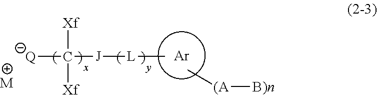
wherein Ar, n, A, B, Q⁻, M⁺, Xf, J, L, x and y have the same meanings as respective symbols in formulae (2-1) and (2-2).

4. The actinic ray-sensitive or radiation-sensitive composition according to claim 2,
wherein in formula (2-1), B is a group containing a hydrocarbon group having a carbon number of 4 or more.

5. The actinic ray-sensitive or radiation-sensitive composition according to claim 2,
wherein in formula (2-1), B is a group containing a tertiary or quaternary carbon atom-containing hydrocarbon group having a carbon number of 4 or more.

6. The actinic ray-sensitive or radiation-sensitive composition according to claim 2,
wherein in formula (2-1), B is a group containing a cyclic hydrocarbon having a carbon number of 4 or more.

7. The actinic ray-sensitive or radiation-sensitive composition according to claim 1,
wherein the low molecular compound (1) further contains (S) a dissolution auxiliary group capable of accelerating a dissolution of the low molecular compound (1) in an alkali developer.

8. The actinic ray-sensitive or radiation-sensitive composition according to claim 1,
wherein the low molecular compound (1) is a compound represented by the following formula (1-1): 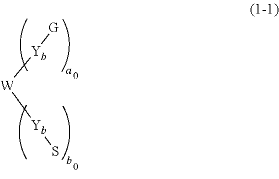
wherein W represents an (a₀+b₀)-valent organic group;
each of Yₐ and Y_{b} independently represents a single bond or a divalent linking group;
G represents an acid-decomposable group capable of decomposing by an action of an acid to accelerate a dissolution of the low molecular compound (1) in an alkali developer;
S is a dissolution auxiliary group capable of accelerating a dissolution of the low molecular compound (1) in an alkali developer;
each of a₀ and b₀ independently represents an integer of 1 to 30, and when a plurality of —(Yₐ-G) groups and a plurality of —(Y_{b}—S) groups are present respectively, the plurality of —(Yₐ-G) groups and the plurality of —(Y_{b}—S) groups are the same or different from each other respectively.

9. An actinic ray-sensitive or radiation-sensitive composition, comprising:
a solvent; and
(1A) a compound which is a low molecular compound having a molecular weight of 500 to 5,000 and containing, in one molecule, (Z) one or more groups capable of decomposing upon irradiation with an actinic ray or radiation to produce an acid, (G) one or more acid-decomposable groups capable of decomposing by an action of an acid to accelerate a dissolution of the compound (1A) in an alkali developer and (S) one or more dissolution auxiliary groups capable of accelerating a dissolution of the compound (1A) in an alkali developer, wherein assuming that the number of the functional groups in one molecule of (Z), (G) and (S) is z, q and s, respectively, q/z≧2 and s/z≧2.

10. The actinic ray-sensitive or radiation-sensitive composition according to claim 9,
wherein the compound (1A) is a compound represented by the following formula (1A-1) or (1A-2): 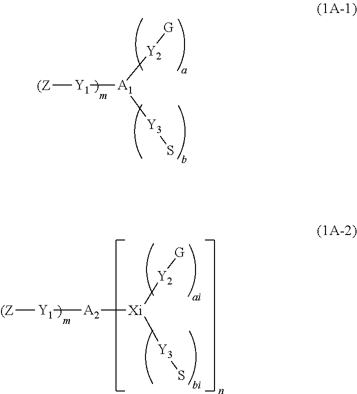
wherein in formula (1A-1), A₁ represents an (a+b+m)-valent organic group;
each of Y₁, Y₂ and Y₃ independently represents a single bond or a divalent linking group;
Z represents a group capable of decomposing upon irradiation with an actinic ray or radiation to produce an acid;
G represents an acid-decomposable group capable of decomposing by an action of an acid to accelerate a dissolution of the compound (1A) in an alkali developer;
S represents a dissolution auxiliary group capable of accelerating a dissolution of the compound (1A) in an alkali developer;
m represents an integer of 1 to 3; and
each of a and b independently represents an integer of 2 to 10, in formula (1A-2), A₂ represents an (m+n)-valent organic group;
Y₁, Y₂, Y₃, Z, G, S and m have the same meanings as those in formula (1A-1);
Xi represents an (ai+bi+1)-valent organic group;
n represents an integer of 1 to 10;
each of ai and bi independently represents an integer of 0 to 5; and
ai and bi are not 0 at the same time, and
in formulae (1A-1) and (1A-2), when a plurality of —(Y₁—Z) groups, a plurality of —(Y₂-G) groups, a plurality of —(Y₃—S) groups and a plurality of Xi's are present respectively, the plurality of —(Y₁—Z) groups, the plurality of —(Y₂-G) groups, the plurality of —(Y₃—S) groups and the plurality of Xi's are the same or different from each other respectively.

11. The actinic ray-sensitive or radiation-sensitive composition according to claim 10,
wherein the compound (1A) contains at least one aromatic ring.

12. The actinic ray-sensitive or radiation-sensitive composition according to claim 11, comprising:
as the compound (1A), a compound in which at least one of A₁, Y₁, Y₂ and Y₃ in formula (1A-1) or at least one of A₂, Xi, Y₁, Y₂ and Y₃ in formula (1A-2) is a group containing an aromatic group.

13. The actinic ray-sensitive or radiation-sensitive composition according to claim 11,
wherein the aromatic ring is a benzene ring.

14. The actinic ray-sensitive or radiation-sensitive composition according to claim 11,
wherein the aromatic group is a condensed ring composed of two or more rings.

15. The actinic ray-sensitive or radiation-sensitive composition according to claim 14,
wherein the aromatic ring is a naphthalene ring.

16. The actinic ray-sensitive or radiation-sensitive composition according to claim 9, further comprising:
a basic compound.

17. A pattern forming method, comprising:
forming a film by using the actinic ray-sensitive or radiation-sensitive composition according to claim 1; and
exposing and developing the film.

18. The pattern forming method according to claim 17,
wherein the exposure is performed using X-ray, electron beam or EUV.

19. A pattern forming method, comprising;
forming a film by using the actinic ray-sensitive or radiation-sensitive composition according to claim 9; and
exposing and developing the film.

20. The pattern forming method according to claim 19,
wherein the exposure is performed using X-ray, electron beam or EUV.
